(19) United States
(12) Patent Application Publication
(10) Pub. No.: US 2010/0237330 A1
(43) Pub. Date: Sep. 23, 2010

(54) ORGANIC ELECTROLUMINESCENT COMPOUND AND ORGANIC LIGTH EMITTING DIODE USING THE SAME

(76) Inventors: Mi Ae Lee, Gyeonggi-do (KR); Hyuck Joo Kwon, Seoul (KR); Young Jun Cho, Seoul (KR); Bong Ok Kim, Seoul (KR); Sung Min Kim, Seoul (KR)

Correspondence Address: ROHM AND HAAS ELECTRONIC MATERIALS LLC, 455 FOREST STREET, MARLBOROUGH, MA, 01752, US

(21) Appl. No.: 12/451,572

(22) PCT Filed: May 8, 2008
(86) PCT No.: PCT/KR2008/002573

§ 371 Date: Apr. 26, 2010

(30) Foreign Application Priority Data
May 21, 2007 (KR) 10-2007-0049004

(51) Int. Cl. H01L 51/54; C07F 7/08

(52) U.S. Cl. 257/40; 556/432; 556/489; 257/E51.041

(57) ABSTRACT

The present invention relates to novel organic electroluminescent compounds and organic light emitting diodes comprising the same. Since the organic electrolumescent compounds according to the invention have good luminous efficiency and life property as an electroluminescent material, OLED's having very good operation lifetime can be produced.

### TECHNICAL FIELD

The present invention relates to novel organic electroluminescent compounds and organic light emitting diodes comprising the same.

### BACKGROUND ART

As the modern society comes into information-oriented age, the importance of a display, which plays a role of interface between the electronic information device and human being, increases. As a novel planar display technique, OLED's have been actively investigated throughout the world, since OLED's show excellent display property as self-luminescent device, and the manufacture is easy because of simple device structure, and enable manufacturing of ultra-thin and ultra-light weight displays.

OLED device usually consists of a plurality of thin layers of organic compound between a cathode and an anode made of metal. Electrons and holes injected through the cathode and anode are transmitted to an electroluminescent layer via an electron injection layer and an electron transportation layer, and a hole injection layer and a hole transportation layer, respectively, to form excitons, which degrade into stable state to emit light. In particular, the properties of an OLED largely depend on the properties of the organic electroluminescent compound employed. Accordingly studies on core organic materials having enhanced performances have been actively achieved.

The core organic materials are classified into electroluminescent materials, carrier injection and transportation materials in view of their functions. The electroluminescent materials can be classified into host materials and dopant materials. Usually, as the device structure with most excellent EL properties, structures comprising a core organic thin film layer employing host-dopant doping system have been known.

Recently, small size displays are practically used, so that development of OLED's with high efficiency and long life is raising as an urgent subject. This would be an important milestone in the field of practical use of medium to large size OLED panels. Thus, development of core organic materials having more excellent properties as compared to conventional core organic materials is urgently required. From this point of view, development of host materials, carrier injection and transportation materials is one of the important subjects to be solved.

Desirable properties for host material as solid state solvent and energy deliverer or material for carrier injection or transportation in an OLED are high purity and appropriate molecular weight to enable vacuum vapor deposition. In addition, they should ensure thermal stability with high glass transition temperature and thermal decomposition temperature, and they should have high electrochemical stability for long life of the product, and easily form an amorphous thin layer. Particularly, it is very important for them to have good adhesion with the material of other adjacent layers, along with difficulties in interlayer migration.

Representative examples for conventional electron transportation material include aluminum complexes such as tris(8-hydroxyquinoline)aluminum (III) (Alq), which had been used prior to the multilayer thin film OLED's disclosed by Kodak in 1987; and beryllium complexes such as bis(10-hydroxybenzo-[h]quinolinato)beryllium (Bebq), which was reported in the middle of 1990's in Japan [T. Sato et al., J. Mater. Chem. 10 (2000) 1151]. However, the limitation of the materials has come to the fore as OLED's have been practically used since 2002. Thereafter, many electron transportation materials of high performance have been investigated and reported to approach their practical use.

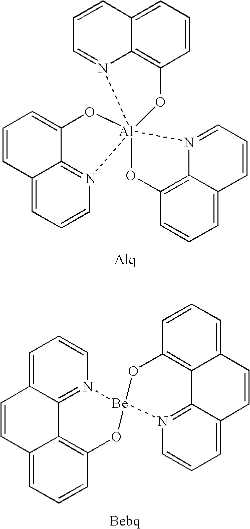

In the meanwhile, non-metal complex electon transportation materials of good features which have been reported up to the present include spiro-PBD [N. Jahansson et al., Adv. Mater. 10 (1998) 1136], PyPySPyPy [M. Uchida et al., Chem. Mater. 13 (2001) 2680] and TPBI [Y.-T. Tao et al., Appl. Phys. Lett. 77 (2000) 1575] of Kodak. However, there remain various needs for improvement in terms of electroluminescent properties and lifetime.

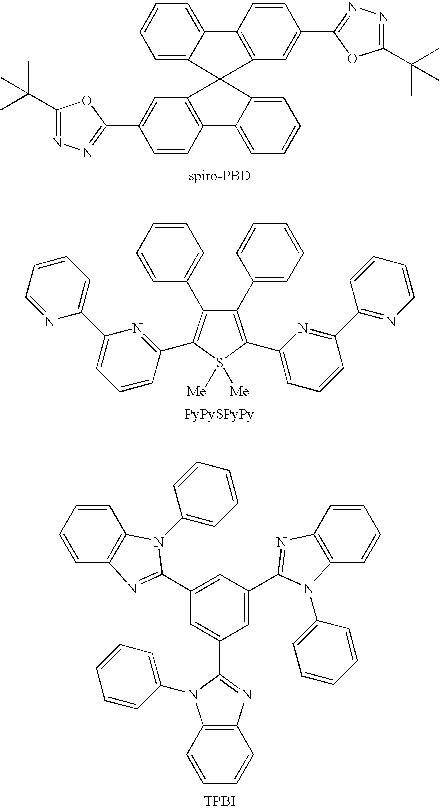

Particularly noticeable is that conventional electron transportation materials have only slightly improved operation voltage as compared to what was reported, or show the problem of considerable reduction of device operation lifetime. In addition, the materials exhibit adverse effects such as deviation in device lifetime for each color and deterioration of thermal stability. Up to the present, those adverse effects are in the way to achieve the objects such as reasonable power consumption and increased luminance, which have been the issues in manufacturing large-size OLED panels.

### DISCLOSURE

### Technical Problem

The object of the invention is to solve the problems described above, and to provide organic electroluminescent compounds with improved electroluminescent properties, excellent power efficiency property and operation lifetime of the device, as compared to that from conventional electron transportation materials. Another object of the invention is to provide an organic light emitting diode comprising said organic electroluminescent compound.

### Technical Solution

The present invention relates to organic electroluminescent compounds represented by Chemical Formula (1) and organic light emitting diodes comprising the same. Since the organic electrolumescent compounds according to the invention have excellent electroluminescent properties, power efficiency and life property of the device, OLED's having very good operation lifetime can be produced.

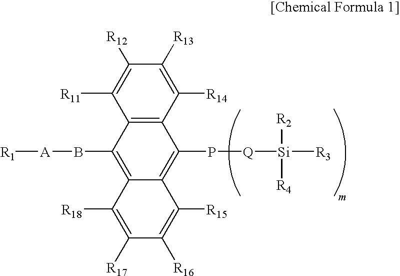

wherein, A, B, P and Q independently represent a chemical bond, or (C₆-C₃₀)arylene with or without one or more substituent(s) selected from a linear or branched and saturated or unsaturated (C₁-C₃₀)alkyl with or without halogen substituent(s), (C₆-C₃₀)aryl and halogen;

R₁ represents hydrogen, (C₆-C₃₀)aryl or

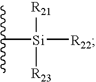

R₂, R₃ and R₄ independently represent a linear or branched and saturated or unsaturated (C₁-C₃₀)alkyl or (C₆-C₃₀)aryl;

R₁₁ through R₁₈, independently represent hydrogen, or a linear or branched and saturated or unsaturated (C₁-C₃₀)alkyl or (C₆-C₃₀)aryl;

R₂₁, R₂₂ and R₂₃ independently represent a linear or branched and saturated or unsaturated (C₁-C₃₀)alkyl or (C₆-C₃₀)aryl; and

m is an integer of 1 or 2;

provided that A, B, P and Q are not chemical bonds all at the same time; if both -A-B- and —P-Q- are phenylene, R₁ necessarily represents hydrogen; excluding both -A-B- and —P-Q-being spirobifluorenylenes, the arylene or aryl may be further substituted by a linear or branched and saturated or unsaturated (C₁-C₃₀)alkyl, (C₁-C₃₀)alkoxy, halogen, (C₂-C₁₂)cycloalkyl, phenyl, naphthyl or anthryl.

In Chemical Formula (1), R₁ represents hydrogen, phenyl, naphthyl, anthryl, biphenyl, phenanthryl, naphthacenyl, fluorenyl, 9,9-dimethyl-fluoren-2-yl, pyrenyl, phenylenyl, fluoranthenyl, trimethylsilyl, triethylsilyl, tripropylsilyl, tri(t-butyl)silyl, t-butyldimethylsilyl, triphenylsilyl or phenyldimethylsilyl; R₂, R₃ and R₄ independently represent methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl or fluorenyl; and R₁₁ through R₁₈ are independently selected from hydrogen, methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl and fluorenyl.

In the Chemical Formulas according to the present invention, it is referred to as ‘a chemical bond’ if A or B does not comprise any element but it is simply linked to R₁ or anthracene, or P or Q does not comprise any element but it is simply linked to Si or anthracene; but A, B, P and Q are not chemical bonds all at the same time. If both -A-B- and —P-Q- are phenylene, R₁ necessarily represents hydrogen; excluding both -A-B- and —P-Q- being spirobifluorenylenes.

In the organic electroluminescent compounds represented by Chemical Formula (1), -A-B- is selected from the following structures:

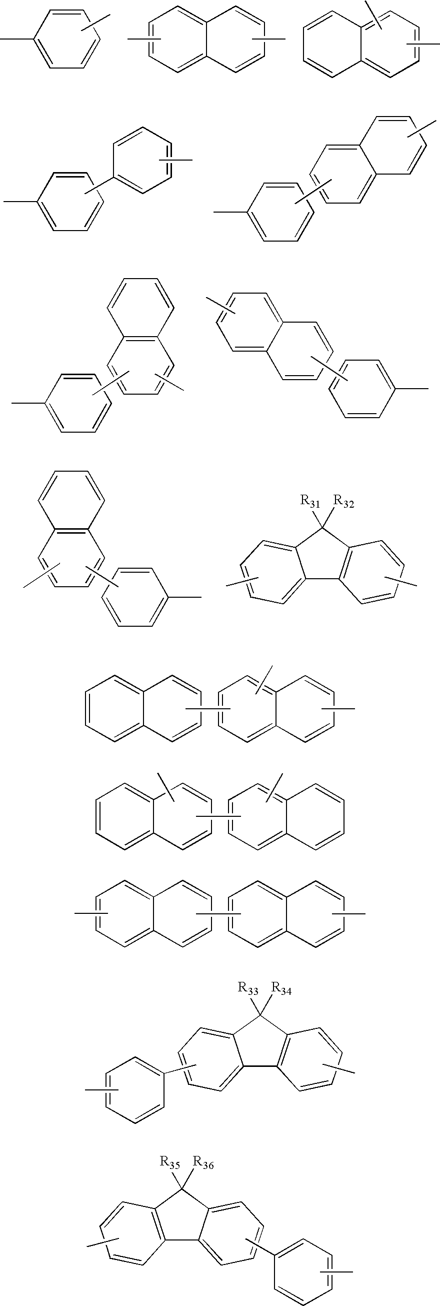

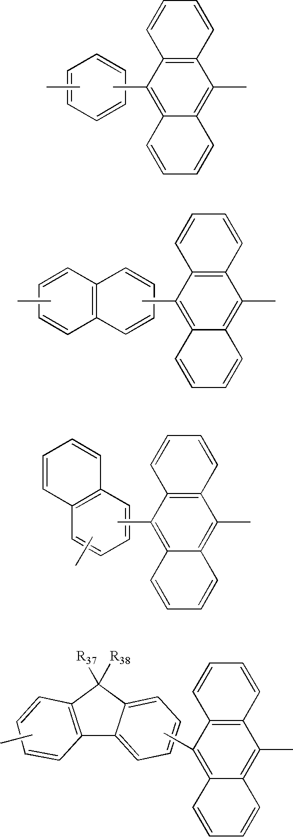

wherein, R₃₁, R₃₂, R₃₃, R₃₄, R₃₅, R₃₆, R₃₇ and R₃₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

In the organic electroluminescent compounds represented by Chemical Formula (1), —P-Q- is selected from the following structures:

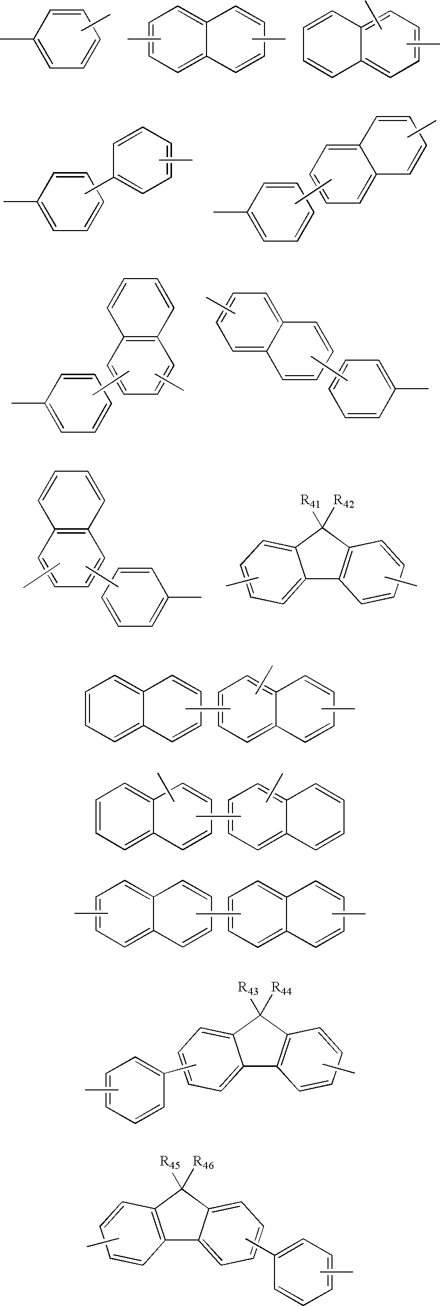

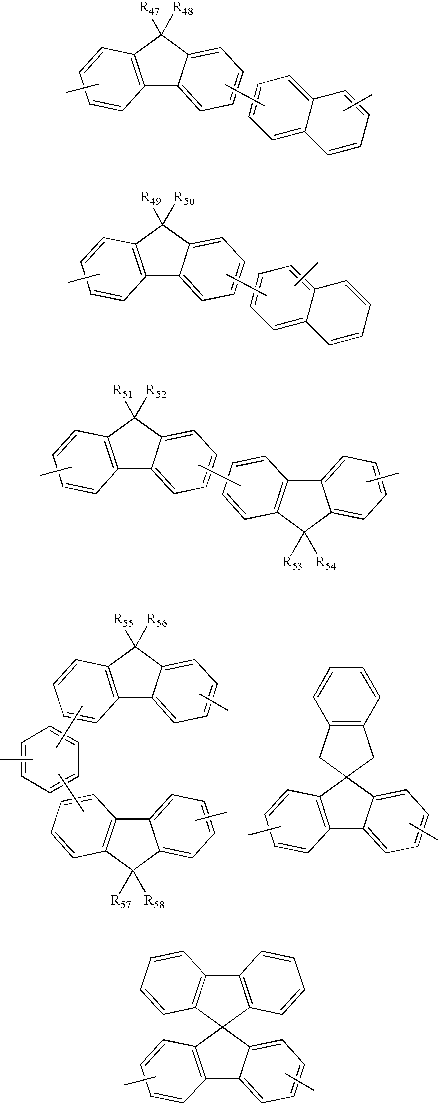

wherein, R₄₁ through R₅₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

The organic electroluminescent compounds according to the present invention may be specifically exemplified by the following compounds, but not restricted thereto.

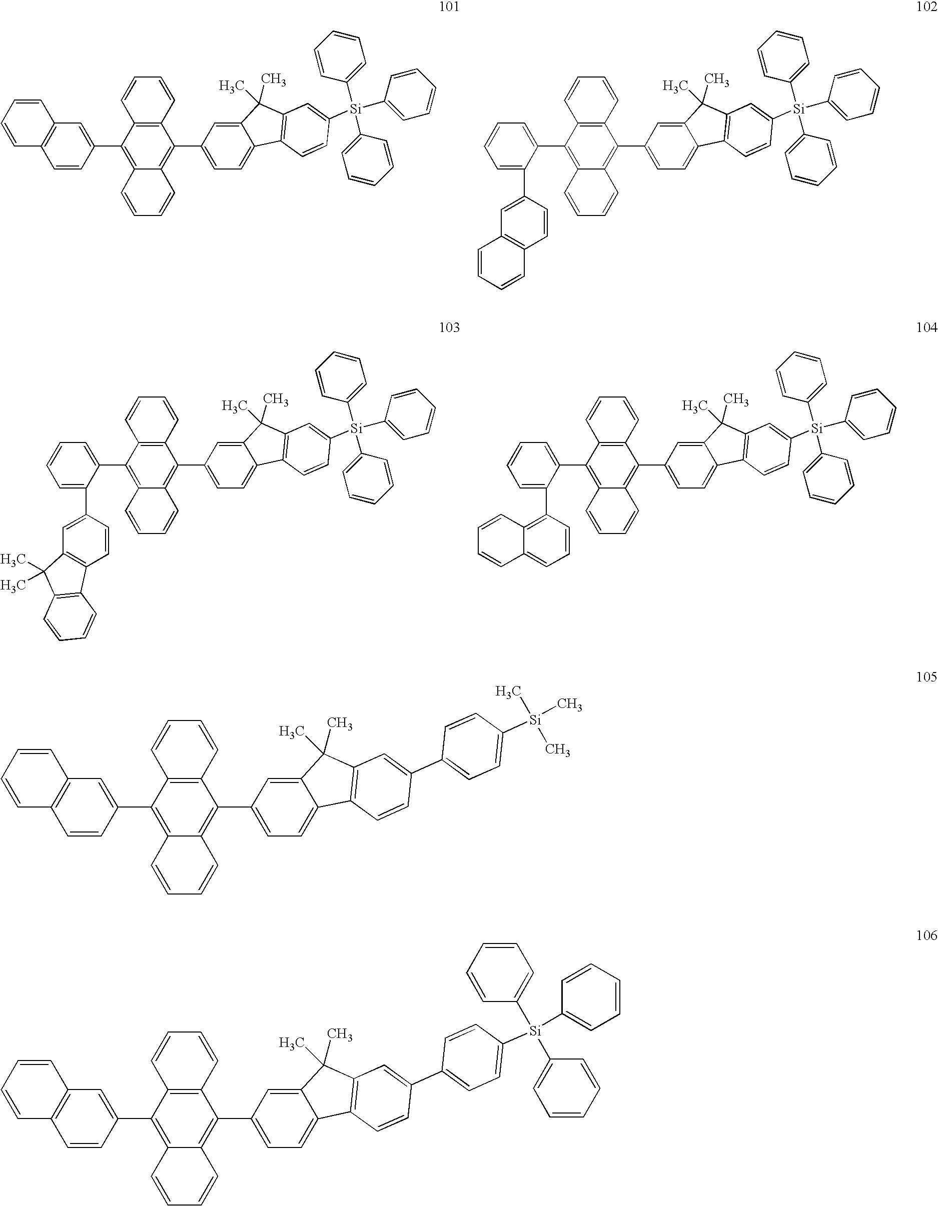

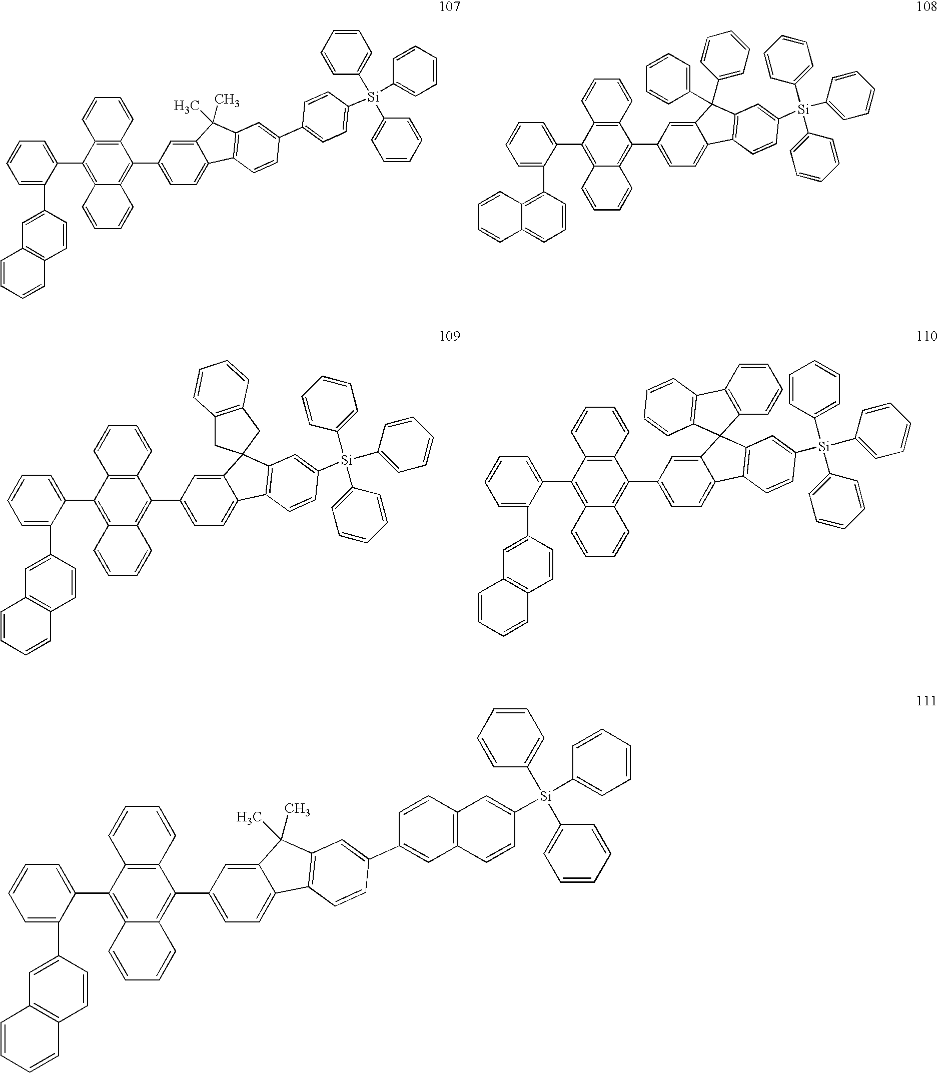

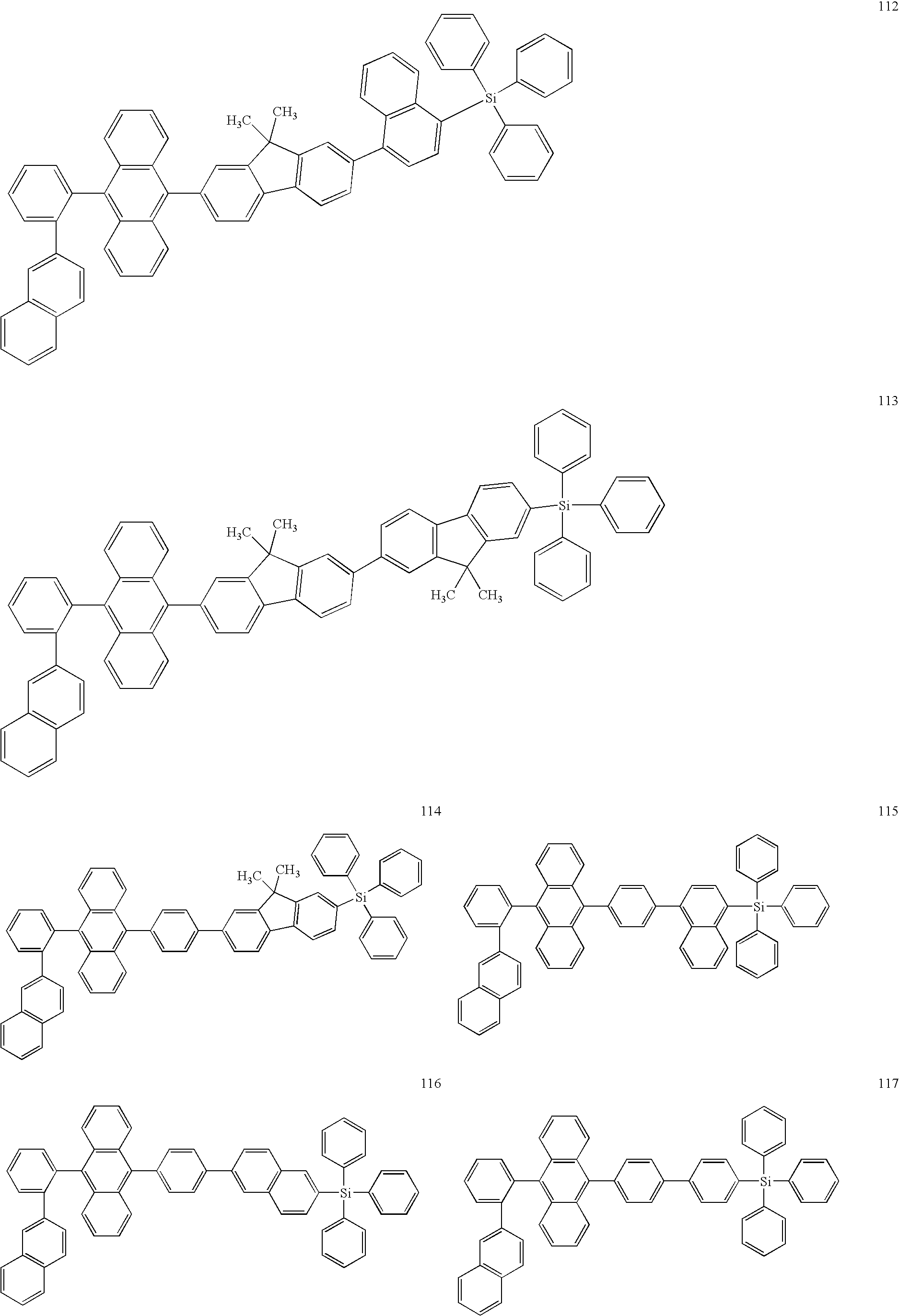

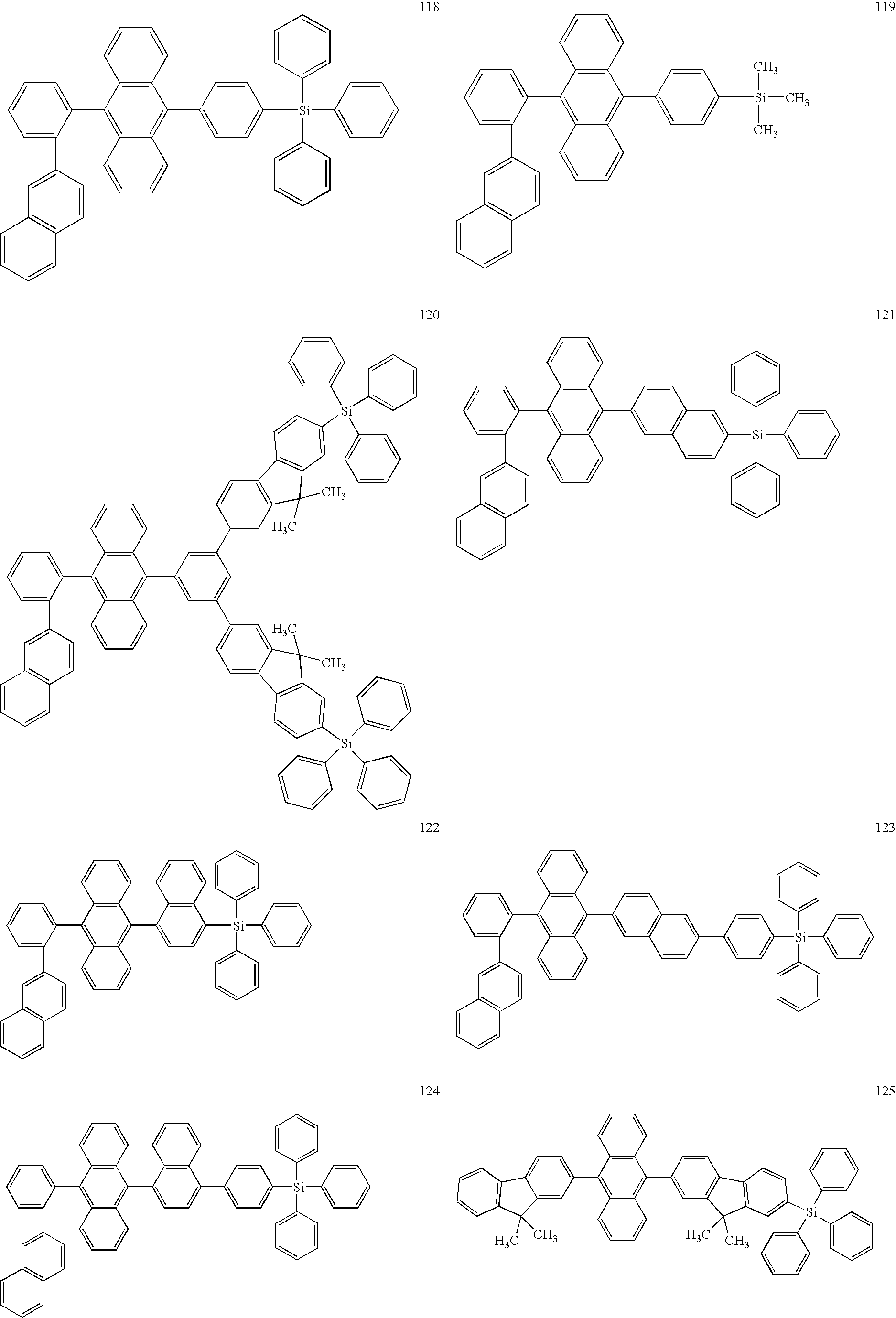

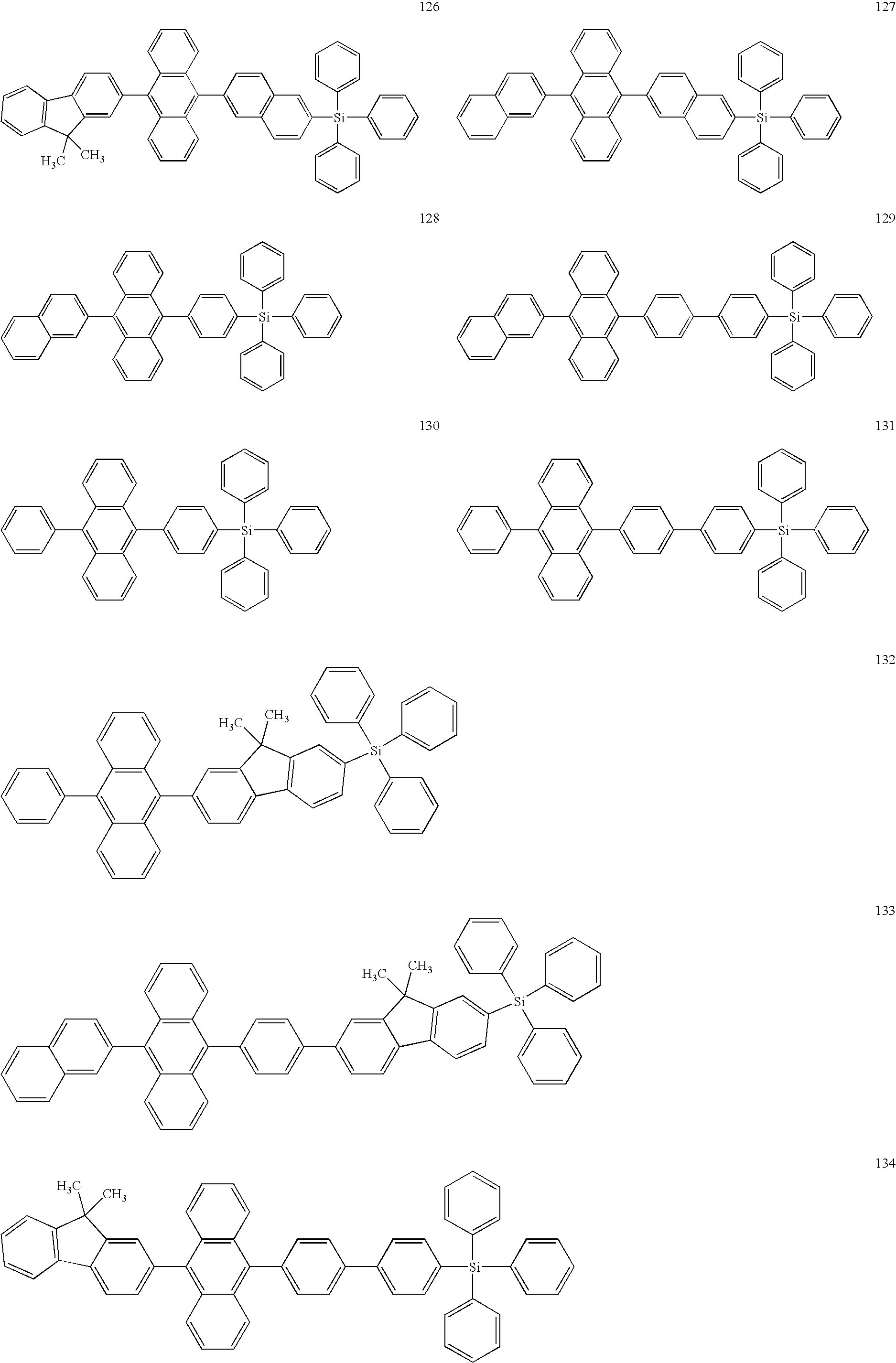

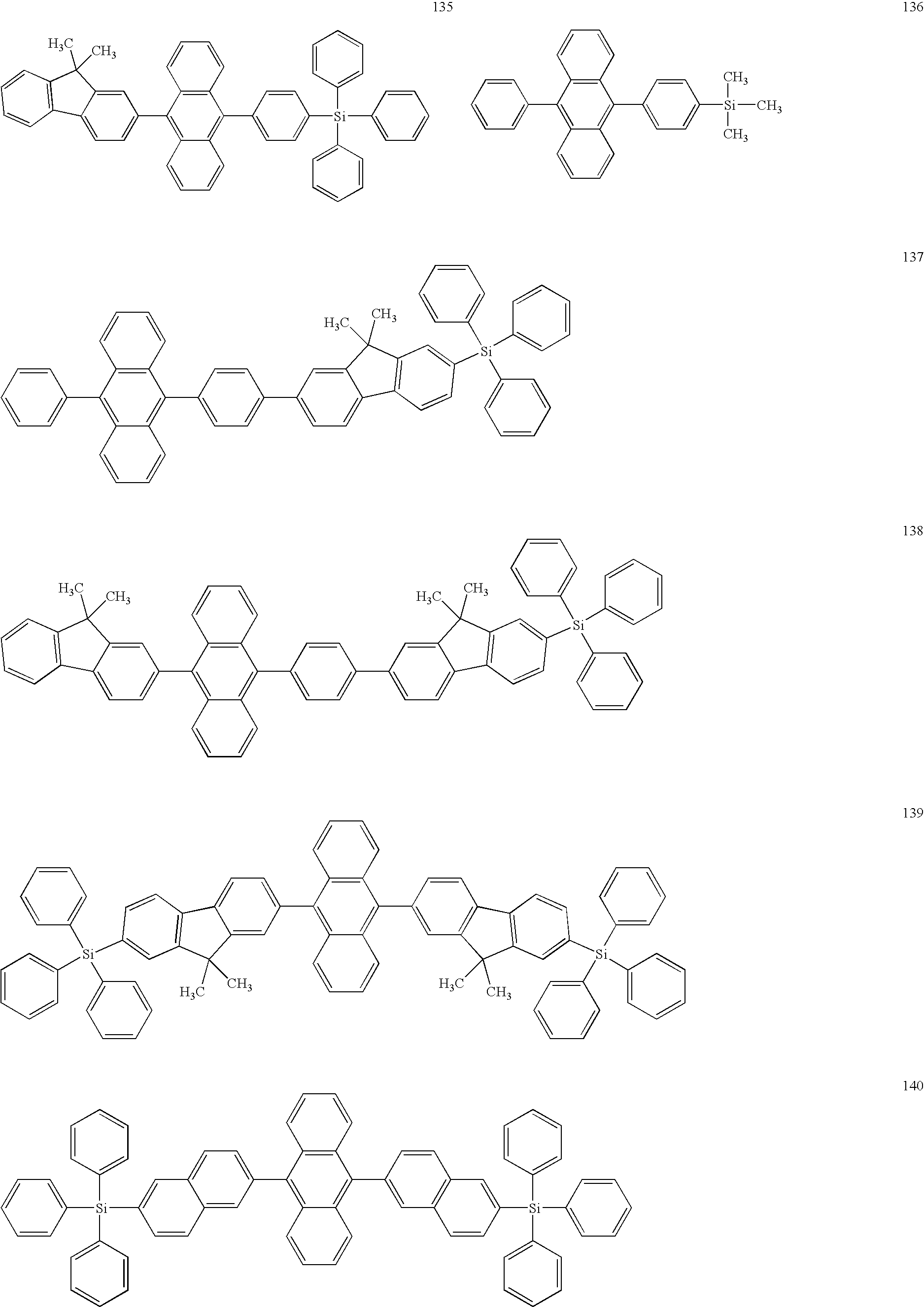

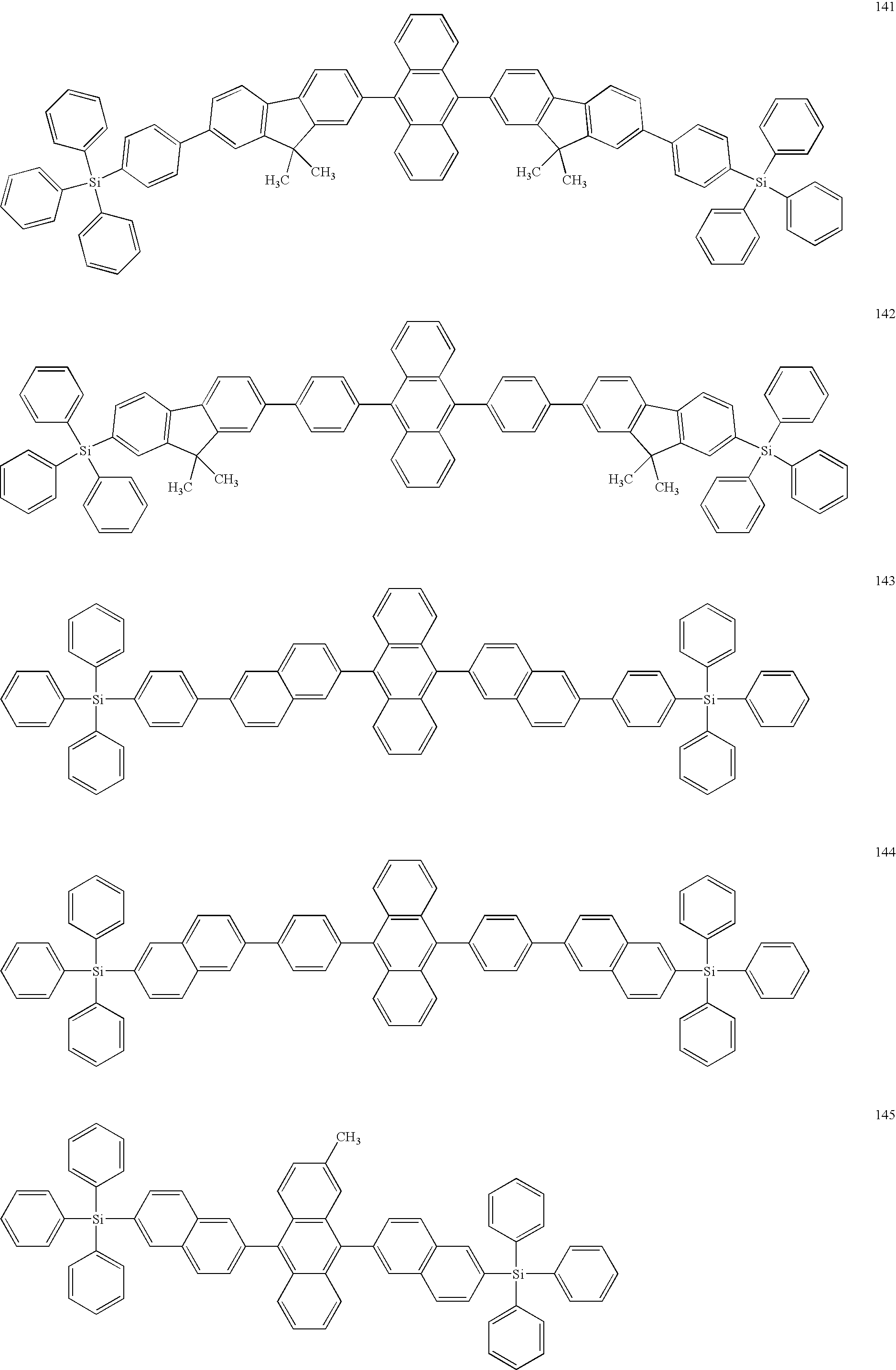

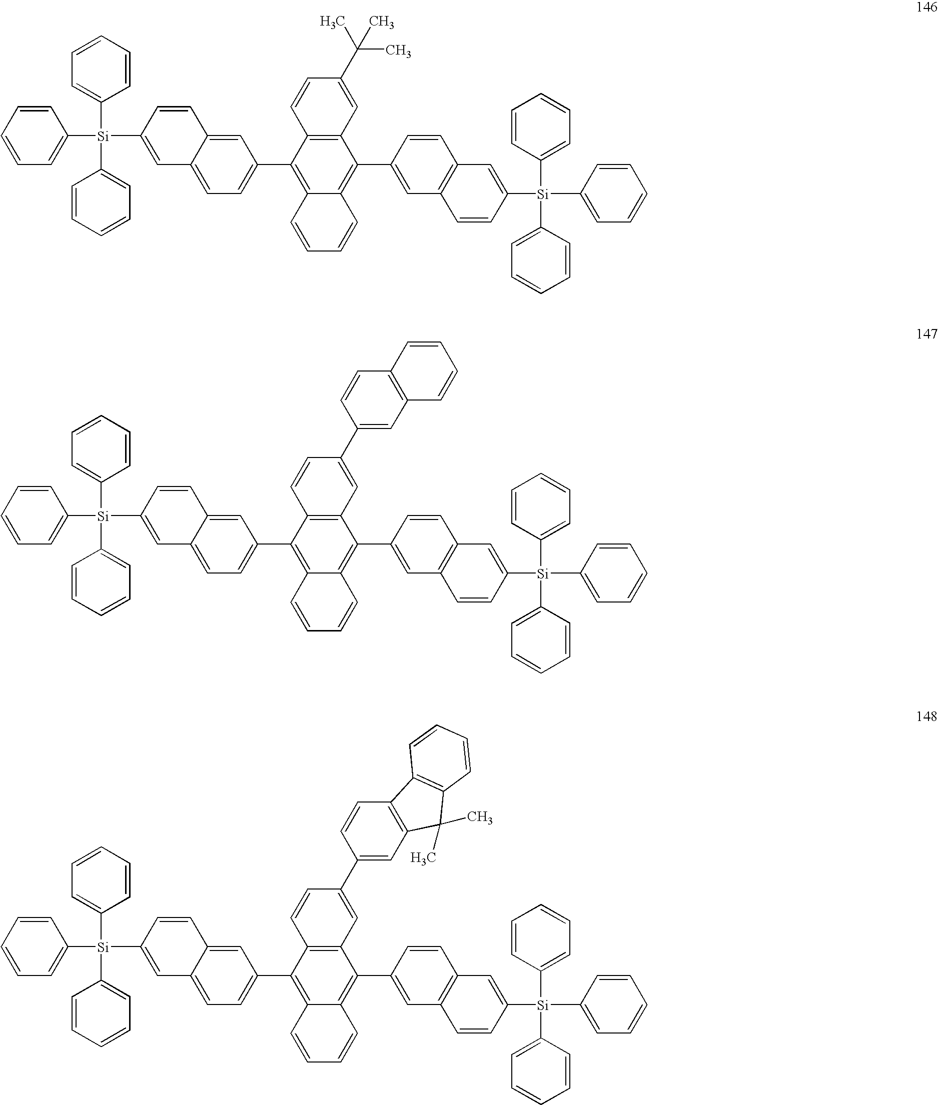

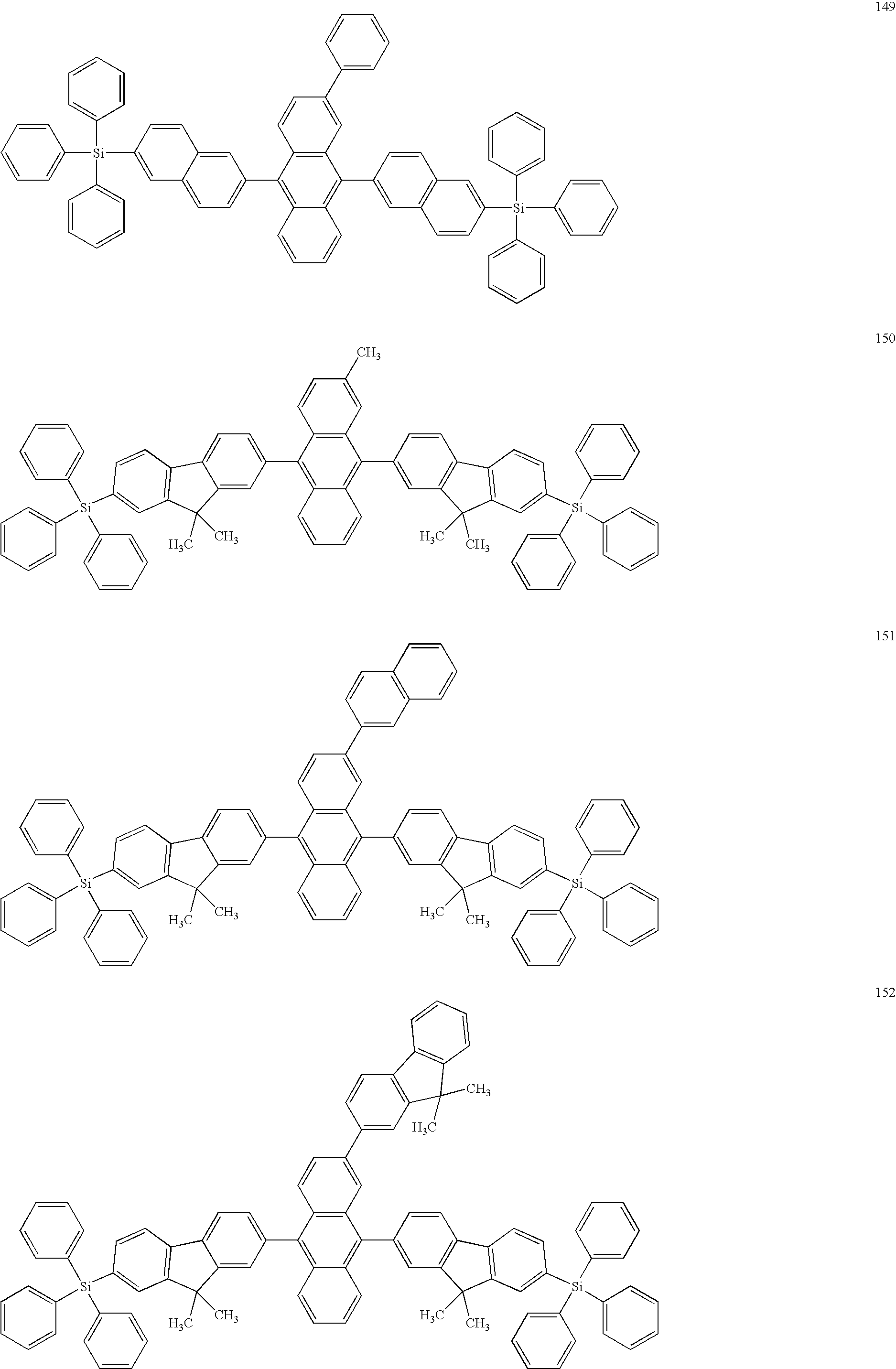

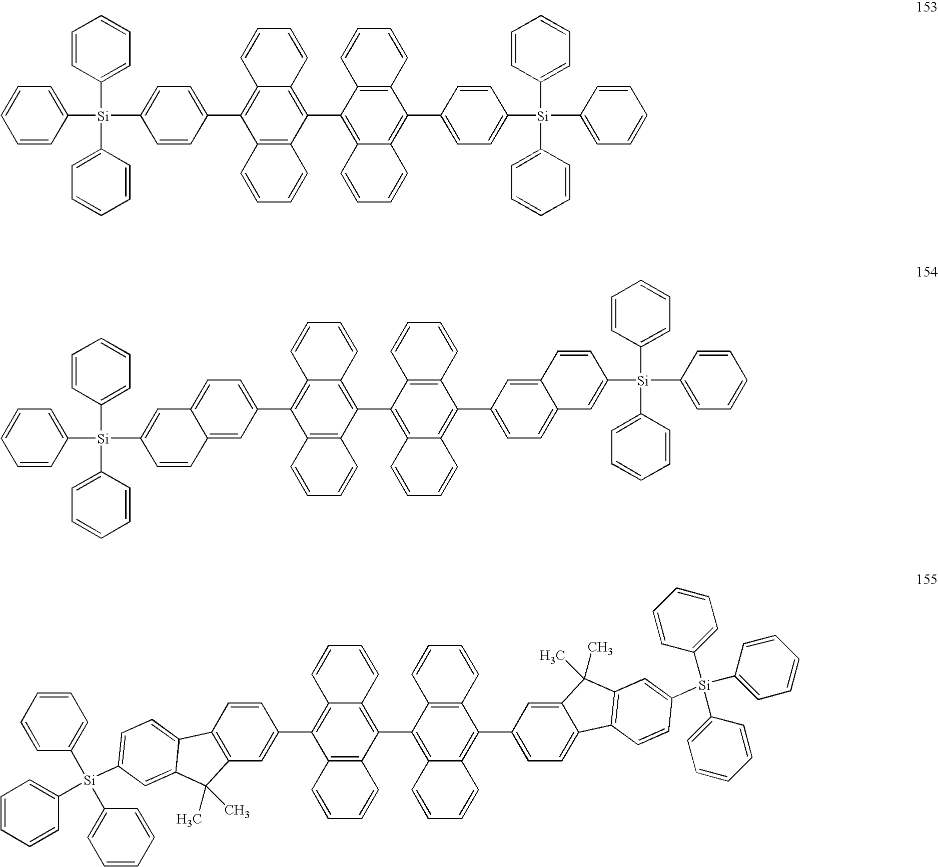

Further, the present invention relates to organic electroluminescent compounds represented by Chemical Formula (2):

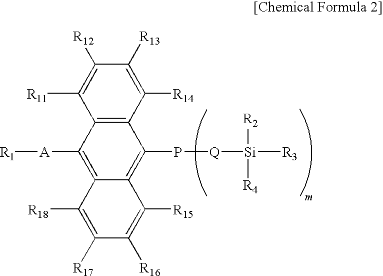

wherein, A represents phenylene, naphthylene or fluorenylene with or without linear or branched and saturated or unsaturated (C₁-C₃₀)alkyl substituent(s);

P and Q independently represent a chemical bond, or (C₆-C₃₀)arylene with or without one or more substituent(s) selected from a linear or branched and saturated or unsaturated (C₁-C₃₀)alkyl with or without halogen substituent(s), (C₆-C₃₀)aryl and halogen;

R₁ represents hydrogen, phenyl, naphthyl, anthryl, biphenyl, phenanthryl, naphthacenyl, fluorenyl or 9,9-dimethyl-fluoren-2-yl;

R₂, R₃ and R₄ independently represent a linear or branched and saturated or unsaturated (C₁-C₃₀)alkyl or (C₆-C₃₀)aryl;

R₁₁ through R₁₈ independently represent hydrogen, or a linear or branched and saturated or unsaturated (C₁-C₃₀)alkyl or (C₆-C₃₀)aryl;

m is an integer of 1 or 2; and

the arylene or aryl may be further substituted by a linear or branched and saturated or unsaturated (C₁-C₃₀)alkyl, (C₁-C₃₀)alkoxy, halogen, (C₃-C₁₂)cycloalkyl, phenyl, naphthyl or anthryl.

In the organic electroluminescent compounds represented by Chemical Formula (2), —P-Q- is selected from the following structures:

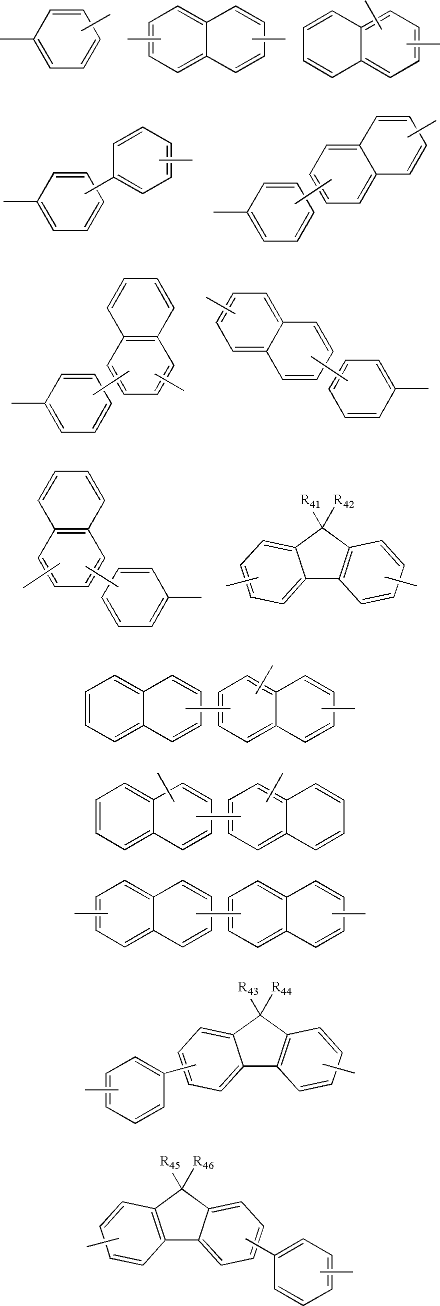

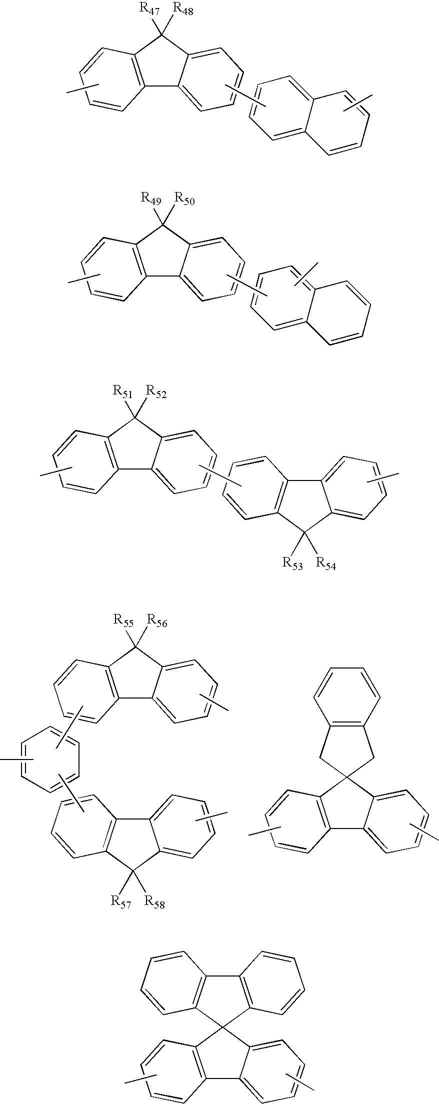

wherein, R₄₁ through R₅₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

In Chemical Formula (2), R₂, R₃ and R₄ independently represent methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl or fluorenyl; and R₁₁ through R₁₈ are independently selected from hydrogen, methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl and fluorenyl.

The organic electroluminescent compounds represented by Chemical Formula (2) according to the present invention may be specifically exemplified by the following compounds, but not restricted thereto.

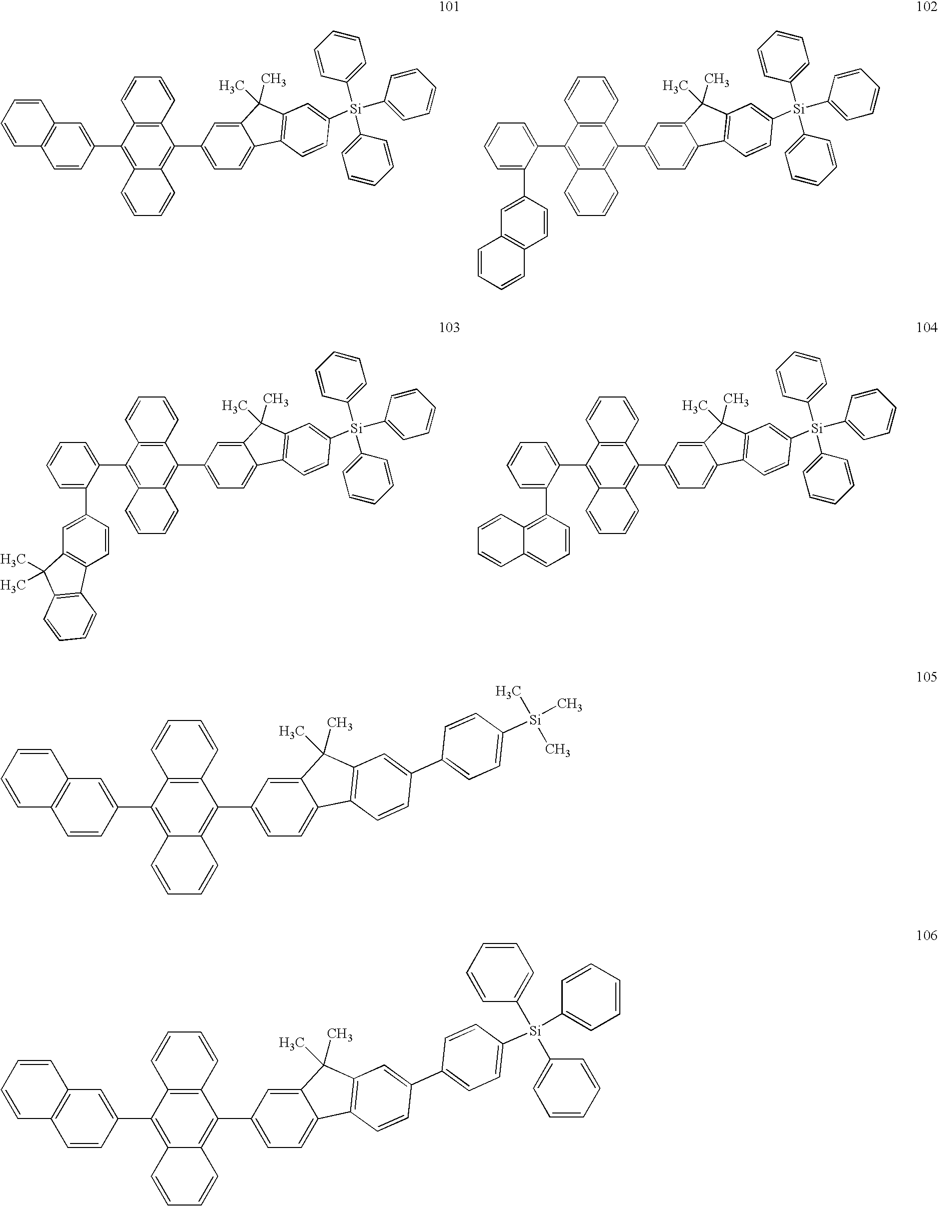

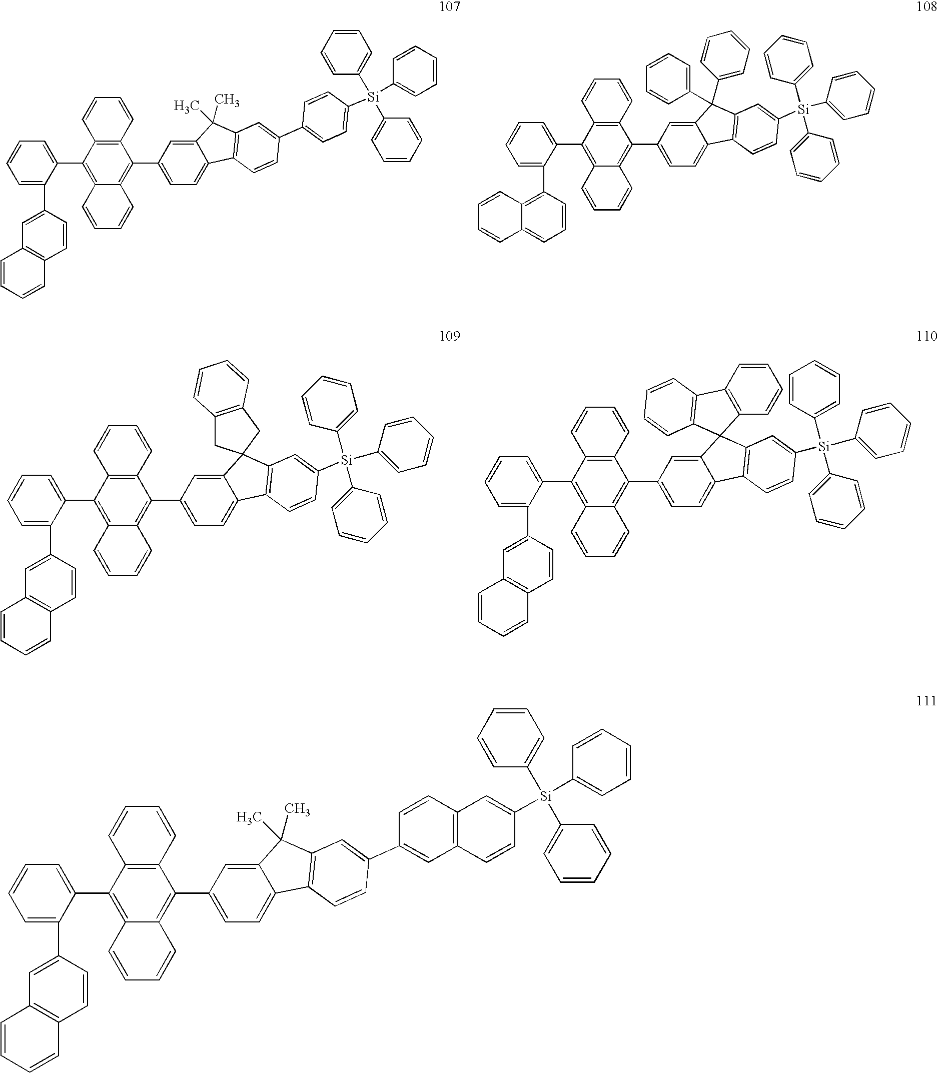

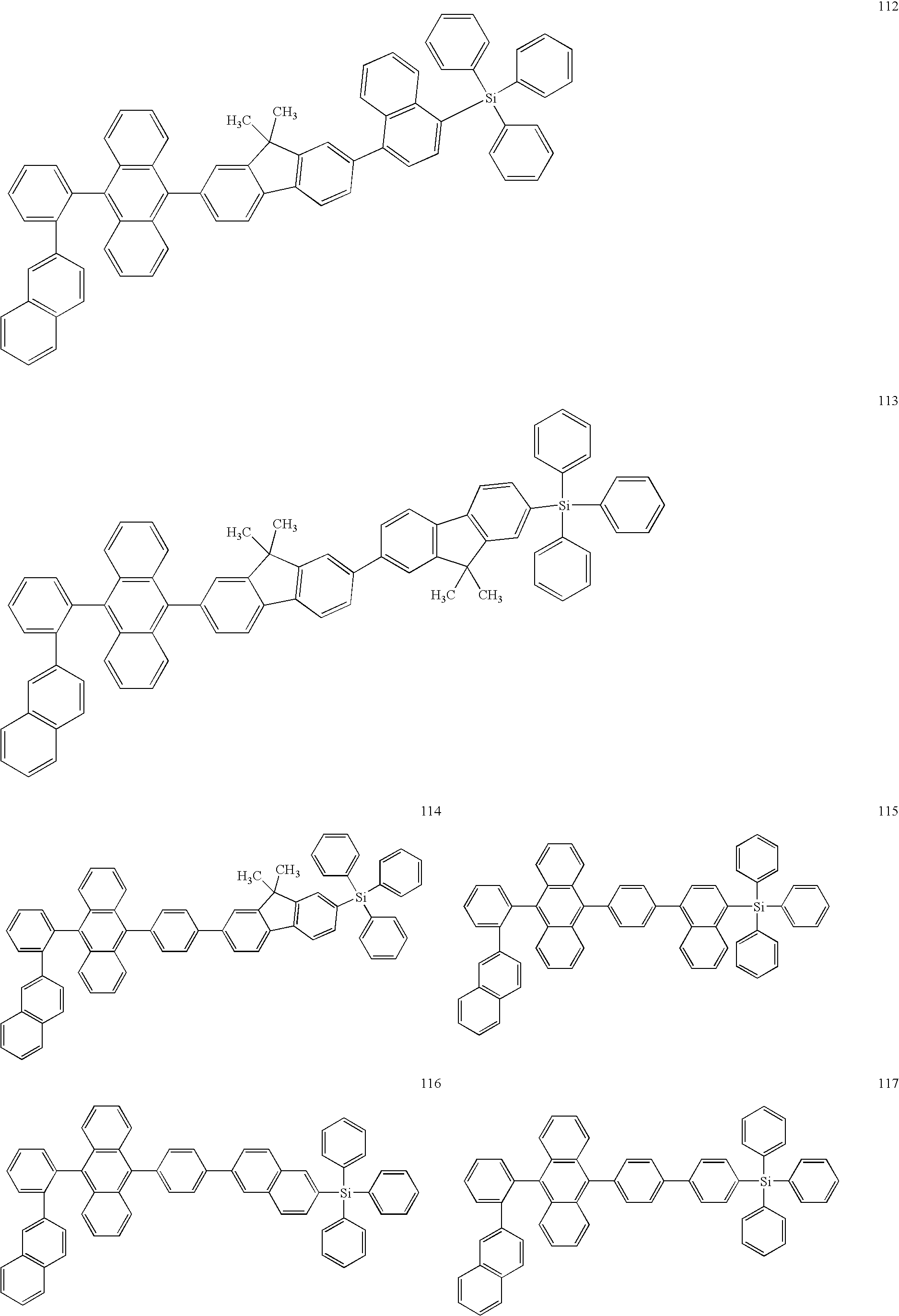

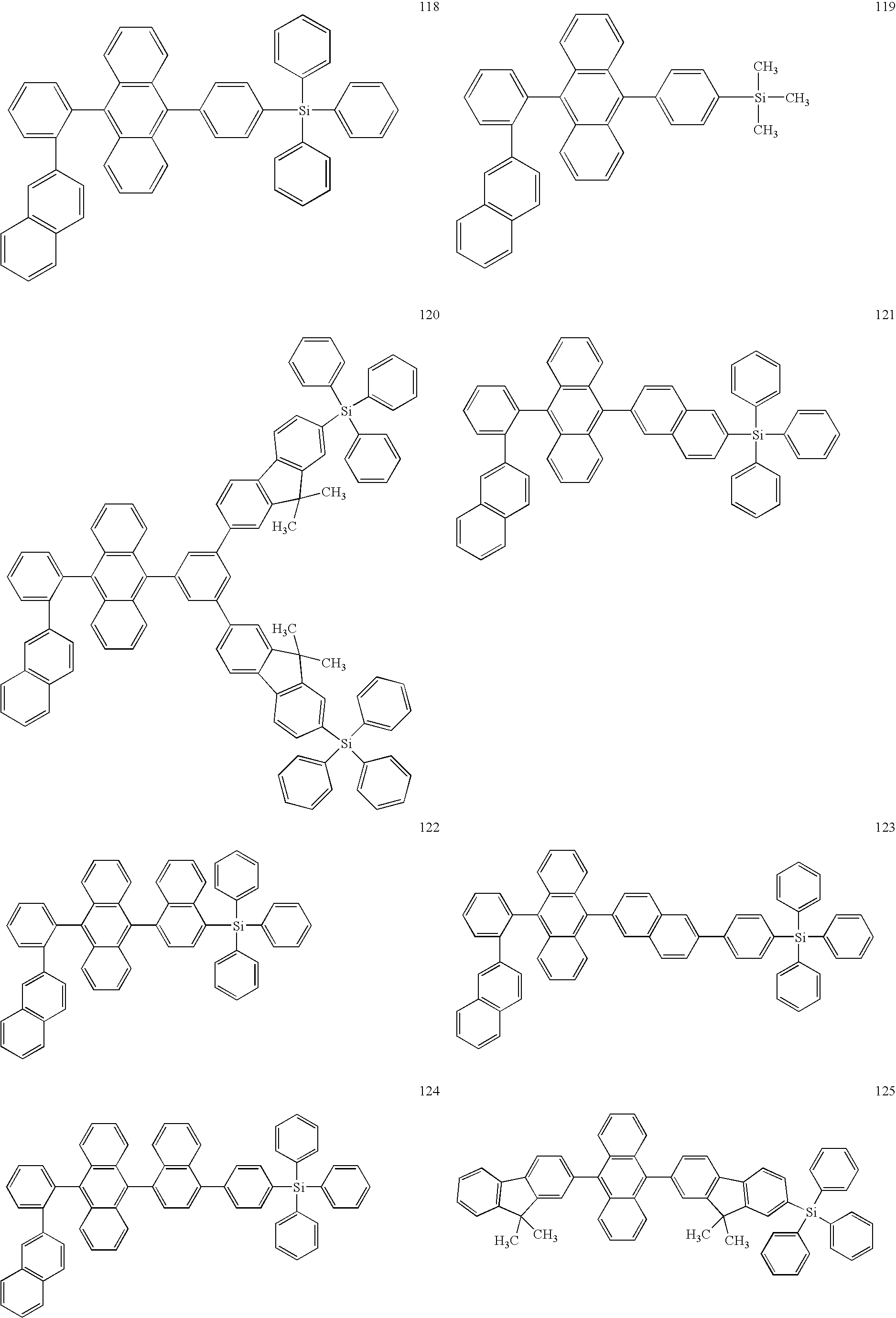

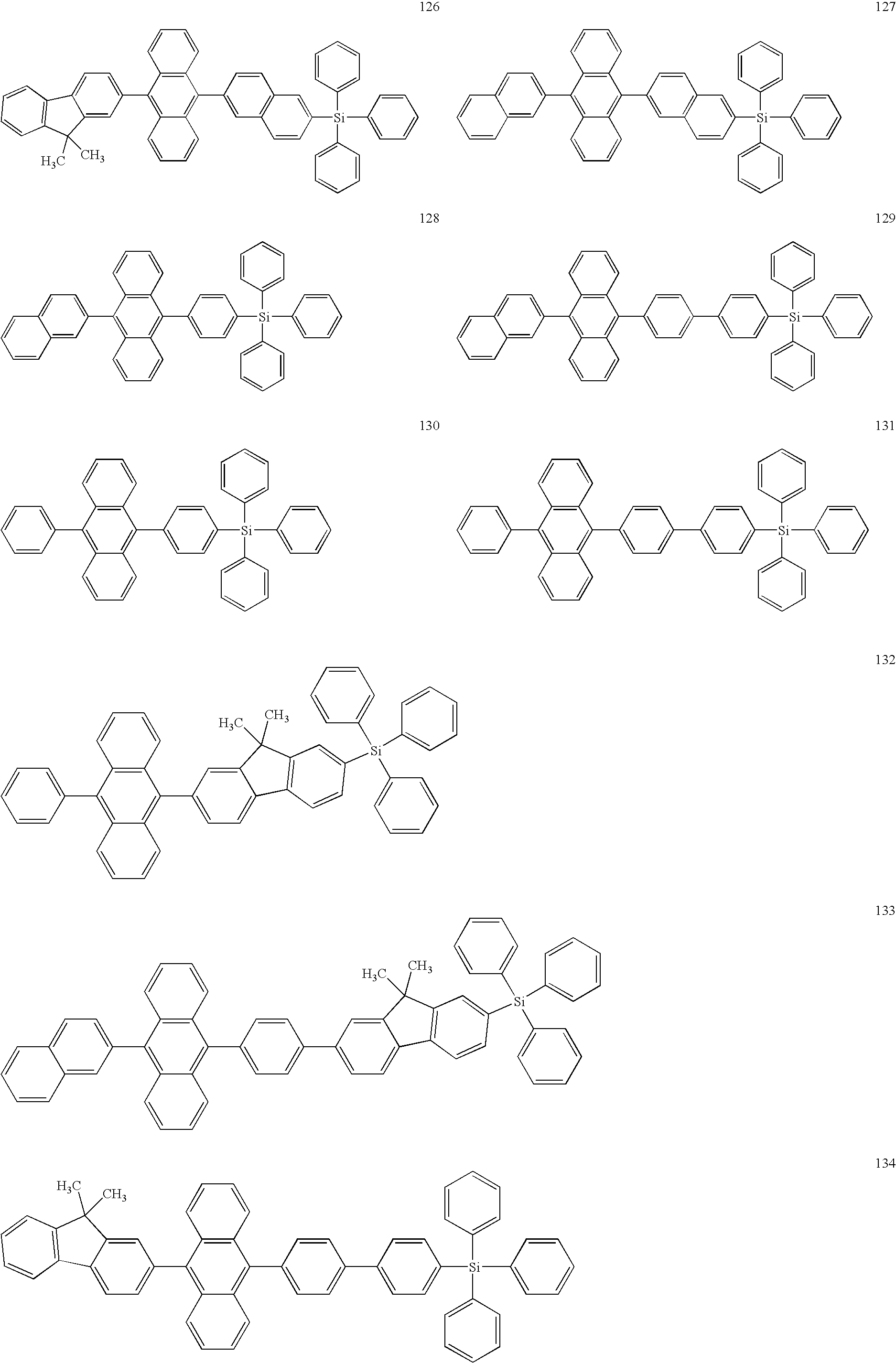

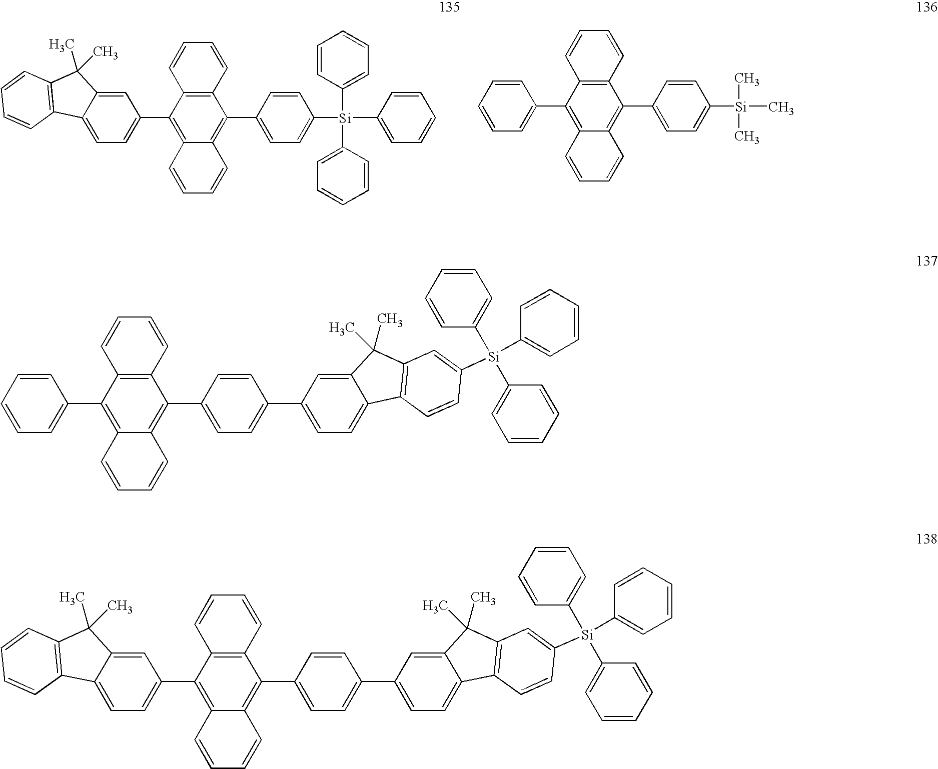

Further, the present invention relates to organic electroluminescent compounds represented by Chemical Formula (3):

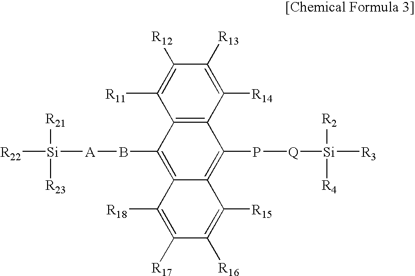

wherein,

A, B, P and Q independently represent a chemical bond, or phenylene, naphthylene, anthrylene or fluorenylene with or without one or more substituent(s) selected from a linear or branched and saturated or unsaturated (C₁-C₃₀)alkyl, (C₆-C₃₀)aryl and halogen, provided that A, B, P and Q are not chemical bonds all at the same time;

R₂, R₃ and R₄ independently represent a linear or branched and saturated or unsaturated (C₁-C₃₀)alkyl or (C₆-C₃₀)aryl;

R₁₁ through R₁₈ independently represent hydrogen, or a linear or branched and saturated or unsaturated (C₁-C₃₀)alkyl or (C₆-C₃₀)aryl;

R₂₁, R₂₂ and R₂₃ independently represent a linear or branched and saturated or unsaturated (C₁-C₃₀)alkyl or (C₆-C₃₀)aryl; and

the aryl may be further substituted by a linear or branched and saturated or unsaturated (C₁-C₃₀)alkyl, (C₁-C₃₀)alkoxy, halogen, (C₃-C₁₂)cycloalkyl, phenyl, naphthyl or anthryl.

In Chemical Formula (3), R₂, R₃ and R₄ independently represent methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl or fluorenyl; R₁₁ through R₁₆ independently represent hydrogen, methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl or fluorenyl; and R₂₁, R₂₂ and R₂₃ are independently selected from methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl and fluorenyl.

In the organic electroluminescent compounds represented by Chemical Formula (3), -A-B- is selected from the following structures:

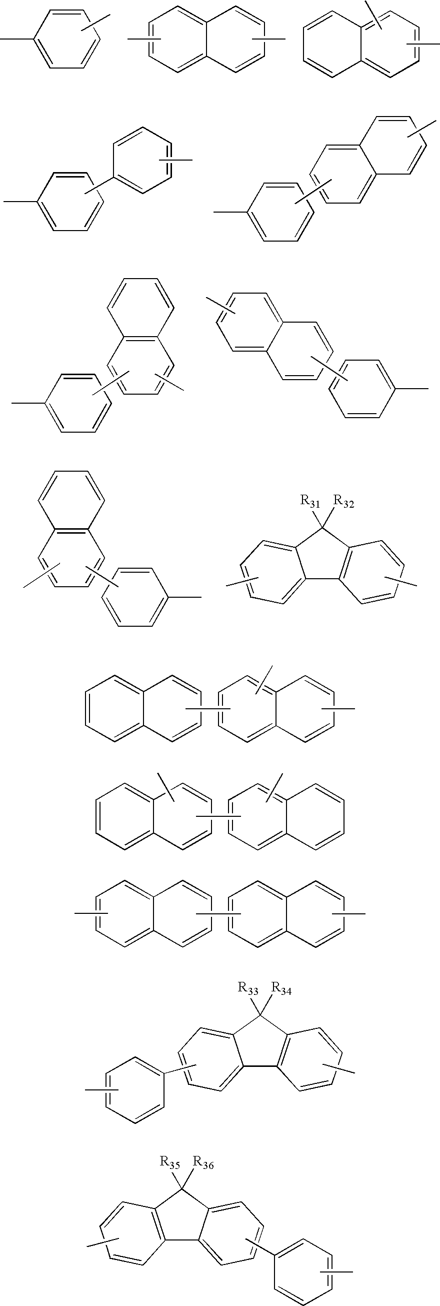

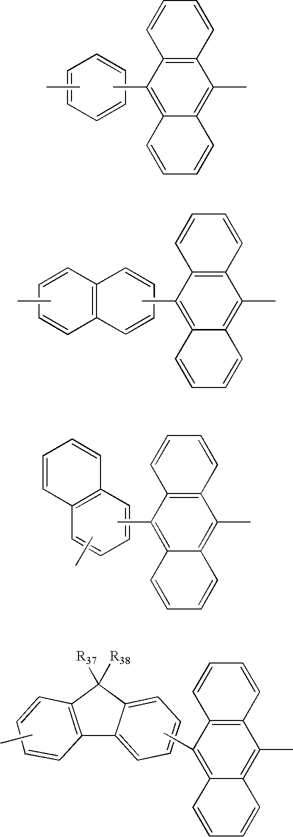

wherein, R₃₁, R₃₂, R₃₃, R₃₄, R₃₅, R₃₆, R₃₇ and R₃₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

In the organic electroluminescent compounds represented by Chemical Formula (3), —P-Q- is selected from the following structures:

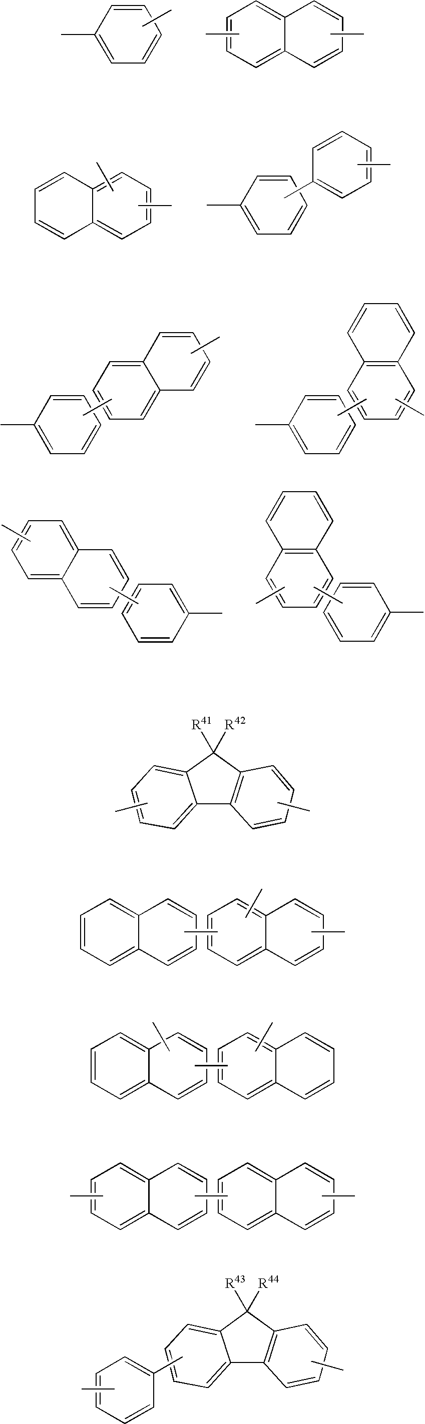

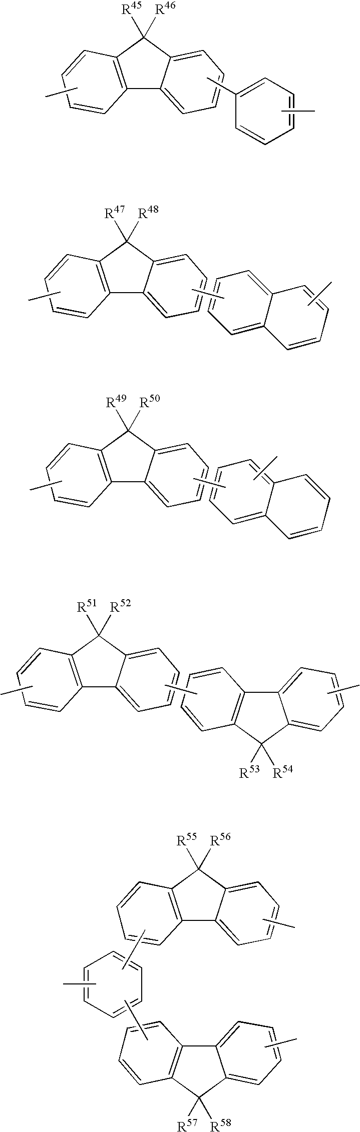

wherein, R₄₁ through R₅₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

The organic electroluminescent compounds represented by Chemical Formula (3) according to the present invention may be specifically exemplified by the following compounds, but not restricted thereto.

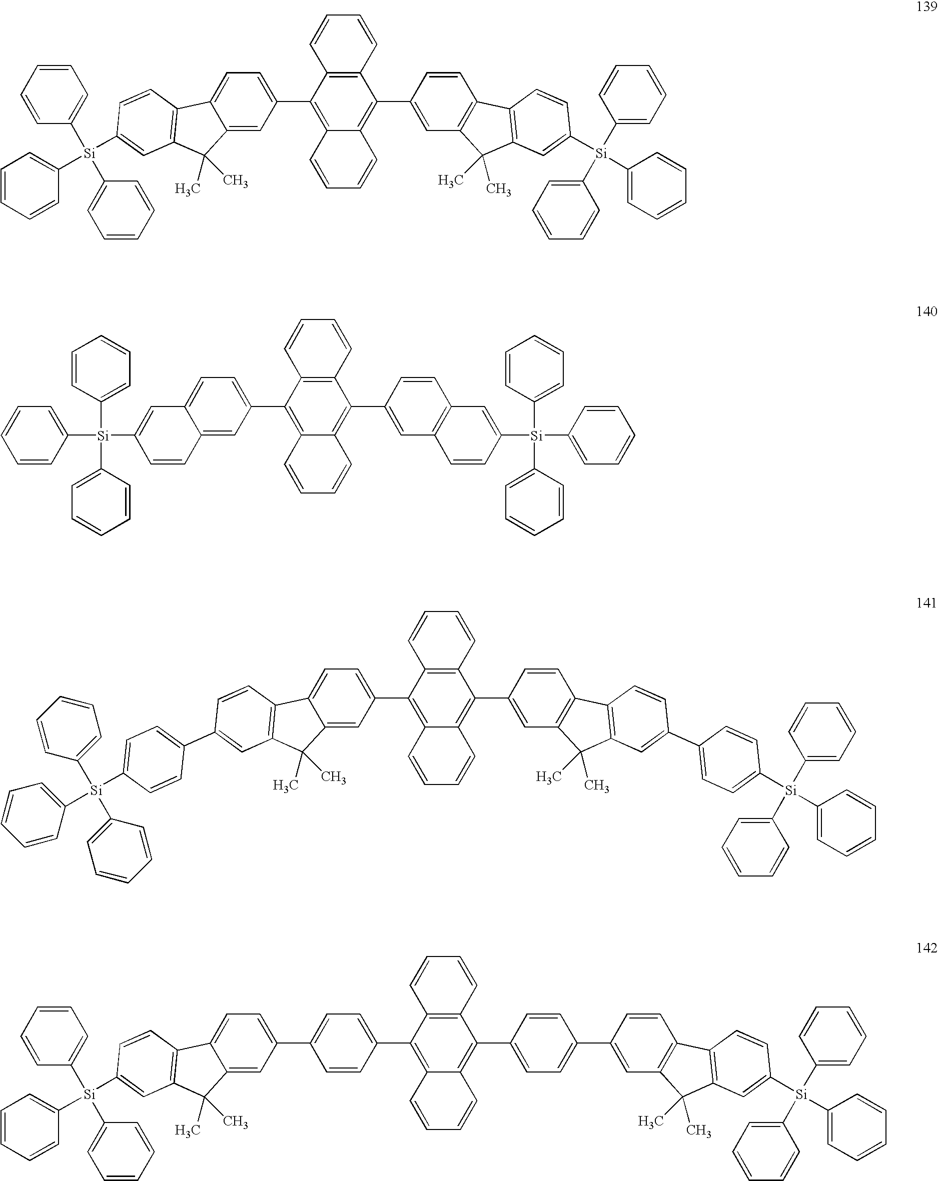

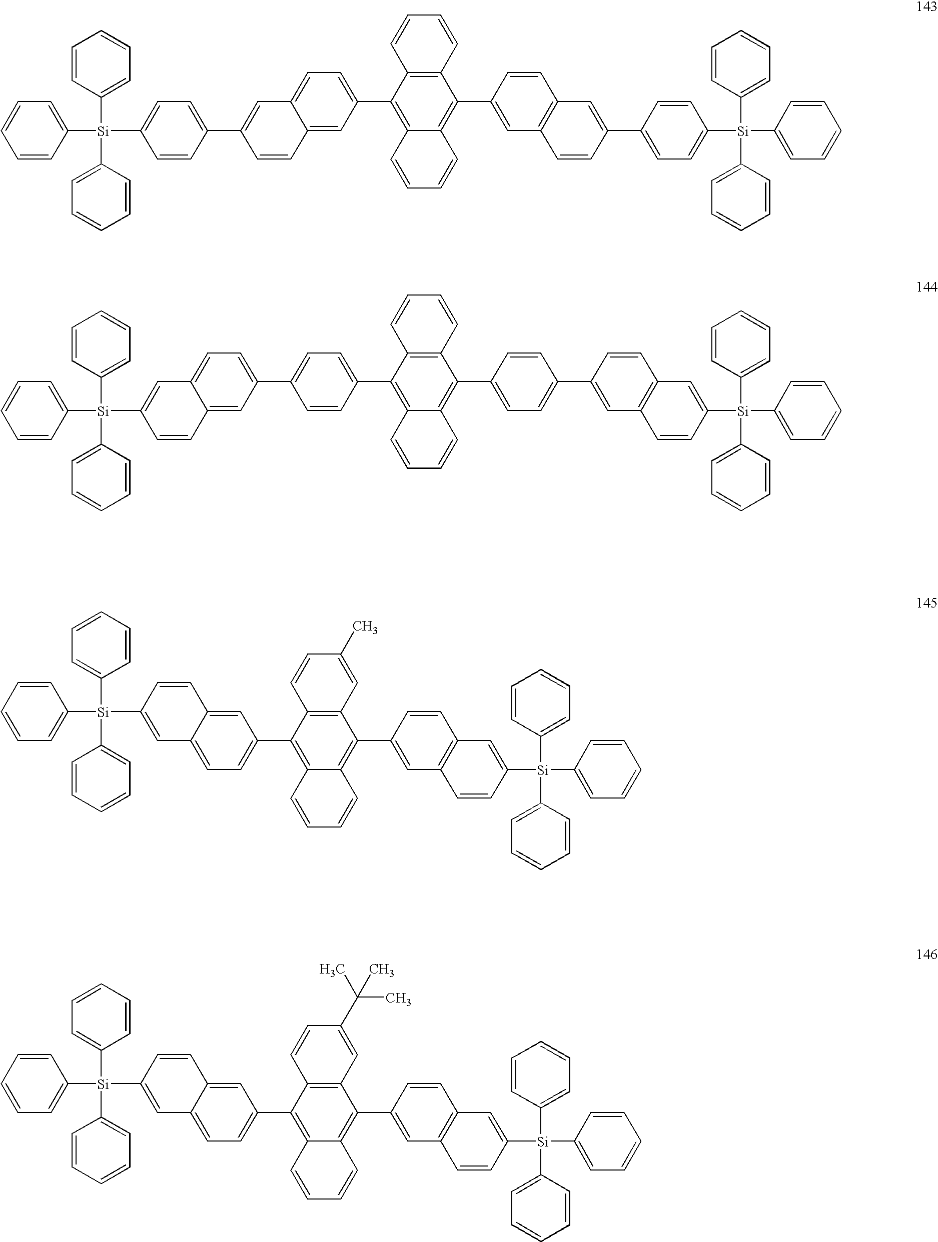

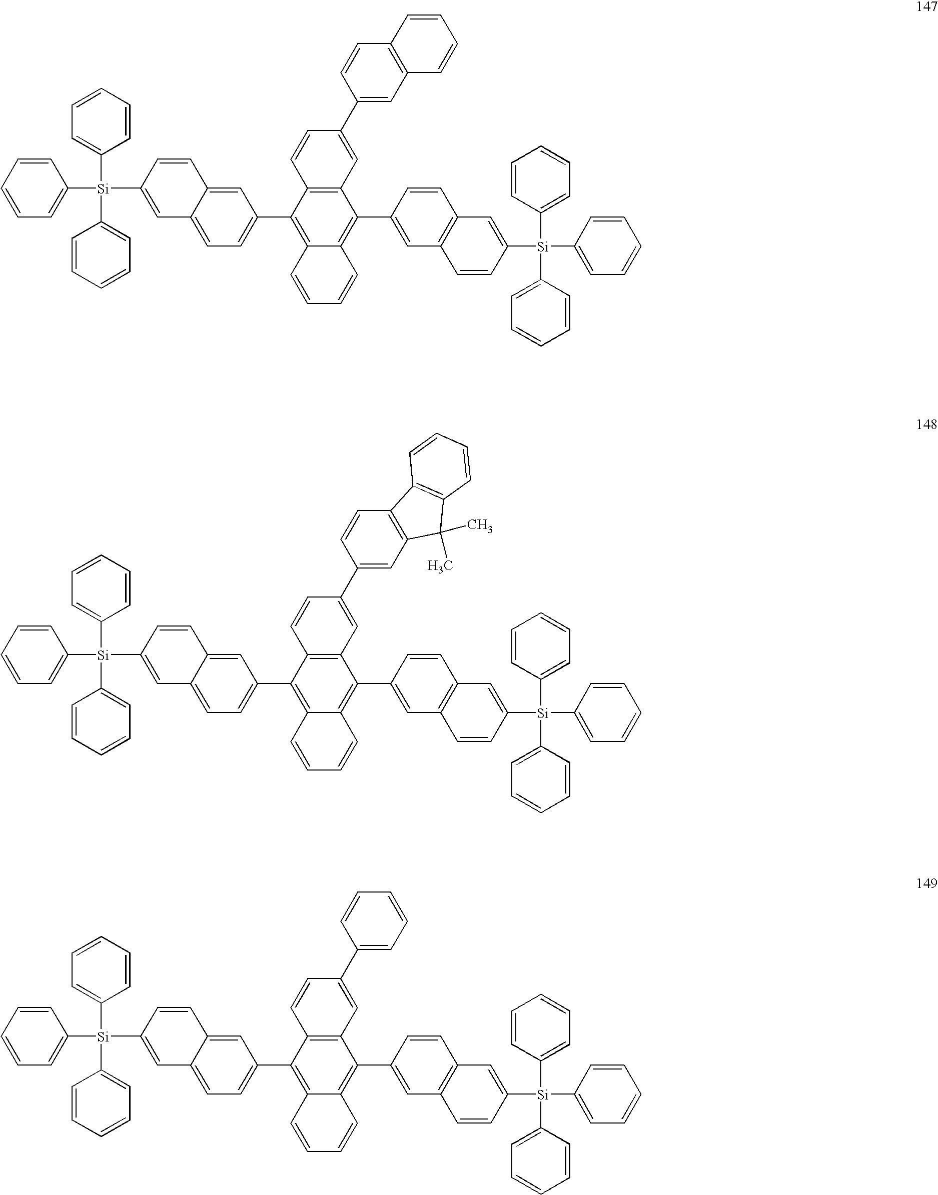

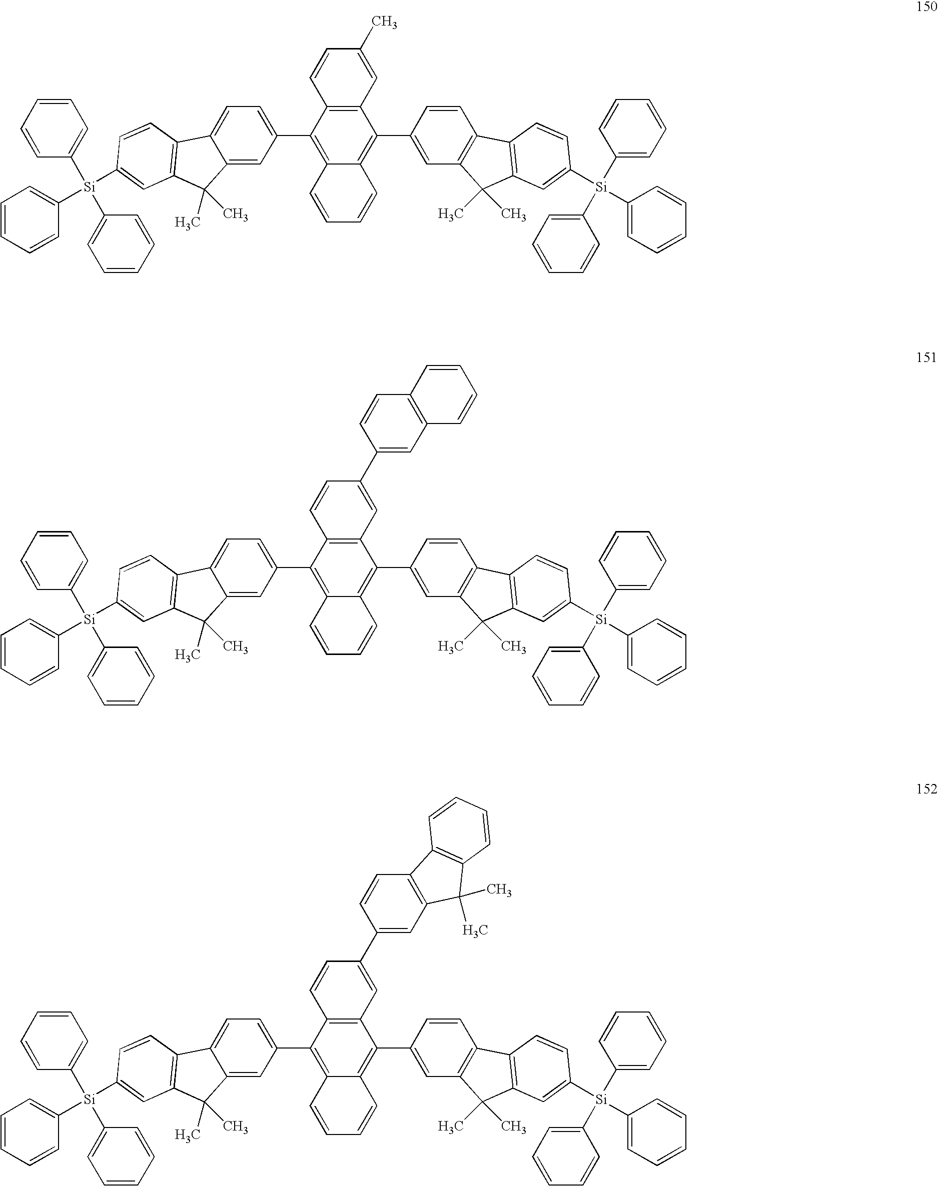

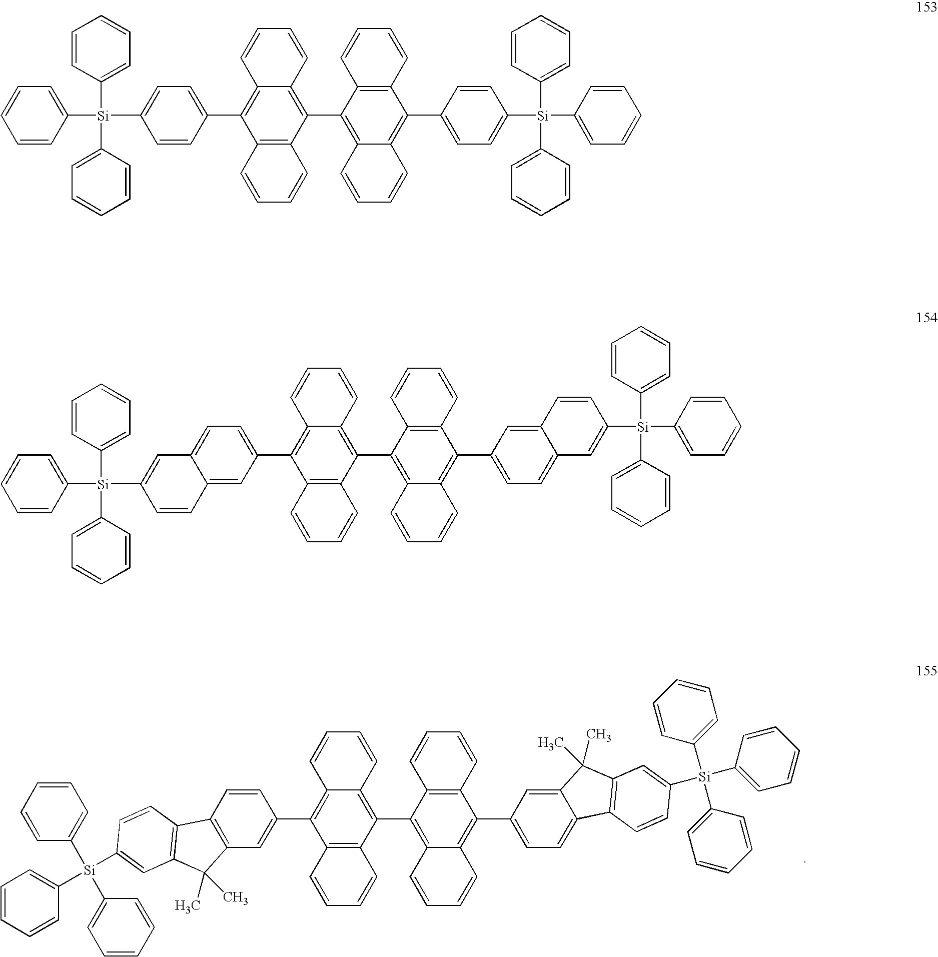

The organic light emitting diode according to the present invention is particularly characterized by employing the organic electroluminescent compound according to the invention as an electron transportation material.

The organic electroluminescent compound according to the present invention can be prepared via a reaction route illustrated by Reaction Scheme (1):

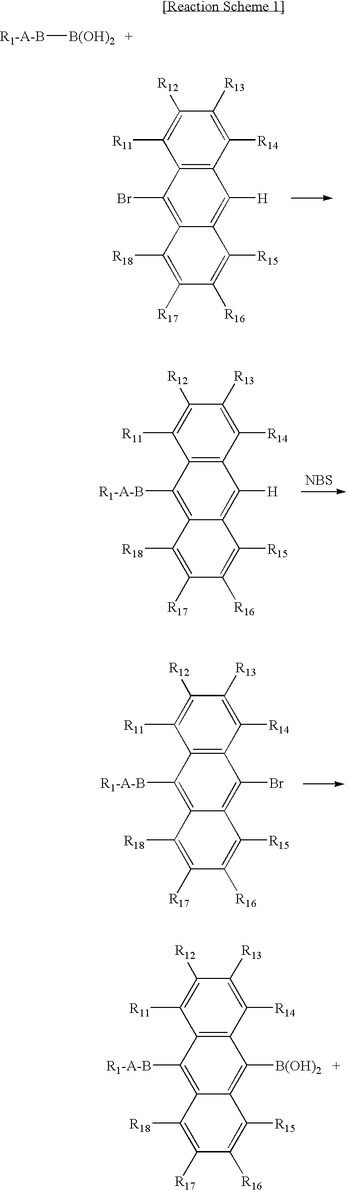

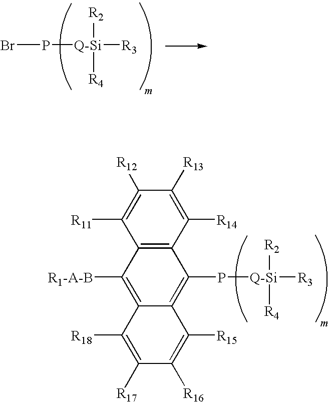

wherein, A, B, P, Q, R₁, R₂, R₃, R₄, R₁₁, R₁₂, R₁₃, R₁₄, R₁₅, R₁₆, R₁₇, R₁₈, R₂₁, R₂₂, R₂₃ and m are defined as in Chemical Formula (1).

### BRIEF DESCRIPTION OF DRAWINGS

FIG. 1 is a cross-sectional view of an OLED;

FIG. 2 shows luminous efficiency curve of Example 10 (Compound 110);

FIG. 3 shows luminance-voltage curve comparing Example 10 (Compound 110) and Comparative Example 1; and

FIG. 4 shows power efficiency-luminance curve comparing Example 10 (Compound 110) and Comparative Example 1.

### DESCRIPTION OF SYMBOLS OF SIGNIFICANT PARTS OF THE DRAWINGS

1: Glass
2: Transparent electrode
3: Hole injection layer
4: Hole transportation layer
5: Electroluminescent layer
6: Electron transportation layer
7: Electron injection layer
8: Al cathode

### ADVANTAGEOUS EFFECTS

Since the organic electrolumescent compounds according to the invention have good luminous efficiency and life property as an electroluminescent material, OLED's having very good operation lifetime can be produced.

### BEST MODE

The present invention is further described with respect to the novel organic electroluminescent compounds according to the invention, processes for preparing the same and the electroluminescent properties of the device employing the same, by referring to Preparation Examples and Examples, which are provided for illustration only but are not intended to be restrictive in any way.

### PREPARATION EXAMPLES

### Preparation Example 1

### Preparation of Compound (102)

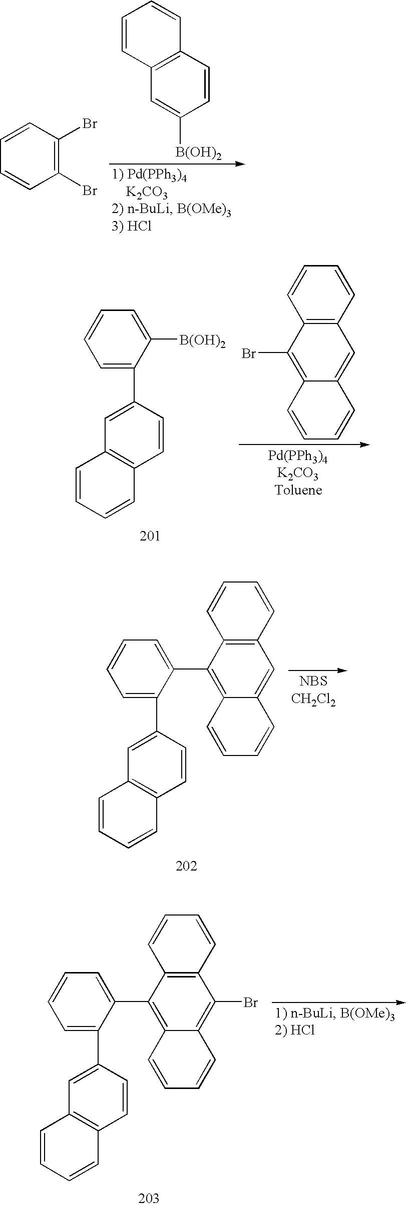

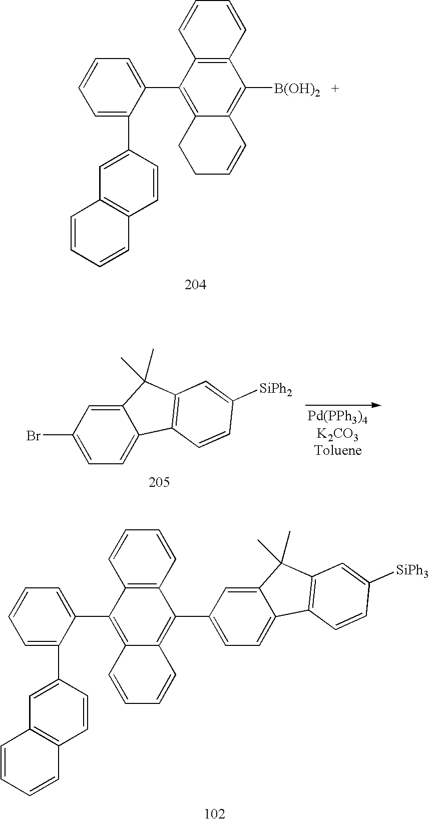

### Preparation of Compound (201)

A flask was charged with 1,2-dibromobenzene (100.0 g, 423.9 mmol), 2-naphthaleneboronic acid (80.2 g, 466. 3 mmol), toluene (1000 mL) and tetrakis(triphenylphosphine)palladium (Pd(PPh₃)₄) (24.5 g, 21.2 mmol), and the mixture was stirred under argon atmosphere. Aqueous potassium carbonate solution (300 mL) was then added dropwise thereto, and the resultant mixture was heated under reflux for 4 hours with stirring. The reaction was quenched by adding distilled water (2000 mL), and the reaction mixture was extracted with ethyl acetate (1000 mL). The organic extract was dried over anhydrous magnesium sulfate, filtered and concentrated under reduced pressure. Purification via silica gel column chromatography (ethyl acetate:hexane=1:50) gave 1-bromo-2-(2-naphthyl)benzene (63.59 g, 224.7 mmol, yield: 53.0%).

A 1 L round bottomed flask was charged with 1-bromo-2-(2-naphthyl)benzene (42.0 g, 148.5 mmol) and tetrahydrofuran (1000 mL), and n-BuLi (1.6 M in hexane) (89.0 mL, 222.5 mmol) was added dropwise thereto at −78° C. After stirring the mixture at the same temperature for 1 hour, trimethylborate (24.8 mL, 222.5 mmol) was added dropwise to the reaction mixture, and the temperature was raised to room temperature. The reaction mixture was stirred for 12 hours, and when the reaction was completed, 1M hydrochloric acid solution (500 mL) was added thereto, and the resultant mixture was stirred for 5 hours. Organic extract obtained from extraction with distilled water (500 mL) and ethyl acetate (600 mL) was dried over anhydrous magnesium sulfate, filtered and concentrated under reduced pressure. Recrystallization from ethyl acetate (80 mL) and methanol (600 mL) gave Compound (201) (27.28 g, 110.0 mmol, yield: 74.1%).

### Preparation of Compound (202)

A 500 mL round bottomed flask was charged with Compound (201) (27.28 g, 110.0 mmol), 9-bromoanthracene (28.16 g, 88.0 mmol), toluene (500 mL) and tetrakis(triphenylphosphine)palladium (Pd(PPh₃)₄) (2.45 g, 2.05 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (600 mL) was added to the reaction mixture, which was then extracted with ethyl acetate (400 mL). The organic extract was dried over anhydrous magnesium sulfate, filtered and concentrated under reduced pressure. Purification via silica gel column chromatography (dichloromethane:hexane=1:15) gave Compound (202) (25.20 g, 66.32 mmol, yield: 75.4%).

### Preparation of Compound 203

A 500 mL round bottomed flask was charged with Compound (202) (35.20 g, 92.62 mmol), N-bromosuccinimide (18.13 g, 101.9 mmol) and dichloromethane (500 mL), and the mixture was stirred at room temperature for 12 hours. When the reaction was completed, the solvent was removed under reduced pressure. Recrystallization from dichloromethane (100 mL) and hexane (500 mL) gave Compound (203) (34.51 g, 75.33 mmol, yield: 81.3%).

### Preparation of Compound (204)

A 500 mL round bottomed flask was charged with Compound (203) (42.56 g, 92.62 mmol) and tetrahydrofuran (1000 mL), and n-BuLi (1.6 M in hexane) (55.57 mL, 138.9 mmol) was added dropwise thereto at −78° C. After stirring the mixture at the same temperature for 1 hour, trimethylborate (15.49 mL, 138.9 mmol) was added dropwise to the reaction mixture, and the temperature was raised to room temperature. The reaction mixture was stirred for 12 hours, and when the reaction was completed, 1M hydrochloric acid solution (500 mL) was added thereto, and the resultant mixture was stirred for 5 hours. Organic extract obtained from extraction with distilled water (500 mL) and ethyl acetate (400 mL) was dried over anhydrous magnesium sulfate, filtered and concentrated under reduced pressure. Recrystallization from ethyl acetate (50 mL) and methanol (600 mL) gave Compound (204) (30.43 g, 71.78 mmol, yield: 77.5%).

### Preparation of Compound (102)

A 500 mL round bottomed flask was charged with Compound (204) (30.43 g, 71.78 mmol), Compound (205) (30.43 g, 57.42 mmol), toluene (500 mL) and tetrakis(triphenylphosphine)palladium (Pd(PPh₃)₄) (4.15 g, 3.59 mmol), and the mixture was stirred under argon atmosphere. Aqueous potassium carbonate solution (200 mL) was then added dropwise thereto, and the resultant mixture was heated under reflux for 4 hours with stirring. When the reaction was completed, distilled water (600 mL) was added to the reaction mixture, which was then extracted with ethyl acetate (500 mL). The organic extract obtained was dried over anhydrous magnesium sulfate, filtered and concentrated under reduced pressure. Purification via silica gel column chromatography (dichloromethane:hexane=1:10) and recrystallization from hexane gave Compound (102) (35.78 g, 43.11 mmol, yield: 75.1%) as pale yellow product.

¹H NMR (400 MHz, CDCl₃): δ=7.94 (d, 1H), 7.92 (d, 1H), 7.89 (s, 1H), 7.84 (s, 1H), 7.79 (s, 1H), 7.75 (d, 1H), 7.68-7.65 (m, 7H), 7.61 (d, 1H), 7.56-7.53 (m, 9H), 7.38-7.35 (m, 9H), 7.33-7.27 (m, 8H), 1.65 (s, 6H)

MS/FAB C₆₃H₄₆Si 830.34 (found). 831.12 (calculated)

### Preparation Example 2

### Preparation of Compound (103)

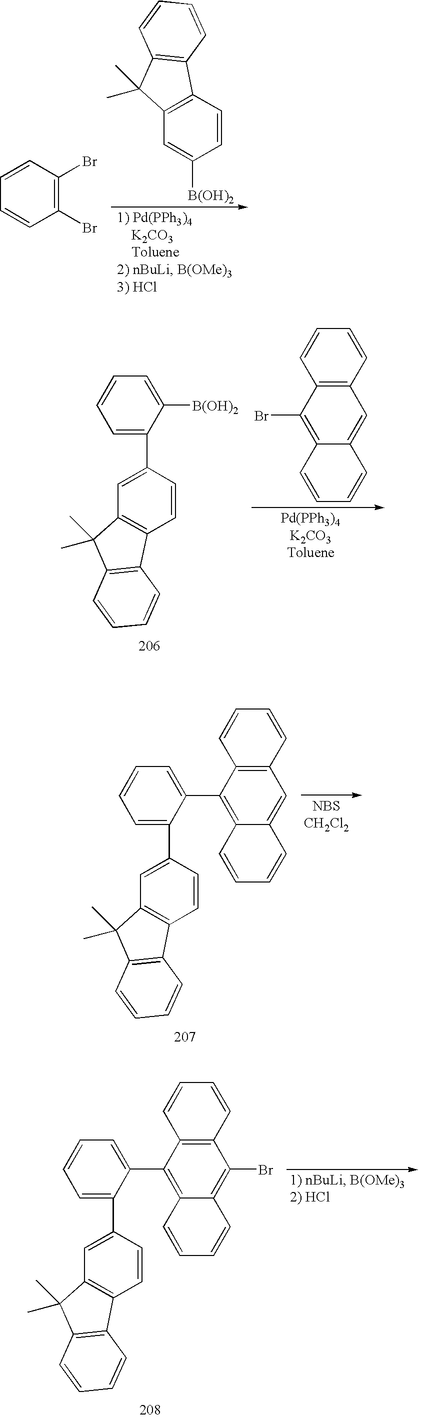

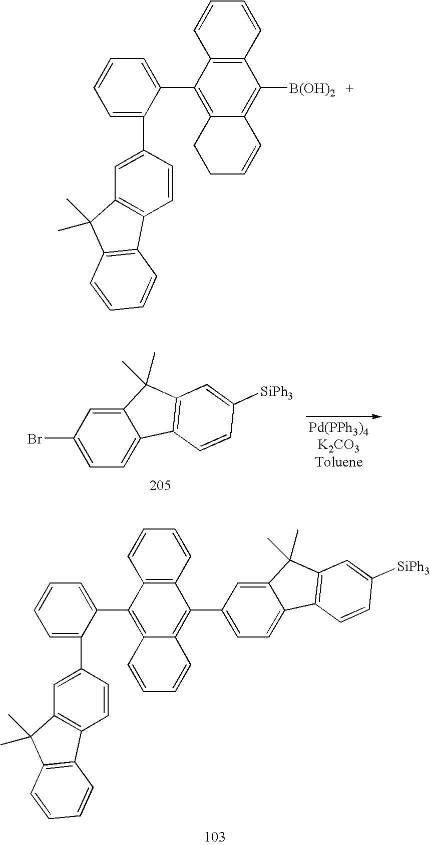

### Preparation of Compound (206)

A 1 L round bottomed flask was charged with 1,2-dibromobenzene (100 g, 423.9 mmol), 2-(9,9′-dimethyl)fluoreneboronic acid (111.0 g, 466.3 mmol), toluene (1000 mL) and tetrakis(triphenylphosphine)palladium (Pd(PPh₃)₄) (24.5 g, 21.2 mmol), and the mixture was stirred under argon atmosphere. Aqueous potassium carbonate solution (300 mL) was then added dropwise thereto, and the resultant mixture was heated under reflux for 4 hours with stirring. When the reaction was completed, distilled water (1500 mL) was added to the reaction mixture, which was then extracted with ethyl acetate (800 mL). The organic extract obtained was dried over anhydrous magnesium sulfate, filtered and concentrated under reduced pressure. Purification via silica gel column chromatography (ethyl acetate:hexane=1:30) gave the product, 1-bromo-2-(9,9′-dimethyl)fluorenylbenzene (75.52 g, 217.0 mmol, yield: 51.2%).

A 1 L round bottomed flask was charged with 1-bromo-2-(9,9′-dimethyl)fluorenylbenzene (51.68 g, 148.5 mmol) and tetrahydrofuran (1000 mL), and n-BuLi (1.6 M in hexane) (89.0 mL, 222.5 mmol) was added dropwise thereto at −78° C. After stirring the mixture at the same temperature for 1 hour, trimethylborate (24.8 mL, 222.5 mmol) was added dropwise to the reaction mixture, and the temperature was raised to room temperature. The reaction mixture was stirred for 12 hours, and when the reaction was completed, 1M hydrochloric acid solution (500 mL) was added thereto, and the resultant mixture was stirred for 5 hours. Organic extract obtained from extraction with distilled water (500 mL) and ethyl acetate (400 mL) was dried over anhydrous magnesium sulfate, filtered and concentrated under reduced pressure. Recrystallization from ethyl acetate (50 mL) and methanol (600 mL) gave Compound (206) (29.31 g, 93.34 mmol, yield: 62.9%).

### Preparation of Compound (207)

A 500 mL round bottomed flask was charged with Compound (206) (34.54 g, 110.0 mmol), 9-bromoanthracene (28.16 g, 88.0 mmol), toluene (500 mL) and tetrakis(triphenylphosphine)palladium (Pd(PPh₃)₄) (2.45 g, 2.05 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (500 mL) was added to the reaction mixture, which was then extracted with ethyl acetate (500 mL). The organic extract obtained was dried over anhydrous magnesium sulfate, filtered and concentrated under reduced pressure. Purification via silica gel column chromatography (dichloromethane:hexane=1:15) gave Compound (207) (32.34 g, 72.51 mmol, yield: 82.4%).

### Preparation of Compound (208)

A 500 mL round bottomed flask was charged with Compound (207) (41.44 g, 92.62 mmol), N-bromosuccinimide (18.13 g, 101.9 mmol) and dichloromethane (250 mL), and the mixture was stirred at room temperature for 12 hours. When the reaction was completed, the solvent was removed under reduced pressure. Recrystallization from dichloromethane (150 mL) and hexane (800 mL) gave Compound (208) (30.52 g, 58.24 mmol, yield: 62.9%).

### Preparation of Compound (209)

A 500 mL round bottomed flask was charged Compound (208) (48.53 g, 92.62 mmol) and tetrahydrofuran (800 mL), and n-BuLi (1.6 M in hexane) (55.57 mL, 138.9 mmol) was added dropwise thereto at −78° C. After stirring the mixture at the same temperature for 1 hour, trimethylborate (15.49 mL, 138.9 mmol) was added dropwise to the reaction mixture, and the temperature was raised to room temperature. The reaction mixture was stirred for 12 hours, and when the reaction was completed, 1M hydrochloric acid solution (400 mL) was added thereto, and the resultant mixture was stirred for 5 hours. Organic extract obtained from extraction with distilled water (500 mL) and ethyl acetate (500 mL) was dried over anhydrous magnesium sulfate, filtered and concentrated under reduced pressure. Recrystallization from ethyl acetate (100 mL) and methanol (800 mL) gave Compound (209) (32.33 g, 65.98 mmol, yield: 71.2%).

### Preparation of Compound (103)

A 500 mL round bottomed flask was charged with Compound (209) (35.17 g, 71.78 mmol), Compound (205) (30.43 g, 57.42 mmol), toluene (600 mL) and tetrakis(triphenylphosphine)palladium (Pd(PPh₃)₄) (4.15 g, 3.59 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (500 mL) was added to the reaction mixture, which was then extracted with ethyl acetate (500 mL). The organic extract obtained was dried over anhydrous magnesium sulfate, filtered and concentrated under reduced pressure. Purification via silica gel column chromatography (dichloromethane:hexane=1:10) and recrystallization from hexane gave Compound (103) (31.76 g, 35.45 mmol, yield: 61.7%) as pale yellow product.

¹H NMR (400 MHz, CDCl₃): δ=7.94 (d, 1H), 7.90 (d, 2H), 7.84-7.82 (m, 2H), 7.78 (s, 2H), 7.68-7.65 (m, 5H), 7.62 (d, 2H), 7.57-7.54 (m, 9H), 7.38-7.34 (m, 10H), 7.33-7.27 (m, 7H), 1.67 (s, 6H), 1.66 (s, 6H)

MS/FAB C₆₉H₅₂Si 896.38 (found). 897.23 (calculated)

### Preparation Example 3

### Preparation of Compound (110)

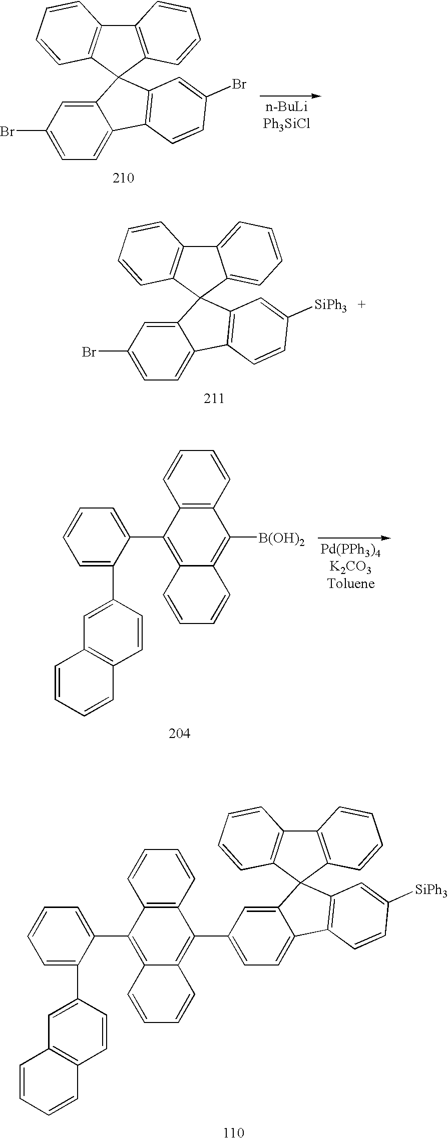

### Preparation of Compound (211)

A 500 mL round bottomed flask was charged with Compound (210) (43.90 g, 92.62 mmol) and tetrahydrofuran (1000 mL), and n-BuLi (1.6 M in hexane) (55.57 mL, 138.9 mmol) was added dropwise thereto at −78° C. After stirring the mixture at the same temperature for 1 hour, triphenylsilyl chloride (40.95 g, 138.9 mmol) was added dropwise to the reaction mixture, and the temperature was raised to room temperature. The reaction mixture was stirred for 12 hours, and when the reaction was completed, distilled water (1000 mL) was added thereto. Organic extract obtained from extraction with ethyl acetate (800 mL) was dried over anhydrous magnesium sulfate, filtered and concentrated under reduced pressure. Purification via silica gel column chromatography (dichloromethane:hexane=1:25) gave Compound (211) (34.22 g, 52.33 mmol, yield: 56.5%).

### Preparation of Compound (110)

A 500 mL round bottomed flask was charged with Compound (211) (34.22 g, 52.33 mmol), Compound (204) (27.74 g, 65.42 mmol), toluene (500 ml) and tetrakis(triphenylphosphine)palladium (Pd(PPh₃)₄) (3.72 g, 3.22 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (800 mL) was added to the reaction mixture, which was then extracted with ethyl acetate (500 mL). The organic extract obtained was dried over anhydrous magnesium sulfate, filtered and concentrated under reduced pressure. Purification via silica gel column chromatography (dichloromethane:hexane=1:7) and recrystallization from hexane gave Compound (110) (33.56 g, 35.22 mmol, yield: 67.3%) as pale yellow product.

¹H NMR (400 MHz, CDCl₃): δ=7.94 (d, 2H), 7.90 (s, 1H), 7.79 (s, 2H), 7.74-7.72 (m, 3H), 7.69-7.66 (m, 6H), 7.62-7.58 (m, 6H), 7.56-7.52 (m, 9H), 7.40-7.35 (m, 11H), 7.33-7.28 (m, 8H), 7.20-7.16 (m, 4H).

MS/FAB C₇₃H₄₈Si 952.35 (found). 953.25 (calculated)

### Preparation Example 4

### Preparation of Compound (120)

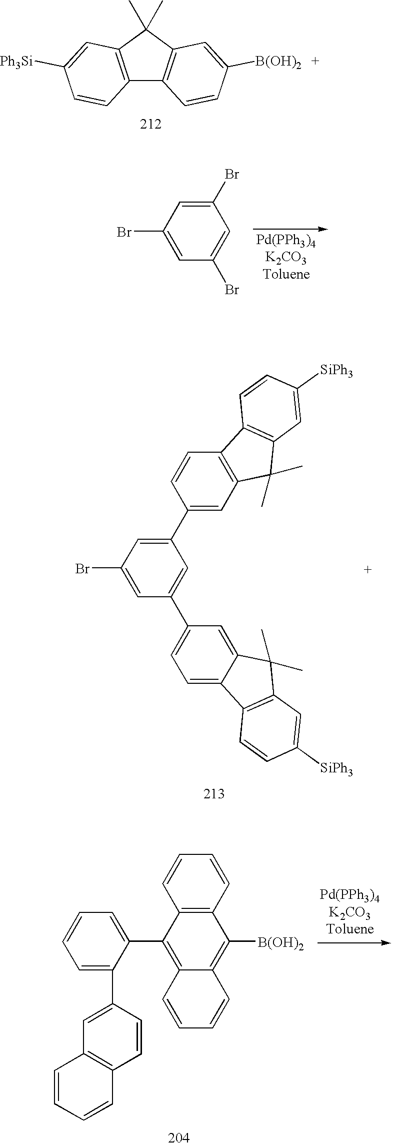

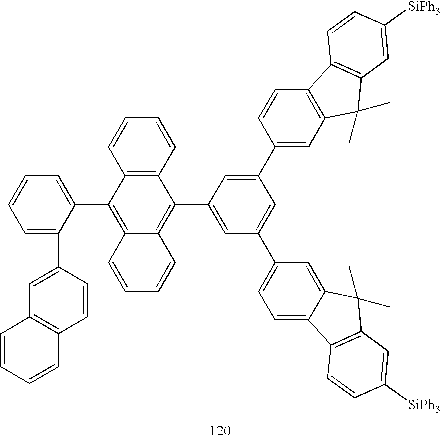

### Preparation of Compound (213)

A 250 mL round bottomed flask was charged with Compound (212) (10.55 g, 21.23 mmol), 1,3,5-tribromobenzene (4.457 g, 14.15 mmol), toluene (150 mL) and tetrakis(triphenylphosphine)palladium (Pd(PPh₃)₄) (0.654 g, 0.567 mmol), and the mixture was stirred under argon atmosphere. Aqueous potassium carbonate solution (50 mL) was then added dropwise thereto, and the resultant mixture was heated under reflux for 4 hours with stirring. When the reaction was completed, distilled water (300 mL) was added to the reaction mixture, which was then extracted with ethyl acetate (150 mL). The organic extract obtained was dried over anhydrous magnesium sulfate, filtered and concentrated under reduced pressure. Purification via silica gel column chromatography (dichloromethane:hexane=1:20) and recrystallization from dichloromethane (10 mL) and hexane (100 mL) gave Compound (213) (4.987 g, 4.714 mmol, yield: 33.3%) as pale yellow product.

### Preparation of Compound (120)

A 250 mL round bottomed flask was charged with Compound (213) (4.987 g, 4.714 mmol), Compound (204) (2.409 g, 5.681 mmol), toluene (100 mL) and tetrakis(triphenylphosphine)palladium (Pd(PPh₃)₄) (0.274 g, 0.237 mmol), and the mixture was stirred under argon atmosphere. Aqueous potassium carbonate solution (50 mL) was then added dropwise thereto, and the resultant mixture was heated under reflux for 4 hours with stirring. When the reaction was completed, distilled water (500 mL) was added to the reaction mixture, which was then extracted with ethyl acetate (500 mL). The organic extract obtained was dried over anhydrous magnesium sulfate, filtered and concentrated under reduced pressure. Purification via silica gel column chromatography (dichloromethane:hexane=1:8) and recrystallization from hexane gave Compound (120) (2.354 g, 1.733 mmol, yield: 36.8%) as pale yellow product.

¹H NMR (400 MHz, CDCl₃): δ=8.07 (s, 2H), 7.96 (d, 2H), 7.91 (s, 1H), 7.85 (s, 2H), 7.75 (d, 1H), 7.70-7.65 (m, 11H), 7.63 (d, 2H), 7.56-7.52 (m, 15H), 7.51 (d, 2H), 7.39-7.35 (m, 18H), 7.34-7.27 (m, 8H), 1.67 (s, 12H)

MS/FAB C₁₀₂H₇₆Si₂ 1356.55 (found). 1357.87 (calculated)

### Preparation Example 5

### Preparation of Compound (125)

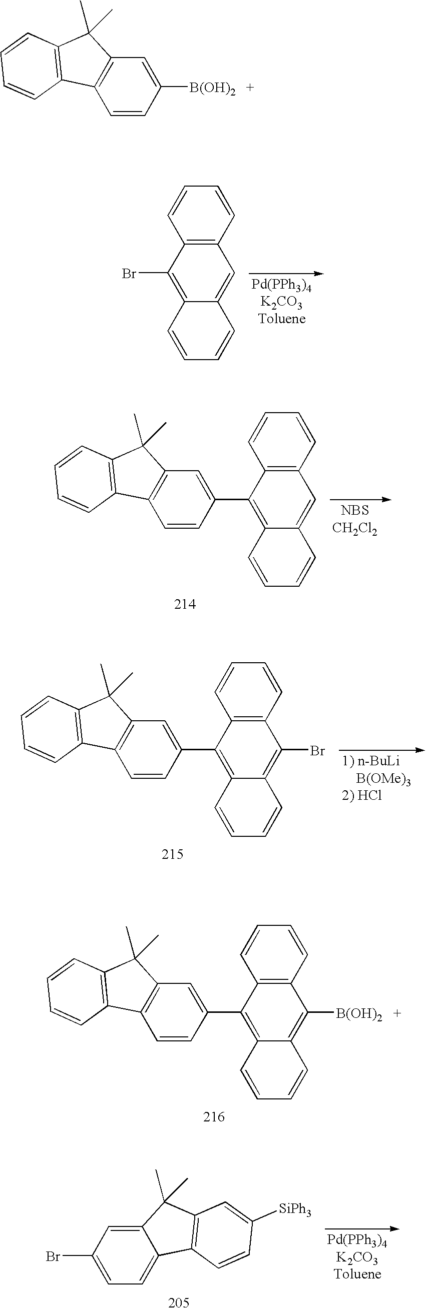

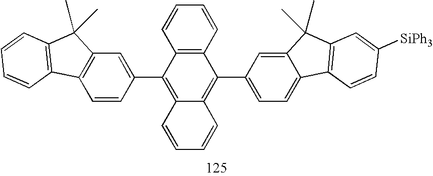

### Preparation of Compound (214)

A 500 mL round bottomed flask was charged with 9,9′-dimethylfluorene-2-boronic acid (26.18 g, 110.0 mmol), 9-bromoanthracene (28.16 g, 88.0 mmol), toluene (500 mL) and tetrakis(triphenylphosphine)palladium (Pd(PPh₃)₄) (2.45 g, 2.05 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (500 mL) was added to the reaction mixture, which was then extracted with ethyl acetate (300 mL). The organic extract obtained was dried over anhydrous magnesium sulfate, filtered and concentrated under reduced pressure. Purification via silica gel column chromatography (dichloromethane:hexane=1:15) gave Compound (214) (22.23 g, 59.92 mmol, yield: 68.1%).

### Preparation of Compound (215)

A 500 mL round bottomed flask was charged with Compound (214) (22.23 g, 59.92 mmol), N-bromosuccinimide (11.73 g, 65.91 mmol) and dichloromethane (250 mL), and the mixture was stirred at room temperature for 12 hours. When the reaction was completed, the solvent was removed under reduced pressure. Recrystallization from dichloromethane (10 mL) and hexane (100 mL) gave Compound (215) (15.18 g, 33.81 mmol, yield: 56.4%).

### Preparation of Compound (216)

A 500 mL round bottomed flask was charged Compound (215) (37.51 g, 83.36 mmol) and tetrahydrofuran (500 mL), and n-BuLi (1.6 M in hexane) (50.01 mL, 125.0 mmol) was added dropwise thereto at −78° C. After stirring the mixture for 1 hour, trimethylborate (13.94 mL, 125.0 mmol) was added dropwise to the reaction mixture, and the temperature was raised to room temperature. The reaction mixture was stirred for 12 hours, and when the reaction was completed, 1M hydrochloric acid solution (200 mL) was added thereto, and the resultant mixture was stirred for 5 hours. Distilled water (500 mL) was added thereto, and the mixture was extracted with ethyl acetate (300 mL). The extract was dried over anhydrous magnesium sulfate, filtered and concentrated under reduced pressure. Purification via silica gel column chromatography (ethyl acetate:hexane=2:1) gave Compound (216) (29.98 g, 72.42 mmol, yield: 86.9%).

### Preparation of Compound (125)

A 500 mL round bottomed flask was charged with Compound (216) (29.72 g, 71.78 mmol), Compound (205) (30.43 g, 57.42 mmol), toluene (500 mL) and tetrakis(triphenylphosphine)palladium (Pd(PPh₃)₄) (4.15 g, 3.59 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (600 mL) was added to the reaction mixture, which was then extracted with ethyl acetate (500 mL). The organic extract obtained was dried over anhydrous magnesium sulfate, filtered and concentrated under reduced pressure. Purification via silica gel column chromatography (dichloromethane:hexane=1:10) and recrystallization from hexane gave Compound (125) (31.12 g, 37.90 mmol, yield: 66.0%) as pale yellow product.

¹H NMR (400 MHz, CDCl₃): δ=7.96 (d, 1H), 7.90 (d, 2H), 7.86 (t, 1H), 7.83 (s, 1H), 7.78 (s, 2H), 7.69-7.66 (m, 5H), 7.62 (d, 2H), 7.58-7.53 (m, 7H), 7.40 (t, 1H), 7.38-7.35 (m, 9H), 7.34-7.28 (m, 5H), 1.68 (s, 6H), 1.67 (s, 6H).

MS/FAB C₆₂H₄₈Si 820.35 (found). 821.13 (calculated)

### Preparation Example 6

### Preparation of Compound (130)

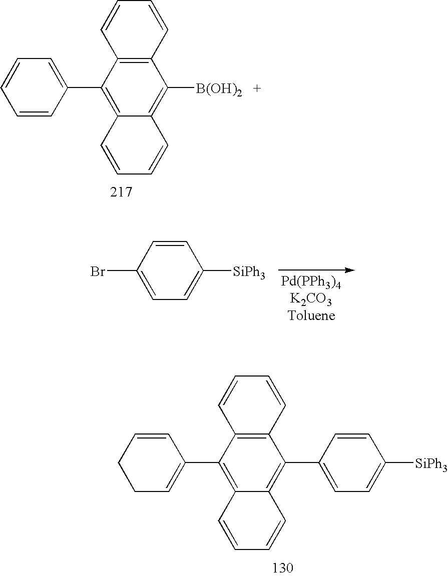

A 500 mL round bottomed flask was charged with Compound (217) (11.9 g, 39.7 mmol), 4-triphenylsilyl-bromobenzene (15.0 g, 36.1 mmol), toluene (150 mL) and tetrakis(triphenylphosphine)palladium (Pd(PPh₃)₄) (2.1 g, 1.8 mmol), and the mixture was stirred under argon atmosphere. Aqueous potassium carbonate solution (60 mL) was then added dropwise thereto, and the resultant mixture was heated under reflux for 4 hours with stirring. When the reaction was completed, distilled water (300 mL) was added to the reaction mixture, which was then extracted with ethyl acetate (200 mL). The organic extract obtained was dried over anhydrous magnesium sulfate, filtered and concentrated under reduced pressure. Purification via silica gel column chromatography (dichloromethane:hexane=1:10) and recrystallization from hexane gave Compound (130) (10.6 g, 18.1 mmol, yield: 50.0%) as pale yellow product.

¹H NMR (400 MHz, CDCl₃): δ=7.22 (m, 1H), 7.32-7.36 (m, 15H), 7.48-7.54 (m, 8H), 7.58-7.67 (m, 8H).

MS/FAB C₄₄H₃₂Si 588.23 (found) 589.23 (calculated)

### Preparation Example 7

### Preparation of Compound (141)

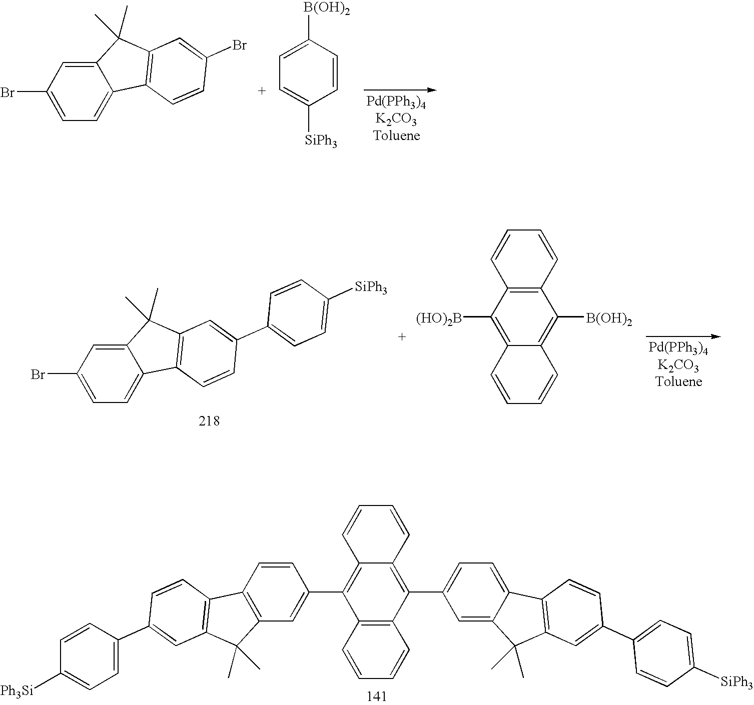

### Preparation of Compound (218)

A 500 mL round bottomed flask was charged with 2,7-dibromo-9,9′-dimethylfluorene (11.97 g, 34.0 mmol), 4-triphenylsilyl-phenylboronic acid (15.5 g, 40.8 mmol), toluene (200 mL) and tetrakis(triphenylphosphine)palladium (0) (Pd(PPh₃)₄) (1.96 g, 1.70 mmol), and the mixture was stirred under argon atmosphere. Aqueous potassium carbonate solution (50 mL) was then added dropwise thereto, and the resultant mixture was heated under reflux for 4 hours with stirring. When the reaction was completed, distilled water (300 mL) was added to the reaction mixture, which was then extracted with ethyl acetate (200 mL). The organic extract obtained was dried over anhydrous magnesium sulfate, filtered and concentrated under reduced pressure. Purification via silica gel column chromatography (ethyl acetate:hexane=1:50) gave Compound (218) (8.23 g, 13.54 mmol, yield: 39.8%).

### Preparation of Compound (141)

A 500 mL round bottomed flask was charged with Compound (218) (43.64 g, 71.78 mmol), 9,10-anthracene diboronic acid (7.956 g, 29.91 mmol), toluene (250 mL) and tetrakis(triphenylphosphine)palladium (0) (Pd(PPh₃)₄) (4.15 g, 3.59 mmol), and the mixture was stirred under argon atmosphere. Aqueous potassium carbonate solution (100 mL) was then added dropwise thereto, and the resultant mixture was heated under reflux for 4 hours with stirring. When the reaction was completed, distilled water (400 mL) was added to the reaction mixture, which was then extracted with ethyl acetate (300 mL). The organic extract obtained was dried over anhydrous magnesium sulfate, filtered and concentrated under reduced pressure. Purification via silica gel column chromatography (dichloromethane:hexane=1:10) and recrystallization from hexane gave Compound (141) (12.31 g, 9.99 mmol, yield: 33.4%) as pale yellow product.

¹H NMR (400 MHz, CDCl₃): δ=7.92 (d, 2H), 7.91 (d, 2H), 7.79 (s, 2H), 7.77 (s, 2H), 7.69-7.66 (m, 4H), 7.64-7.60 (m, 8H), 7.58 (d, 4H), 7.58-7.52 (m, 12H), 7.39-7.34 (m, 18H), 7.33-7.31 (m, 4H), 1.66 (s, 12H).

MS/FAB C₉₂H₇₀Si₂, 1230.50 (found). 1231.71 (calculated)

### Preparation Example 8

### Preparation of Compound (150)

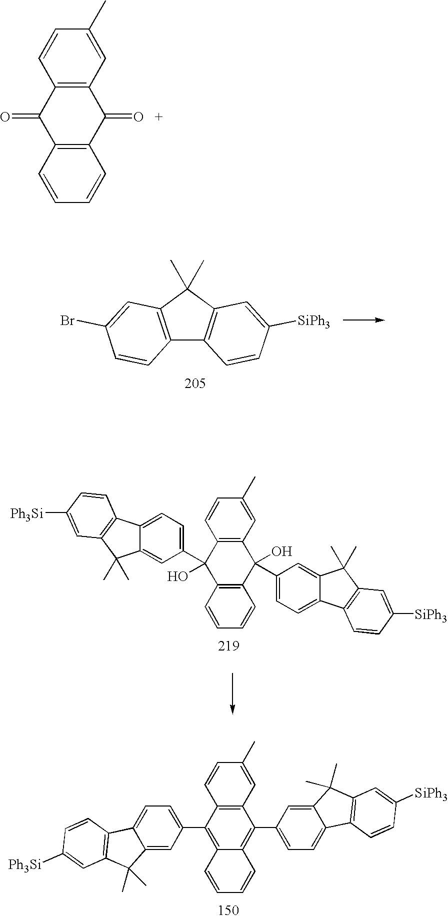

### Preparation of Compound (219)

In a 500 mL round bottomed flask, Compound (205) (29.89 g, 56.24 mmol) was dissolved in tetrahydrofuran (150 mL). At −78° C., n-BuLi (2.5 M in hexane) (22.49 mL, 56.24 mmol) was added dropwise thereto at −78° C. After stirring the mixture at the same temperature for 1 hour, 2-methylanthraquinone (5 g, 22.49 mmol) was added to the reaction mixture, and the temperature was raised to room temperature. The reaction mixture was stirred for 12 hours, and when the reaction was completed, distilled water (300 mL) was added thereto, and the resultant mixture was extracted with ethyl acetate (200 mL). The organic extract obtained was dried over anhydrous magnesium sulfate, filtered and concentrated under reduced pressure. Recrystallization from hexane gave Compound (219) (16.10 g, 14.28 mmol).

### Preparation of Compound (150)

A 500 mL round bottomed flask was charged with Compound (219) (16.10 g, 14.27 mmol), potassium iodide (9.48 g, 57.11 mmol) and sodium phosphinate monohydrate (12.10 g, 114.22 mmol), and acetic acid (150 mL) was added thereto. The mixture was stirred at 1000 for 12 hours, and cooled to room temperature. When the reaction was completed, distilled water (300 mL) was added to the reaction mixture, and the solid produced was filtered under reduced pressure. After washing with aqueous potassium carbonate solution, the solid was purified via silica gel column chromatography (dichloromethane:hexane=1:10) to obtain Compound (150) (6.25 g, 5.71 mmol, yield: 40.05%).

¹H NMR (400 MHz, CDCl₃): δ=7.95 (d, 2H), 7.91 (d, 2H), 7.84 (s, 2H), 7.77 (s, 2H), 7.69-7.65 (m, 4H), 7.62-7.59 (m, 3H), 7.58-7.52 (m, 12H), 7.47 (s, 1H), 7.41-7.34 (m, 18H), 7.33-7.31 (m, 2H), 7.20 (d, 1H), 2.46 (s, 3H), 1.67 (s, 12H).

MS/FAB C₈₁H₆₄Si₂, 1092.45 (found). 1093.55 (calculated)

### Preparation Example 9-55

The compounds listed in Table 1 were prepared according to the procedures described in Preparation Examples 1 to 8, and the NMR data of those compounds are shown in Table 2.

TABLE 1

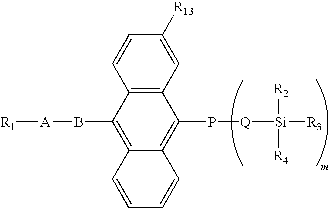

| NO. | R₁ | —A—B— | —P—Q— |
|---|---|---|---|
| 101 | H | 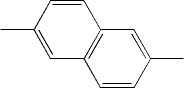 | 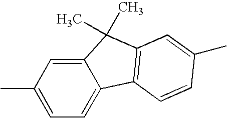 |
| 102 | 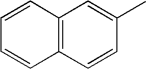 | 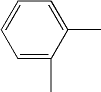 | 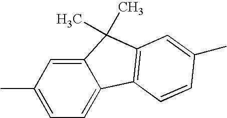 |
| 103 | 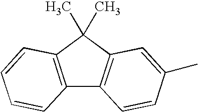 | 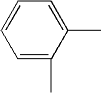 | 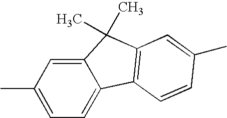 |
| 104 | 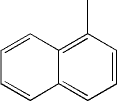 | 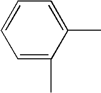 | 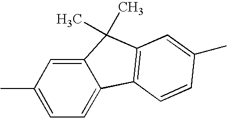 |
| 105 | H | 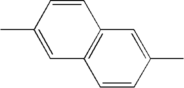 | 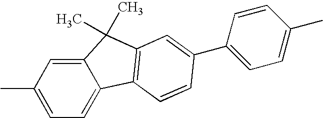 |
| 106 | H | 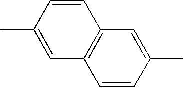 | 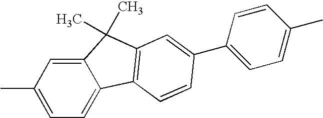 |
| 107 | 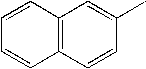 | 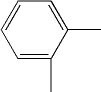 | 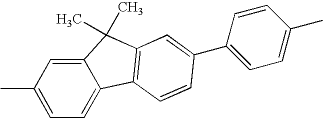 |
| 108 | 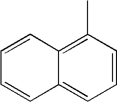 | 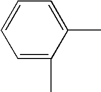 | 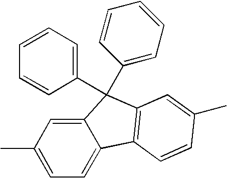 |
| 109 | 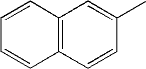 | 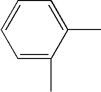 | 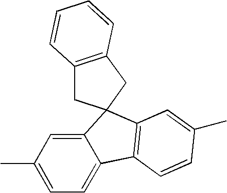 |
| 110 | 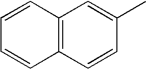 | 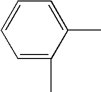 | 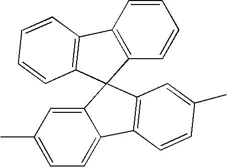 |
| 111 | 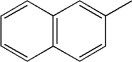 | 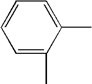 | 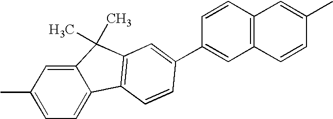 |
| 112 | 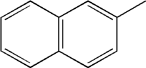 | 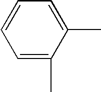 | 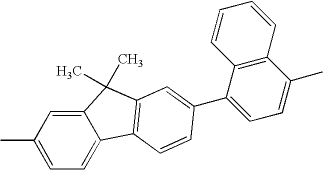 |
| 113 | 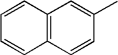 | 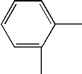 | 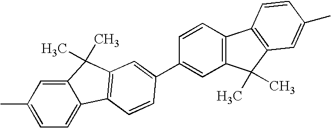 |
| 114 | 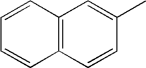 | 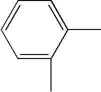 | 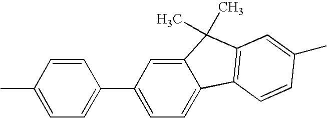 |
| 115 | 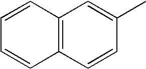 | 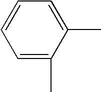 | 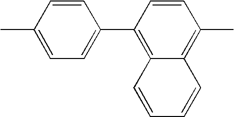 |
| 116 | 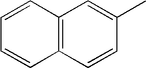 | 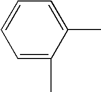 | 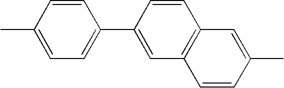 |
| 117 | 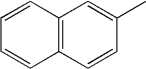 | 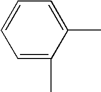 | 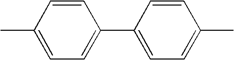 |
| 118 | 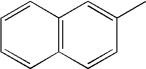 | 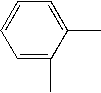 | 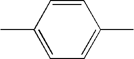 |
| 119 | 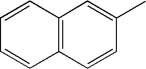 | 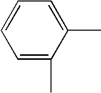 | 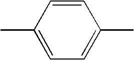 |
| 120 | 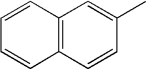 | 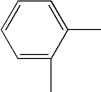 | 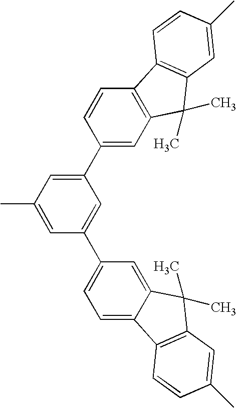 |
| 121 | 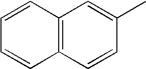 | 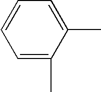 | 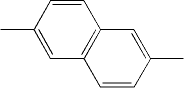 |
| 122 | 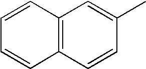 | 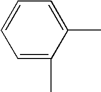 | 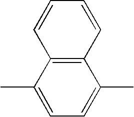 |
| 123 | 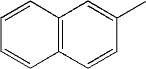 | 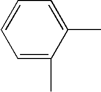 | 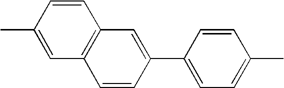 |
| 124 | 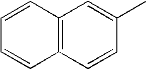 | 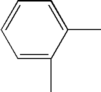 | 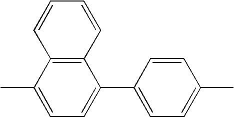 |
| 125 | H | 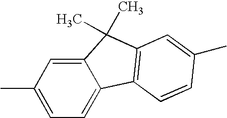 | 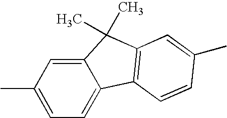 |
| 126 | H | 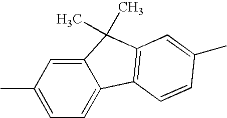 | 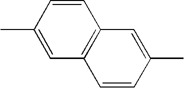 |
| 127 | H | 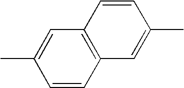 | 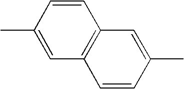 |
| 128 | H | 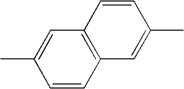 | 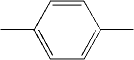 |
| 129 | H | 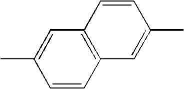 | 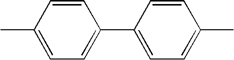 |
| 130 | H | 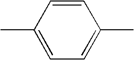 | 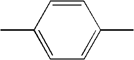 |
| 131 | H | 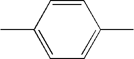 | 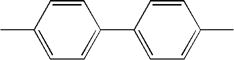 |
| 132 | H | 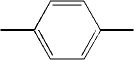 | 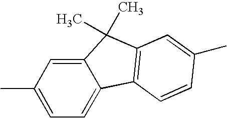 |
| 133 | H | 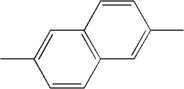 | 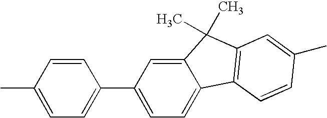 |
| 134 | H | 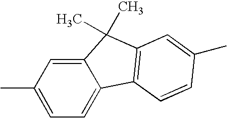 | 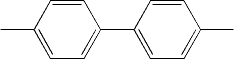 |
| 135 | H | 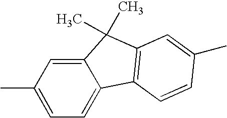 | 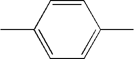 |
| 136 | H | 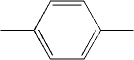 | 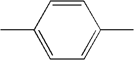 |
| 137 | H | 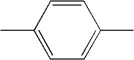 | 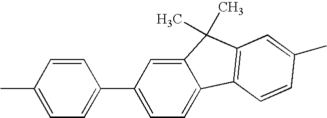 |
| 138 | H | 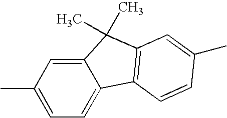 | 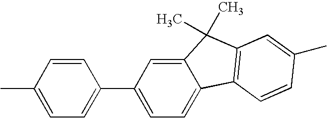 |
| 139 | 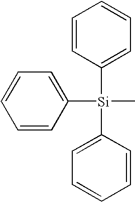 | 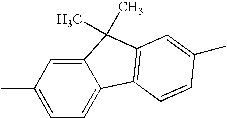 | 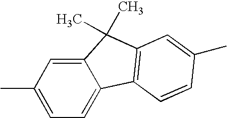 |
| 140 | 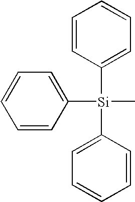 | 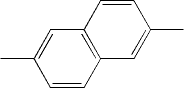 | 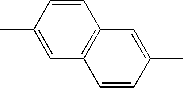 |
| 141 | 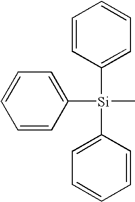 | 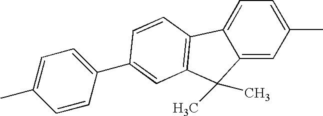 | 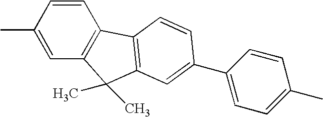 |
| 142 | 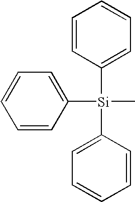 | 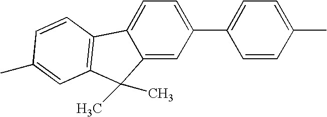 | 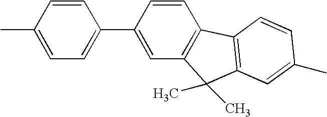 |
| 143 | 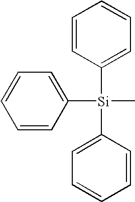 | 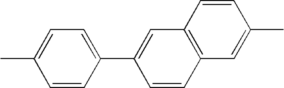 | 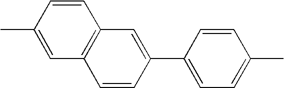 |
| 144 | 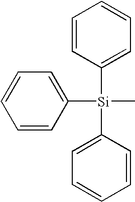 | 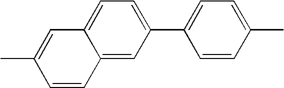 | 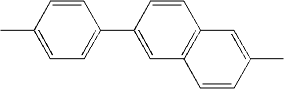 |
| 145 | 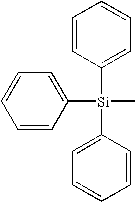 | 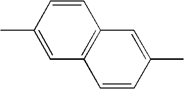 | 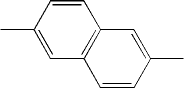 |
| 146 | 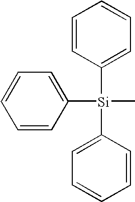 | 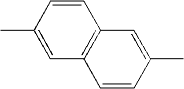 | 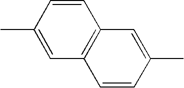 |
| 147 | 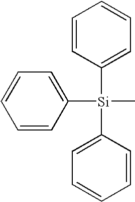 | 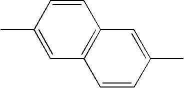 | 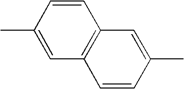 |
| 148 | 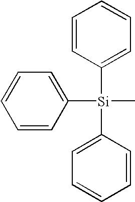 | 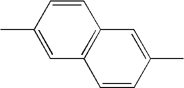 | 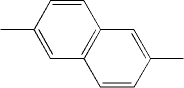 |
| 149 | 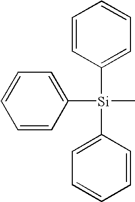 | 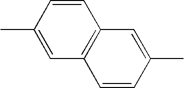 | 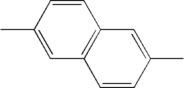 |
| 150 | 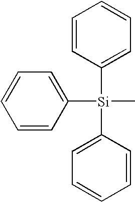 | 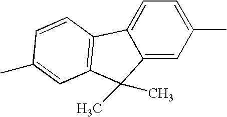 | 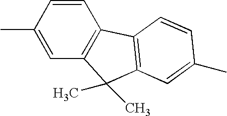 |
| 151 | 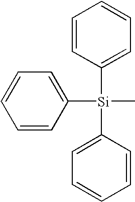 | 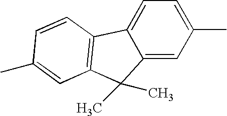 | 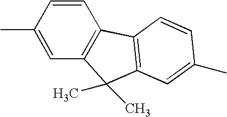 |
| 152 | 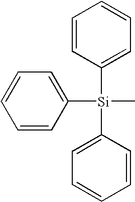 | 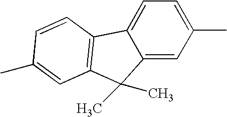 | 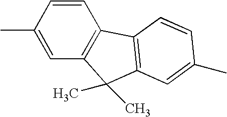 |
| 153 | 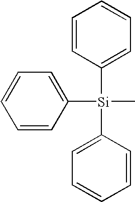 | 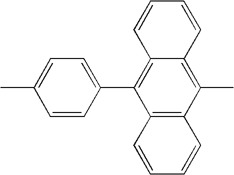 | 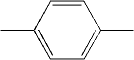 |
| 154 | 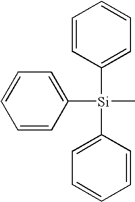 | 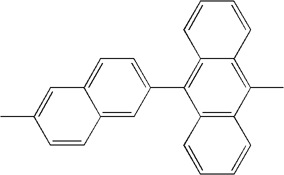 | 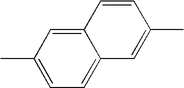 |
| 155 | 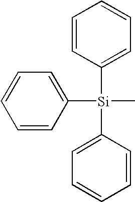 | 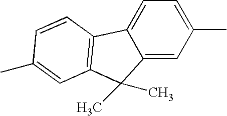 | 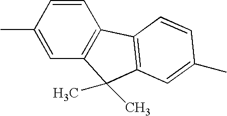 |

| NO. | R₂ | R₃ | R₄ | R₁₃ | m |
|---|---|---|---|---|---|
| 101 | 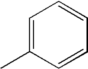 | 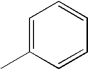 | 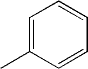 | H | 1 |
| 102 | 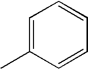 | 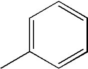 | 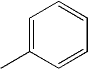 | H | 1 |
| 103 | 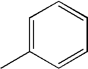 | 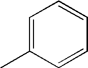 | 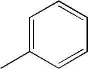 | H | 1 |
| 104 | 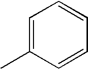 | 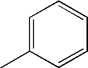 | 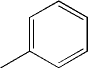 | H | 1 |
| 105 | —CH₃ | —CH₃ | —CH₃ | H | 1 |
| 106 | 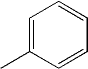 | 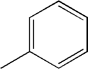 | 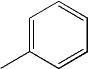 | H | 1 |
| 107 | 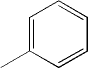 | 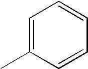 | 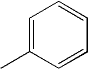 | H | 1 |
| 108 | 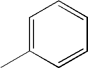 | 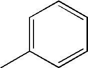 | 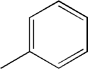 | H | 1 |
| 109 | 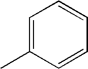 | 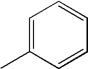 | 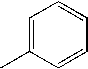 | H | 1 |
| 110 | 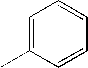 | 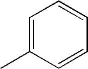 | 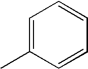 | H | 1 |
| 111 | 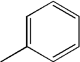 | 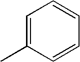 | 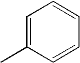 | H | 1 |
| 112 | 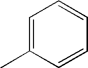 | 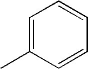 | 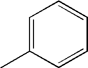 | H | 1 |
| 113 | 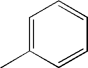 | 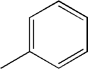 | 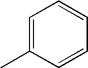 | H | 1 |
| 114 | 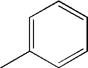 | 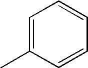 | 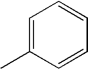 | H | 1 |
| 115 | 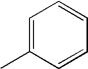 | 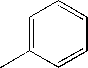 | 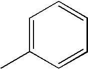 | H | 1 |
| 116 | 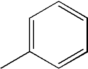 | 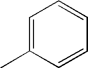 | 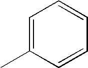 | H | 1 |
| 117 | 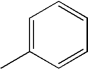 | 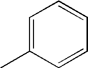 | 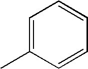 | H | 1 |
| 118 | 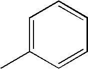 | 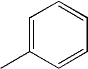 | 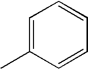 | H | 1 |
| 119 | —CH₃ | —CH₃ | —CH₃ | H | 1 |
| 120 | 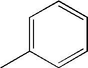 | 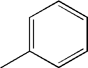 | 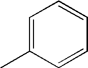 | H | 2 |
| 121 | 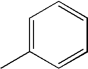 | 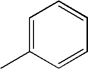 | 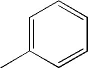 | H | 1 |
| 122 | 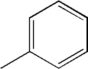 | 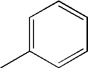 | 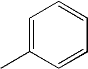 | H | 1 |
| 123 | 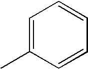 | 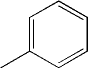 | 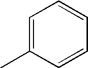 | H | 1 |
| 124 | 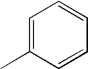 | 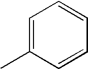 | 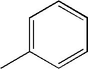 | H | 1 |
| 125 | 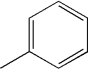 | 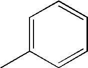 | 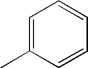 | H | 1 |
| 126 | 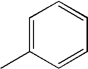 | 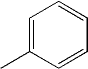 | 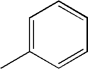 | H | 1 |
| 127 | 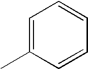 | 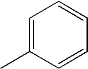 | 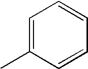 | H | 1 |
| 128 | 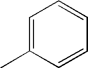 | 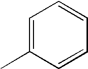 | 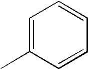 | H | 1 |
| 129 | 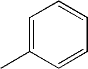 | 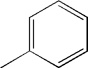 | 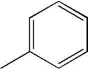 | H | 1 |
| 130 | 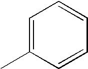 | 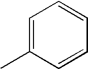 | 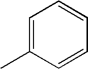 | H | 1 |
| 131 | 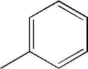 | 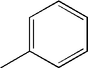 | 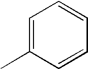 | H | 1 |
| 132 | 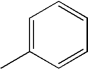 | 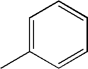 | 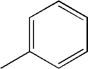 | H | 1 |
| 133 | 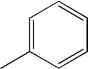 | 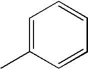 | 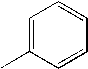 | H | 1 |
| 134 | 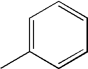 | 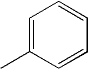 | 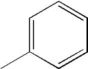 | H | 1 |
| 135 | 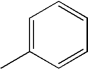 | 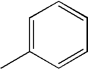 | 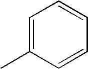 | H | 1 |
| 136 | —CH₃ | —CH₃ | —CH₃ | H | 1 |
| 137 | 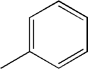 | 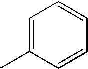 | 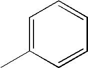 | H | 1 |
| 138 | 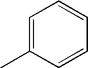 | 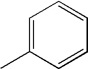 | 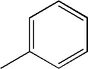 | H | 1 |
| 139 | 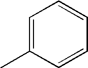 | 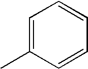 | 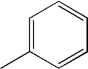 | H | 1 |
| 140 | 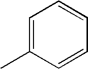 | 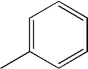 | 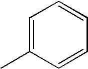 | H | 1 |
| 141 | 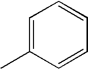 | 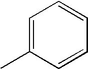 | 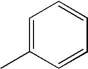 | H | 1 |
| 142 | 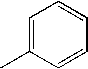 | 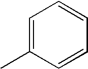 | 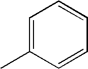 | H | 1 |
| 143 | 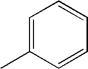 | 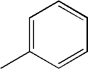 | 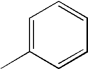 | H | 1 |
| 144 | 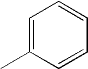 | 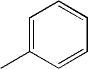 | 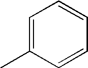 | H | 1 |
| 145 | 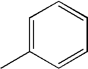 | 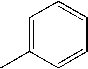 | 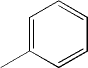 | —CH₃ | 1 |
| 146 | 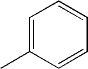 | 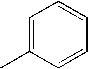 | 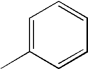 | —C(CH₃)₃ | 1 |
| 147 | 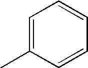 | 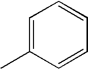 | 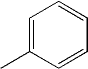 | 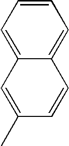 | 1 |
| 148 | 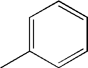 | 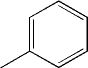 | 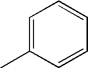 | 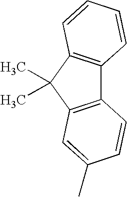 | 1 |
| 149 | 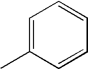 | 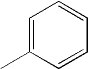 | 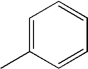 | 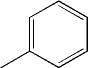 | 1 |
| 150 | 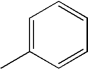 | 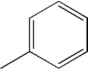 | 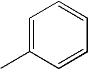 | —CH₃ | 1 |
| 151 | 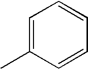 | 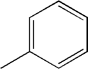 | 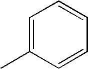 | 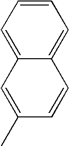 | 1 |
| 152 | 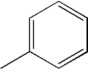 | 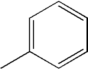 | 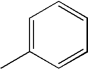 | 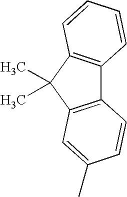 | 1 |
| 153 | 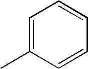 | 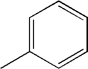 | 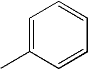 | H | 1 |
| 154 | 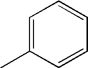 | 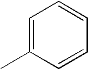 | 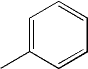 | H | 1 |
| 155 | 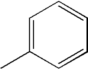 | 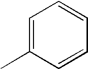 | 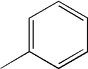 | H | 1 |

TABLE 2

| Compound | |
|---|---|
| NO. | ¹H NMR |
| 101 | ¹H NMR(400 MHz, CDCl₃): δ = 7.94(d, 1H), 7.91(d, 1H), 7.89(s, 1H), |
| | 7.83(s, 1H), 7.77(s, 1H), 7.73(d, 1H), 7.69-7.65(m, 7H), 7.56-7.53(m, |
| | 7H), 7.38-7.35(m, 9H), 7.33-7.31(m, 6H), 1.67(s, 6H) |
| 102 | ¹H NMR(400 MHz, CDCl₃): δ = 7.94(d, 1H), 7.92(d, 1H), 7.89(s, 1H), |
| | 7.84(s, 1H), 7.79(s, 1H), 7.75(d, 1H), 7.68-7.65(m, 7H), 7.61(d, 1H), |
| | 7.56-7.53(m, 9H), 7.38-7.35(m, 9H), 7.33-7.27(m, 8H), 1.65(s, 6H) |
| 103 | ¹H NMR(400 MHz, CDCl₃): δ = 7.94(d, 1H), 7.90(d, 2H), 7.84-7.82(m, |
| | 2H), 7.78(s, 2H), 7.68-7.65(m, 5H), 7.62(d, 2H), 7.57-7.54(m, 9H), |
| | 7.38-7.34(m, 10H), 7.33-7.27(m, 7H), 1.67(s, 6H), 1.66(s, 6H) |
| 104 | ¹H NMR(400 MHz, CDCl₃): δ = 7.94(d, 1H), 7.90(d, 1H), 7.85(s, 1H), |
| | 7.79(s, 1H), 7.69-7.66(m, 7H), 7.63-7.60(m, 2H), 7.56-7.53(m, 9H), |
| | 7.39-7.35(m, 10H), 7.32-7.27(m, 8H), 1.67(s, 6H) |
| 105 | ¹H NMR(400 MHz, CDCl₃): δ = 7.91(d, 2H), 7.89(s, 1H), 7.78(s, 2H), |
| | 7.73(d, 1H), 7.68-7.65(m, 2H), 7.60(d, 2H), 7.55-7.53(d, 3H), 7.46(d, |
| | 2H), 7.33-7.30(m, 6H), 1.67(s, 6H), 0.66(s, 9H) |
| 106 | ¹H NMR(400 MHz, CDCl₃): δ = 7.91(d, 2H), 7.77(s, 1H), 7.77(s, 2H), |
| | 7.74-7.72(m, 1H), 7.68-7.66(m, 6H), 7.60(d, 4H), 7.58(d, 2H), 7.54(d, |
| | 7H), 7.38-7.35(m, 9H), 7.33-7.31(m, 6H), 1.66(s, 6H) |
| 107 | ¹H NMR(400 MHz, CDCl₃): δ = 7.92(s, 2H), 7.90(s, 1H), 7.80(s, 2H), |
| | 7.73(d, 1H), 7.69-7.66(m, 6H), 7.62-7.57(m, 6H), 7.55-7.52(m, 9H), |
| | 7.38-7.35(m, 9H), 7.33-7.27(m, 8H), 1.67(s, 6H) |
| 108 | ¹H NMR(400 MHz, CDCl₃): δ = 7.93(d, 2H), 7.90(s, 1H), 7.80(s, 2H), |
| | 7.75(d, 1H), 7.69-7.66(m, 6H), 7.63-7.58(m, 6H), 7.56-7.53(m, 9H), |
| | 7.38-7.35(m, 9H), 7.33-7.28(m, 8H), 7.18-7.14(t, 4H), 7.09-7.05(m, |
| | 6H) |
| 109 | ¹H NMR(400 MHz, CDCl₃): δ = 7.95(d, 2H), 7.91(s, 1H), 7.80(s, 2H), |
| | 7.75(d, 1H), 7.69-7.66(m, 6H), 7.62-7.58(m, 6H), 7.56-7.52(m, 9H), |
| | 7.38-7.36(m, 9H), 7.32-7.28(m, 8H), 7.22-7.18(m, 4H), 3.62(d, 2H), |
| | 3.38(d, 2H) |
| 110 | ¹H NMR(400 MHz, CDCl₃): δ = 7.94(d, 2H), 7.90(s, 1H), 7.79(s, 2H), |
| | 7.74-7.72(m, 3H), 7.69-7.66(m, 6H), 7.62-7.58(m, 6H), 7.56-7.52(m, |
| | 9H), 7.40-7.35(m, 11H), 7.33-7.28(m, 8H), 7.20-7.16(m, 4H) |
| 111 | ¹H NMR(400 MHz, CDCl₃): δ = 7.93(d, 2H), 7.91(s, 2H), 7.80(d, 1H), |
| | 7.78(s, 2H), 7.74(d, 2H), 7.71-7.65(m, 6H), 7.62(d, 3H), 7.58-7.54(m, |
| | 10H), 7.39-7.35(m, 9H), 7.33-7.27(m, 8H), 1.66(s, 6H) |
| 112 | ¹H NMR(400 MHz, CDCl₃): δ = 7.93(d, 2H), 7.91(s, 1H), 7.80(s, 2H), |
| | 7.75(d, 1H), 7.68-7.63(m, 10H), 7.40-7.36(m, 9H), 7.33-7.29(m, 10H), |
| | 1.67(s, 6H) |
| 113 | ¹H NMR(400 MHz, CDCl₃): δ = 7.96(d, 1H), 7.92(d, 3H), 7.90(s, 1H), |
| | 7.85(s, 1H), 7.80-7.78(m, 3H), 7.75(d, 1H), 7.70-7.66(m, 7H), 7.62(m, |
| | 3H), 7.57-7.53(m, 9H), 7.40-7.35(m, 9H), 7.34-7.28(m, 8H), 1.67(s, |
| | 12H) |
| 114 | ¹H NMR(400 MHz, CDCl₃): δ = 7.95(d, 1H), 7.93(d, 1H), 7.90(s, 1H), |
| | 7.86(s, 1H), 7.80(s, 1H), 7.75(d, 1H), 7.70-7.66(m, 7H), 7.62(d, 1H), |
| | 7.58-7.52(m, 13H), 7.40-7.35(m, 9H), 7.33-7.27(m, 8H), 1.67(s, 6H) |
| 115 | ¹H NMR(400 MHz, CDCl₃): δ = 7.90(s, 1H), 7.75(d, 1H), 7.71-7.67(m, |
| | 9H), 7.65(d, 1H), 7.58-7.53(m, 13H), 7.40-7.35(m, 9H), 7.34-7.27(m, |
| | 10H) |
| 116 | ¹H NMR(400 MHz, CDCl₃): δ = 7.97(s, 1H), 7.90(s, 2H), 7.79(d, 1H), |
| | 7.75(d, 2H), 7.71-7.68(m, 6H), 7.62(d, 1H), 7.58-7.54(m, 14H), |
| | 7.41-7.36(m, 9H), 7.33-7.28(m, 8H) |
| 117 | ¹H NMR(400 MHz, CDCl₃): δ = 7.91(s, 1H), 7.76(d, 1H), 7.70-7.67(m, |
| | 6H), 7.62(d, 2H), 7.59(d, 2H), 7.56-7.53(m, 13H), 7.39-7.35(m, 9H), |
| | 7.34-7.28(m, 8H) |
| 118 | ¹H NMR(400 MHz, CDCl₃): δ = 7.91(s, 1H), 7.75(s, 1H), 7.69-7.66(m, |
| | 6H), 7.62(d, 2H), 7.60(d, 2H), 7.58-7.53(m, 9H), 7.39-7.35(m, 9H), |
| | 7.34-7.27(m, 8H) |
| 119 | ¹H NMR(400 MHz, CDCl₃): δ = 7.91(s, 1H), 7.75(d, 1H), 7.70-7.67(m, |
| | 6H), 7.57-7.54(m, 5H), 7.46(d, 2H), 7.34-7.28(m, 8H), 0.65(s, 9H) |
| 120 | ¹H NMR(400 MHz, CDCl₃): δ = 8.07(s, 2H), 7.96(d, 2H), 7.91(s, 1H), |
| | 7.85(s, 2H), 7.75(d, 1H), 7.70-7.65(m, 11H), 7.63(d, 2H), 7.56-7.52(m, |
| | 15H), 7.51(d, 2H), 7.39-7.35(m, 18H), 7.34-7.27(m, 8H), 1.67(s, 12H) |
| 121 | ¹H NMR(400 MHz, CDCl₃): δ = 7.97(s, 1H), 7.91(s, 1H), 7.89(s, 1H), |
| | 7.79(d, 1H), 7.73(m, 2H), 7.69-7.66(m, 6H), 7.62(d, 1H), 7.58-7.53(m, |
| | 10H), 7.39-7.35(m, 9H), 7.34-7.28(m, 8H) |
| 122 | ¹H NMR(400 MHz, CDCl₃): δ = 7.90(s, 1H), 7.75(d, 1H), 7.69-7.65(m, |
| | 9H), 7.64(d, 1H), 7.58-7.53(m, 9H), 7.39-7.35(m, 9H), 7.34-7.28(m, |
| | 10H) |
| 123 | ¹H NMR(400 MHz, CDCl₃): δ = 7.91(s, 3H), 7.74(d, 3H), 7.69-7.66(m, |
| | 6H), 7.61(d, 2H), 7.58(d, 2H), 7.57-7.53(m, 11H), 7.39-7.35(m, 9H), |
| | 7.34-7.28(m, 8H) |
| 124 | ¹H NMR(400 MHz, CDCl₃): δ = 7.91(s, 1H), 7.74(d, 1H), 7.69-7.66(m, |
| | 8H), 7.60(d, 4H), 7.58(d, 2H), 7.58-7.53(m, 9H), 7.39-7.35(m, 9H), |
| | 7.34-7.28(m, 10H) |
| 125 | ¹H NMR(400 MHz, CDCl₃): δ = 7.96(d, 1H), 7.90(d, 2H), 7.86(t, 1H), |
| | 7.83(s, 1H), 7.78(s, 2H), 7.69-7.66(m, 5H), 7.62(d, 2H), 7.58-7.53(m, |
| | 7H), 7.40(t, 1H), 7.38-7.35(m, 9H), 7.34-7.28(m, 5H), 1.68(s, 6H), |
| | 1.67(s, 6H) |
| 126 | ¹H NMR(400 MHz, CDCl₃): δ = 7.96(s, 1H), 7.91(d, 1H), 7.89(s, 1H), |
| | 7.86(d, 1H), 7.79(d, 1H), 7.77(s, 1H), 7.74(d, 1H), 7.69-7.66(m, 4H), |
| | 7.60(d, 2H), 7.58-7.53(m, 8H), 7.39(t, 1H), 7.38-7.35(m, 9H), |
| | 7.34-7.27(m, 5H), 1.67(s, 6H) |
| 127 | ¹H NMR(400 MHz, CDCl₃): δ = 7.96(s, 1H), 7.90(s, 1H), 7.89(s, 1H), |
| | 7.79(d, 1H), 7.75(d, 2H), 7.69-7.66(m, 6H), 7.62(d, 1H), 7.58-7.53(m, |
| | 8H), 7.39-7.35(m, 9H), 7.34-7.31(m, 6H) |
| 128 | ¹H NMR(400 MHz, CDCl₃): δ = 7.89(s, 1H), 7.74(m, 1H), 7.69-7.65(m, |
| | 6H), 7.61(d, 2H), 7.58(d, 2H), 7.57-7.53(m, 7H), 7.40-7.33(m, 9H), |
| | 7.33-7.29(m, 6H) |
| 129 | ¹H NMR(400 MHz, CDCl₃): δ = 7.32-7.36(m, 15H), 7.54-7.58(m, 13H), |
| | 7.60-7.67(m, 8H), 7.73(m, 1H), 7.89(m, 1H) |
| 130 | ¹H NMR(400 MHz, CDCl₃): δ = 7.22(m, 1H), 7.32-7.36(m, 15H), |
| | 7.48-7.54(m, 8H), 7.58-7.67(m, 8H) |
| 131 | ¹H NMR(400 MHz, CDCl₃): δ = 7.22(m, 1H), 7.32-7.36(m, 15H), |
| | 7.48-7.58(m, 10H), 7.60-7.67(m, 10H) |
| 132 | ¹H NMR(400 MHz, CDCl₃): δ = 1.67(s, 6H), 7.23(m, 1H), 7.32-7.36(m, |
| | 15H), 7.48-7.57(m, 9H), 7.60-7.67(m, 6H), 7.77(m, 1H), 7.90-7.94(m, |
| | 2H) |
| 133 | ¹H NMR(400 MHz, CDCl₃): δ = 1.67(s, 6H), 7.32-7.36(m, 15H), |
| | 7.54-7.60(m, 12H), 7.66-7.67(m, 7H), 7.73-7.77(m, 2H), 7.80-7.83(m, |
| | 2H), 7.89-7.94(m, 2H) |
| 134 | ¹H NMR(400 MHz, CDCl₃): δ = 1.67(s, 6H), 7.28(m, 1H), 7.32-7.38(m, |
| | 14H), 7.54-7.58(m, 13H), 7.60-7.67(m, 7H), 7.77(m, 1H), 7.84-7.90(m, |
| | 2H) |
| 135 | ¹H NMR(400 MHz, CDCl₃): δ = 1.67(s, 6H), 7.28(m, 1H), 7.32-7.38(m, |
| | 14H), 7.54-7.58(m, 9H), 7.60-7.67(m, 7H), 7.77(m, 1H), 7.84(m, 1H), |
| | 7.90(m, 1H) |
| 136 | ¹H NMR(400 MHz, CDCl₃): δ = 0.66(s, 9H), 7.22(m, 1H), 7.32(m, 6H), |
| | 7.46-7.48(m, 4H), 7.54(m, 2H), 7.67(m, 4H) |
| 137 | ¹H NMR(400 MHz, CDCl₃): δ = 1.67(s, 6H), 7.22(m, 1H), 7.32-7.36(m, |
| | 15H), 7.48-7.54(m, 14H), 7.60-7.67(m, 5H), 7.77(m, 1H), 7.83(m, 1H), |
| | 7.90(m, 1H) |
| 138 | ¹H NMR(400 MHz, CDCl₃): δ = 1.67(s, 12H), 7.28(m, 1H), 7.32-7.36(m, |
| | 14H), 7.54-7.55(m, 11H), 7.60-7.67(m, 7H), 7.77(m, 2H), 7.83-7.84(m, |
| | 2H), 7.90-7.94(m, 3H) |
| 139 | ¹H NMR(400 MHz, CDCl₃): δ = 7.95(d, 2H), 7.91(d, 2H), 7.86(s, 2H), |
| | 7.78(s, 2H), 7.69-7.65(m, 6H), 7.62(d, 2H), 7.58-7.53(m, 12H), |
| | 7.39-7.33(m, 18H), 7.33-7.30(m, 4H), 1.68(s, 12H) |
| 140 | ¹H NMR(400 MHz, CDCl₃): δ = 7.96(s, 2H), 7.91(s, 2H), 7.79(d, 2H), |
| | 7.75(d, 2H), 7.69-7.66(m, 4H), 7.62(d, 2H), 7.58-7.52(m, 14H), |
| | 7.39-7.34(m, 18H), 7.33-7.31(m, 4H) |
| 141 | ¹H NMR(400 MHz, CDCl₃): δ = 7.92(d, 2H), 7.91(d, 2H), 7.79(s, 2H), |
| | 7.77(s, 2H), 7.69-7.66(m, 4H), 7.64-7.60(m, 8H), 7.58(d, 4H), |
| | 7.58-7.52(m, 12H), 7.39-7.34(m, 18H), 7.33-7.31(m, 4H), 1.66(s, 12H) |
| 142 | ¹H NMR(400 MHz, CDCl₃): δ = 7.96(d, 2H), 7.92(d, 2H), 7.85(s, 2H), |
| | 7.78(s, 2H), 7.69-7.65(m, 6H), 7.62(d, 2H), 7.58-7.52(m, 20H), |
| | 7.39-7.34(m, 18H), 7.33-7.30(m, 4H), 1.65(s, 12H) |
| 143 | ¹H NMR(400 MHz, CDCl₃): δ = 7.96(s, 2H), 7.90(s, 2H), 7.79(d, 2H), |
| | 7.75(d, 2H), 7.69-7.66(m, 4H), 7.63(d, 2H), 7.59-7.52(m, 22H), |
| | 7.39-7.34(m, 18H), 7.33-7.31(m, 4H) |
| 144 | ¹H NMR(400 MHz, CDCl₃): δ = 7.91(s, 2H), 7.90(s, 2H), 7.76(d, 2H), |
| | 7.75(d, 2H), 7.69-7.66(m, 4H), 7.62(d, 4H), 7.59(d, 4H), 7.58-7.52(m, |
| | 16H), 7.40-7.34(m, 18H), 7.33-7.31(m, 4H) |
| 145 | ¹H NMR(400 MHz, CDCl₃): δ = 7.96(s, 2H), 7.90(s, 2H), 7.79(d, 2H), |
| | 7.74(d, 2H), 7.69-7.67(m, 2H), 7.63(d, 2H), 7.61(d, 1H), 7.60-7.50(m, |
| | 14H), 7.46(s, 1H), 7.40-7.29(m, 20H), 7.18(d, 1H), 2.39(s, 3H) |
| 146 | ¹H NMR(400 MHz, CDCl₃): δ = 7.96(s, 2H), 7.90(s, 2H), 7.79(d, 2H), |
| | 7.74(d, 2H), 7.69-7.67(m, 2H), 7.63(d, 2H), 7.61(d, 1H), 7.60-7.50(m, |
| | 14H), 7.46(s, 1H), 7.40-7.29(m, 2H), 7.18(d, 1H), 1.40(s, 9H) |
| 147 | ¹H NMR(400 MHz, CDCl₃): δ = 7.96(s, 2H), 7.90(s, 4H), 7.79(d,, 2H), |
| | 7.76-7.73(m, 4H), 7.69-7.65(m, 4H), 7.63-7.60(m, 2H), 7.58-7.52(m, |
| | 16H), 7.40-7.33(m, 18H), 7.32-7.29(m, 4H) |
| 148 | ¹H NMR(400 MHz, CDCl₃): δ = 7.96(s, 2H), 7.92(d, 1H), 7.90(s, 3H), |
| | 7.85(d, 1H), 7.79-7.76(m, 3H), 7.74-7.71(m, 3H), 7.68-7.66(m, 2H), |
| | 7.62-7.59(m, 3H), 7.58-7.52(m, 16H), 7.41-7.33(m, 19H), 7.32-7.28(m, |
| | 3H), 1.67(s, 6H) |
| 149 | ¹H NMR(400 MHz, CDCl₃): δ = 7.96(s, 2H), 7.90(s, 3H), 7.78-7.76(d, |
| | 2H), 7.75-7.73(d, 2H), 7.68-7.66(m, 3H), 7.62-7.60(d, 2H), |
| | 7.58-7.52(m, 15H), 7.50-7.47(m, 2H), 7.41-7.34(m, 18H), 7.33-7.29(m, |
| | 4H), 7.22(t, 1H) |
| 150 | ¹H NMR(400 MHz, CDCl₃): δ = 7.95(d, 2H), 7.91(d, 2H), 7.84(s, 2H), |
| | 7.77(s, 2H), 7.69-7.65(m, 4H), 7.62-7.59(m, 3H), 7.58-7.52(m, 12H), |
| | 7.47(s, 1H), 7.41-7.34(m, 18H), 7.33-7.31(m, 2H), 7.20(d, 1H), 2.46(s, |
| | 3H), 1.67(s, 12H) |
| 151 | ¹H NMR(400 MHz, CDCl₃): δ = 7.94(d, 2H), 7.92-7.89(m, 4H), |
| | 7.85-7.83(s, 2H), 7.78(s, 2H), 7.75-7.73(m, 2H), 7.69-7.64(m, 6H), |
| | 7.62-7.60(d, 2H), 7.59-7.48(m, 14H), 7.46-7.33(m, 18H), 7.33-7.30(m, |
| | 4H), 1.67(s, 12H) |
| 152 | ¹H NMR(400 MHz, CDCl₃): δ = 7.95(d, 2H), 7.92-7.89(m, 4H), |
| | 7.85-7.83(m, 3H), 7.78(s, 3H), 7.74(d, 1H), 7.69-7.66(m, 4H), |
| | 7.62-7.59(m, 3H), 7.58-7.48(m, 14H), 7.46-7.33(m, 18H), 7.34-7.32(m, |
| | 2H), 7.29-7.27(m, 2H), 1.68(s, 12H), 1.66(s, 6H) |
| 153 | ¹H NMR(400 MHz, CDCl₃): δ = 7.70-7.66(m, 8H), 7.61(d, 4H), 7.58(d, |
| | 4H), 7.57-7.52(m, 12H), 7.41-7.34(m, 18H), 7.34-7.30(m, 8H) |
| 154 | ¹H NMR(400 MHz, CDCl₃): δ = 7.95(s, 2H), 7.90(s, 2H), 7.79-7.77(d, |
| | 2H), 7.75-7.73(m, 2H), 7.70-7.64(m, 8H), 7.60(d, 2H), 7.59-7.48(m, |
| | 14H), 7.42-7.28(m, 26H) |
| 155 | ¹H NMR(400 MHz, CDCl₃): δ = 7.94(d, 2H), 7.91(d, 2H), 7.85(s, 2H), |
| | 7.79(s, 2H), 7.73-7.63(m, 10H), 7.60(d, 2H), 7.59(d, 2H), 7.59-7.49(m, |
| | 12H), 7.46-7.33(m, 18H), 7.33-7.25(m, 8H), 1.68(s, 12H) |

### Example 1-55

### Manufacture of OLED's Using the Compounds According to the Invention

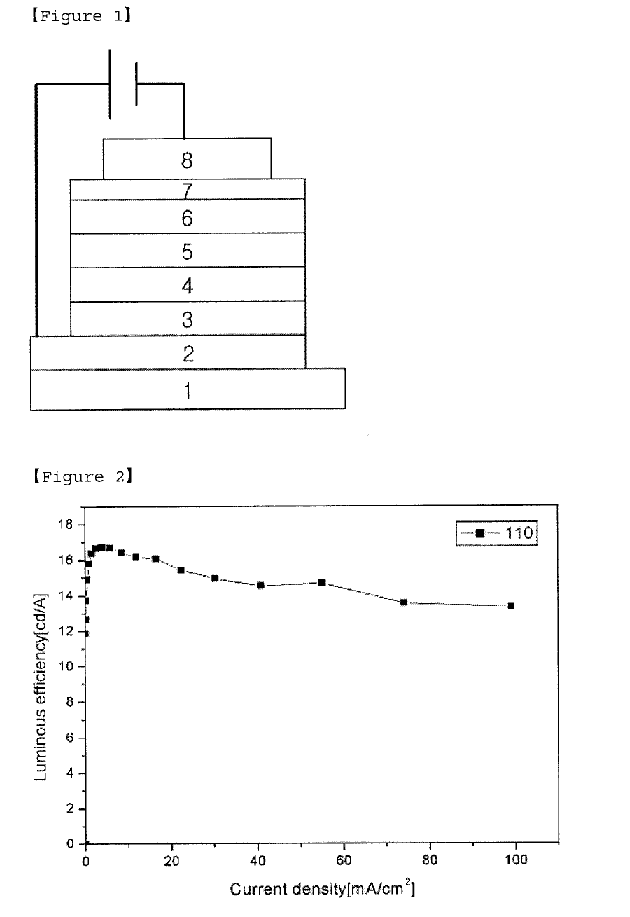

OLED's were manufactured as illustrated in FIG. 1 by using the electron transportation layer materials according to the invention.

First, a transparent electrode ITO thin film (2) (15Ω/□) obtained from glass (1) for OLED was subjected to ultrasonic washing with trichloroethylene, acetone, ethanol and distilled water, subsequently, and stored in isopropanol before use.

Then, an ITO substrate was equipped in a substrate folder of a vacuum vapor-deposit device, and 4,4′,4″-tris(N,N-(2-naphthyl)-phenylamino)triphenylamine (2-TNATA) was placed in a cell of the vacuum vapor-deposit device, which was then vented to reach 10⁻⁶ torr of vacuum in the chamber. Electric current was applied to the cell to evaporate 2-TNATA to vapor-deposit a hole injection layer (3) with 60 nm of thickness on the ITO substrate.

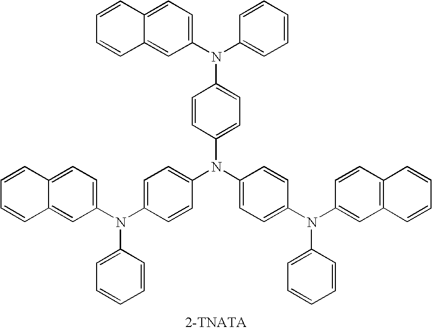

Then, another cell of the vacuum vapor-deposit device was charged with N,N′-bis(α-naphthyl)-N,N′-diphenyl-4,4′-diamine (NPB), and electric current was applied to the cell to evaporate NPB to vapor-deposit a hole transportation layer (4) with 20 nm of thickness on the hole injection layer.

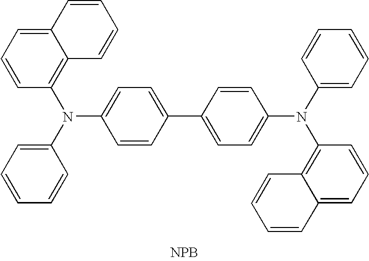

After formation of the hole injection layer and the hole transportation layer, an electroluminescent layer was vapor-deposited as follows. One cell of the vacuum deposition device was charged with tris(8-hydroxyquinoline)aluminum (III) (Alq) as an electroluminescent host material, while another cell of said device was charged with coumarin 545T (C545T), respectively. Two substances were doped by evaporating with different rates to vapor-deposit an electroluminescent layer (5) with a thickness of 30 nm on the hole transportation layer. The doping concentration was preferably 2 to 5 mold on the basis of Alq.

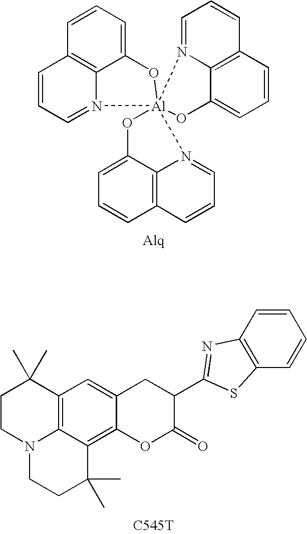

Then, one of the compounds prepared according to the present invention (for example, Compound 110) was vapor-deposited with a thickness of 20 nm, as an electron transportation layer (6), followed by lithium quinolate (Liq) with a thickness of from 1 to 2 nm as an electron injection layer (7). Thereafter, an Al cathode (8) was vapor-deposited with a thickness of 150 nm by using another vacuum vapor-deposit device to manufacture an OLED.

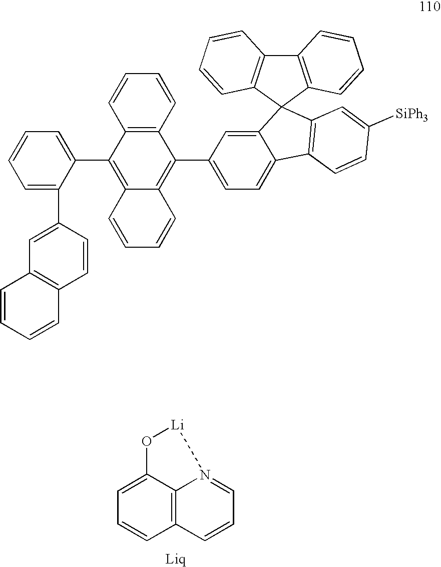

### Comparative Example 1

### Manufacture of an OLED Using Conventional EL Material

A hole injection layer (3), a hole transportation layer (4) and an electroluminescent layer (5) were formed according to the same procedure as described in Example 1, and Alq (tris(8-hydroxyquinoline)-aluminum (III) having the structure shown below was vapor-deposited with 20 nm of thickness as an electron transportation layer (6), followed by lithium quinolate (Liq) with 1˜2 nm of thickness as an electron injection layer (7). An Al cathode (8) was vapor-deposited by using another vacuum vapor-deposit device with a thickness of 150 nm, to manufacture an OLED.

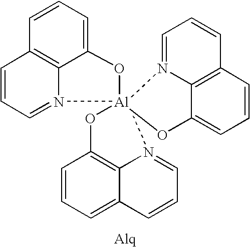

### Experimental Example 1

### Examination of Properties of OLED

Current luminous efficiencies and power efficiencies of OLED's comprising one of the organic electroluminescent compounds (Compound 101 to 155) according to the invention prepared from Example 1 to 155, and the OLED of Comparative Example 1 comprising the conventional electroluminescent compound were measured at 1,000 cd/m², of which the results are shown in Table 3.

TABLE 3

| | Electron | | Luminous | Power | |
|---|---|---|---|---|---|
| | transportation | Operation | efficiency | efficiency | Color |
| | layer | voltage(V) | (cd/A) | (lm/W) | coordinate |
| | material | @1000 cd/m² | @1000 cd/m² | @1000 cd/m² | (x, y) |
| Ex. 2 | Comp. 102 | 5 | 15 | 9.4 | 0.28, 0.65 |
| Ex. 3 | Comp. 103 | 5 | 15.1 | 10.5 | 0.28, 0.65 |
| Ex. 10 | Comp. 110 | 4.5 | 16.7 | 11.6 | 0.28, 0.64 |
| Ex. 20 | Comp. 120 | 4.5 | 15.5 | 10.8 | 0.28, 0.64 |
| Ex. 25 | Comp. 125 | 5 | 15 | 9.4 | 0.29, 0.63 |
| Ex. 30 | Comp. 130 | 4.5 | 14 | 9.7 | 0.27, 0.62 |
| Ex. 41 | Comp. 141 | 5 | 14.4 | 9.0 | 0.29, 0.65 |
| Ex. 50 | Comp. 150 | 5 | 14.7 | 9.2 | 0.29, 0.65 |
| Comp. | Alq₃ | 6 | 11.6 | 6.1 | 0.30, 0.65 |
| Ex. 1 | | | | | |

As can be seen from Table 3, Compound (110) as the electron transportation material (Example 10) showed highest power efficiency. In particular, Compound (110) of Example 10 and Compound (120) of Example 20 showed about 2-fold enhancement of power efficiency as compared to the conventional material, Alq, as the electron transportation layer.

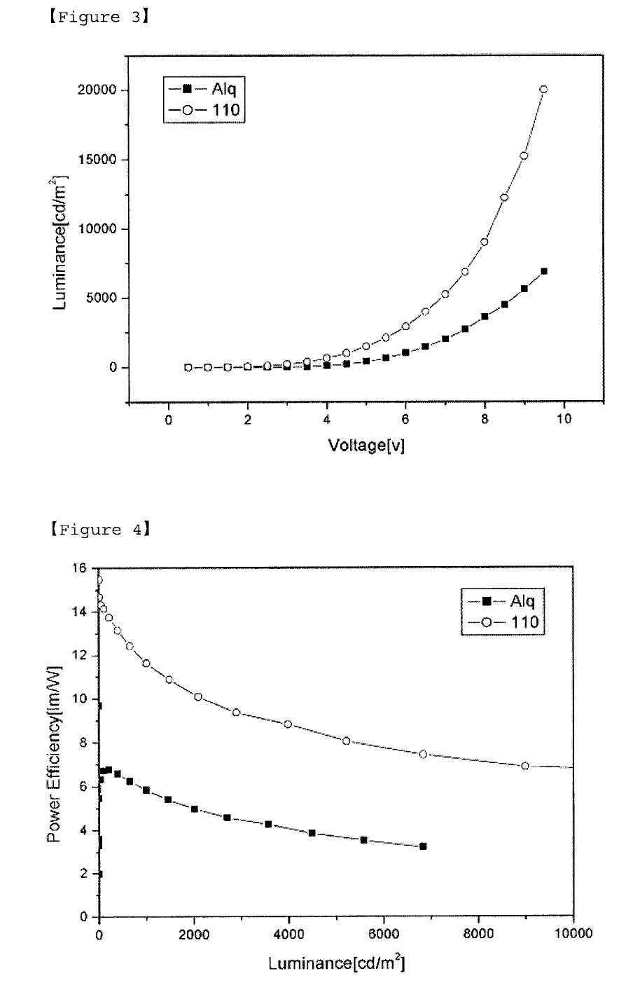

FIG. 2 is a luminous efficiency curve when compound (110) was employed as an electron transportation material. FIG. 3 and FIG. 4 are luminance-voltage and power efficiency-luminance curves, respectively, which compare Compound (110) according to the invention and Alq employed as the electron transportation layer.

From Table 3 showing the properties of the compounds developed by the present invention employed as an electron transportation layer, it is confirmed that the compounds developed by the invention show excellent properties as compared to conventional substances in view of the performances.

Particularly, it is found that the improvement of power consumption due to lowered operation voltage in an OLED employing the material according to the invention comes from improvement of current properties, not from simple improvement of luminous efficiency.

### INDUSTRIAL APPLICABILITY

The compounds according to the invention for an electron transportation layer are advantageous in that they can substantially improve the power efficiency by noticeably lowering the operational voltage and increasing the current efficiency. Thus, it is expected that the material can greatly contribute to reduce the power consumption of an OLED.

1. An organic electroluminescent compound represented by Chemical Formula (1): 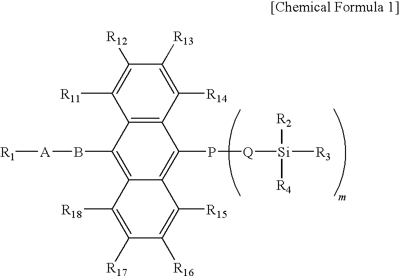
wherein, A, B, P and Q independently represent a chemical bond, or (C₆-C₃₀)arylene with or without one or more substituent(s) selected from a linear or branched and saturated or unsaturated (C₁-C₃₀)alkyl with or without halogen substituent(s), (C₆-C₃₀)aryl and halogen; 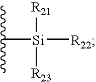
R₁ represents hydrogen, (C₆-C₃₀)aryl or
R₂, R₃ and R₄ independently represent a linear or branched and saturated or unsaturated (C₁-C₃₀)alkyl or (C₆-C₃₀)aryl;
R₁₁ through R₁₈ independently represent hydrogen, or a linear or branched and saturated or unsaturated (C₁-C₃₀)alkyl or (C₆-C₃₀)aryl;
R₂₁, R₂₂ and R₂₃ independently represent a linear or branched and saturated or unsaturated (C₁-C₃₀)alkyl or (C₆-C₃₀)aryl; and
m is an integer of 1 or 2;
provided that A, B, P and Q are not chemical bonds all at the same time; if both -A-B- and —P-Q- are phenylene, R₁ necessarily represents hydrogen; excluding both -A-B- and —P-Q-being spirobifluorenylenes, the arylene and aryl may be further substituted by a linear or branched and saturated or unsaturated (C₁-C₃₀)alkyl, (C₁-C₃₀)alkoxy, halogen, (C₃-C₁₂)cycloalkyl, phenyl, naphthyl or anthryl.

2. An organic electroluminescent compound according to claim 1, wherein R₁ represents hydrogen, phenyl, naphthyl, anthryl, biphenyl, phenanthryl, naphthacenyl, fluorenyl, 9,9-dimethyl-fluoren-2-yl, pyrenyl, phenylenyl, fluoranthenyl, trimethylsilyl, triethylsilyl, tripropylsilyl, tri(t-butyl)silyl, t-butyldimethylsilyl, triphenylsilyl or phenyldimethylsilyl; R₂, R₃ and R₄ independently represent methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl or fluorenyl; and R₁₁ through R₁₈ are independently selected from hydrogen, methyl, ethyl, n-propyl, i-propyl, i-butyl, t-butyl, n-pentyl, i-amyl, n-hexyl, n-heptyl, n-octyl, 2-ethylhexyl, n-nonyl, decyl, dodecyl, hexadecyl, phenyl, naphthyl, anthryl or fluorenyl.

3. An organic electroluminescent compound according to claim 2, wherein -A-B- is selected from the following structures: 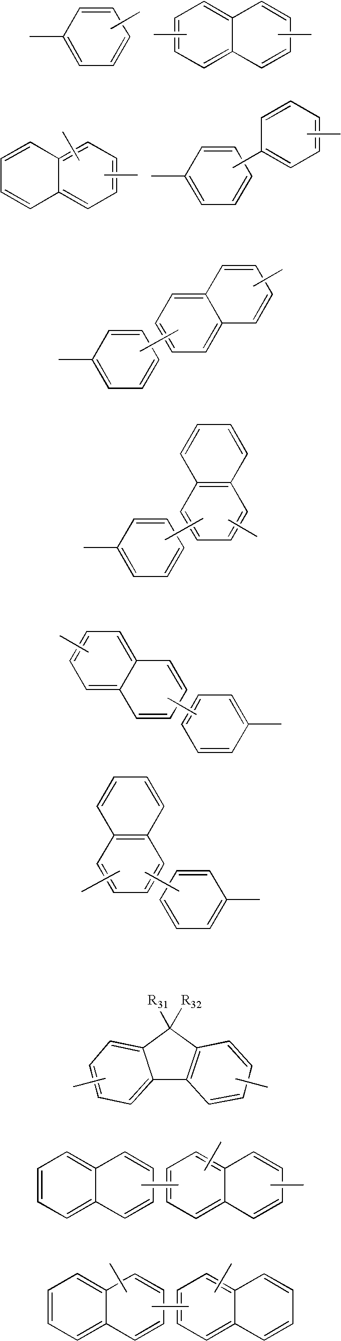 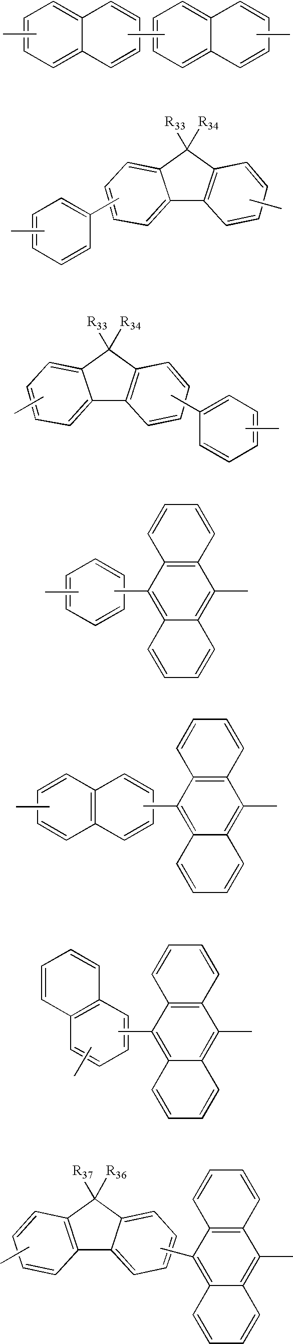
wherein R₃₁, R₃₂, R₃₃, R₃₄, R₃₅, R₃₆, R₃₇ and R₃₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

4. An organic electroluminescent compound according to claim 2, wherein —P-Q- is selected from the following structures: 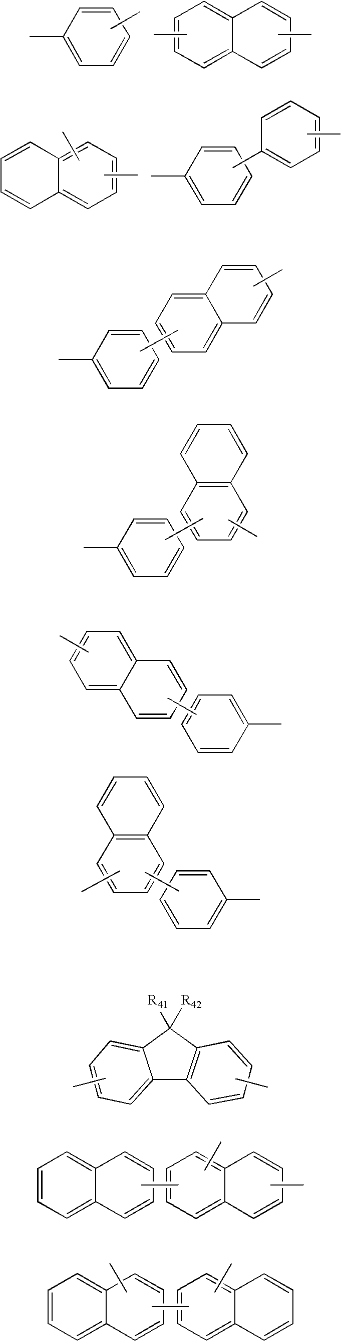 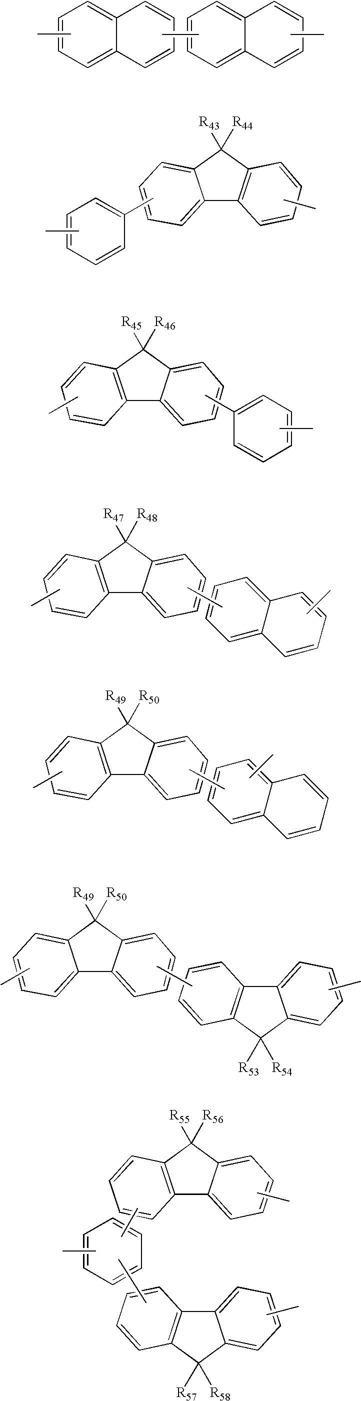 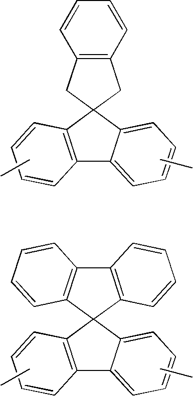
wherein, R₄₁ through R₅₈ independently represent hydrogen, methyl, ethyl, propyl, butyl, isobutyl, pentyl, hexyl, ethylhexyl, heptyl, octyl, isooctyl, nonyl, dodecyl, hexadecyl, phenyl, tolyl, biphenyl, benzyl, naphthyl, anthryl or fluorenyl.

5. An organic electroluminescent compound according to claim 1, which is selected from the following compounds.

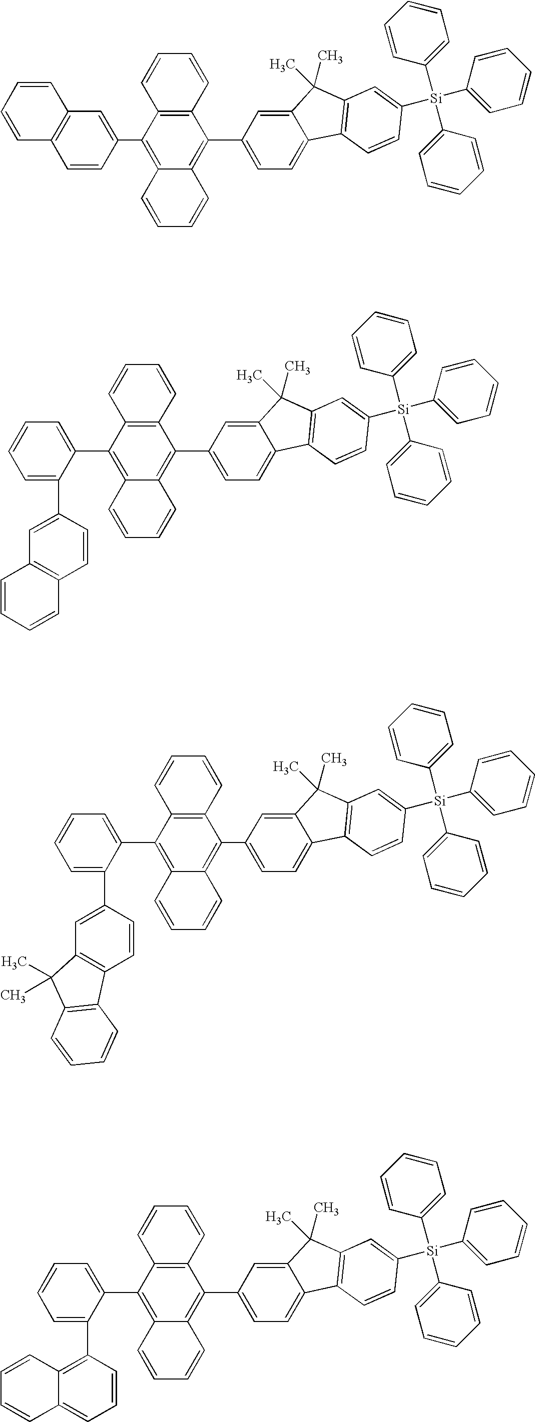

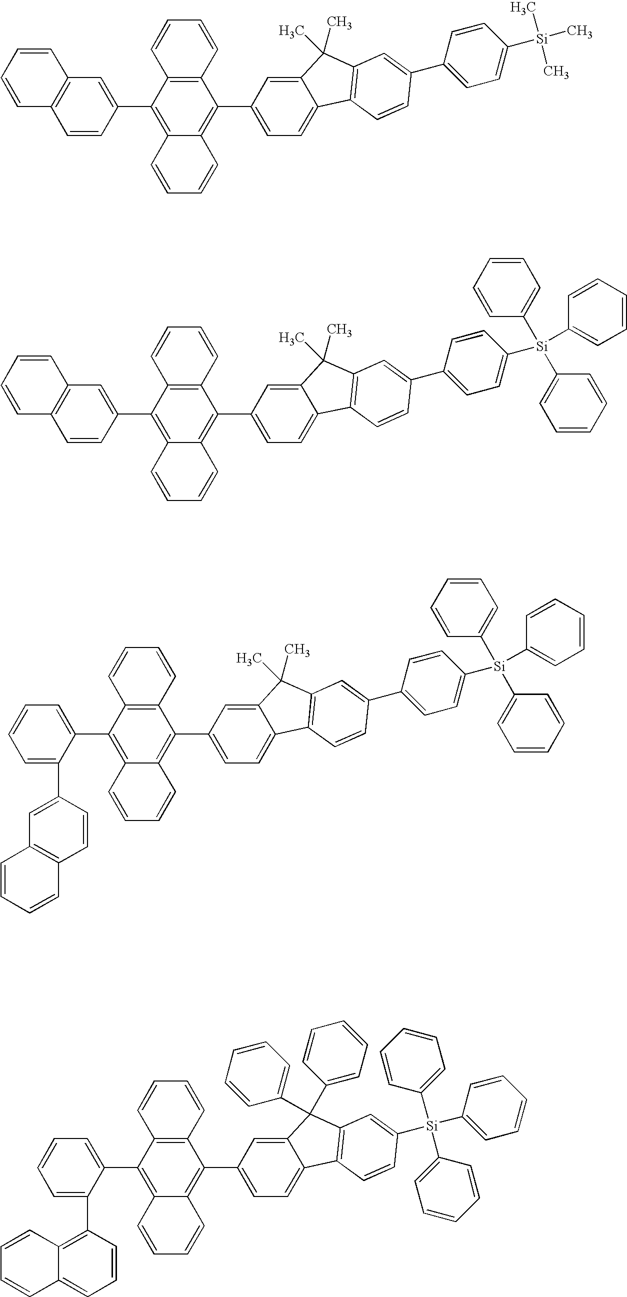

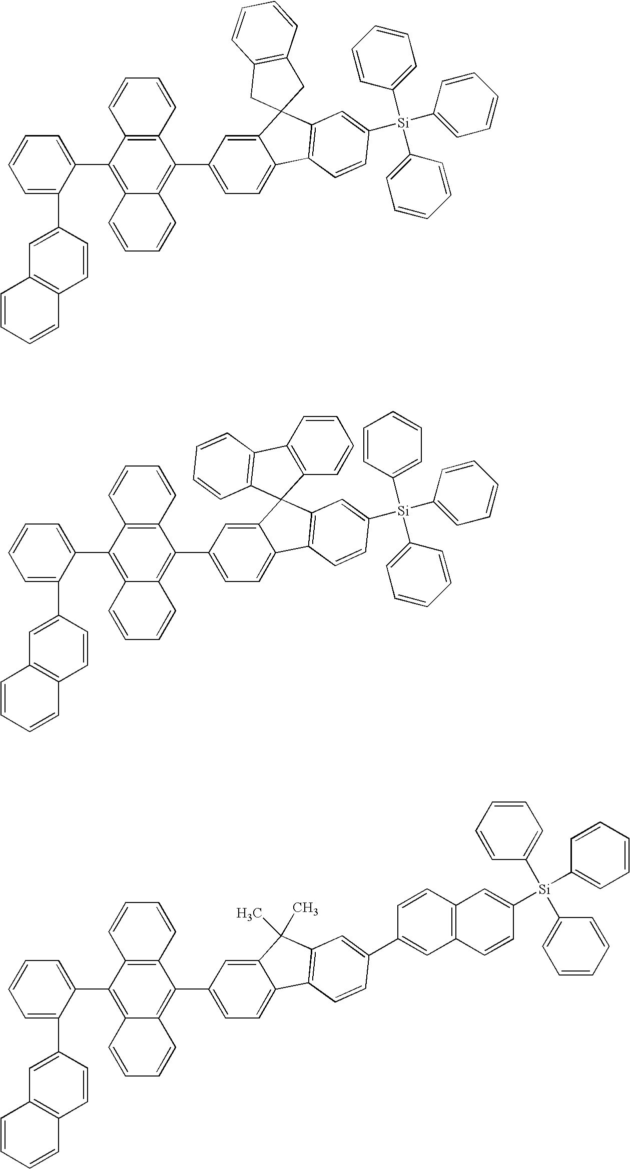

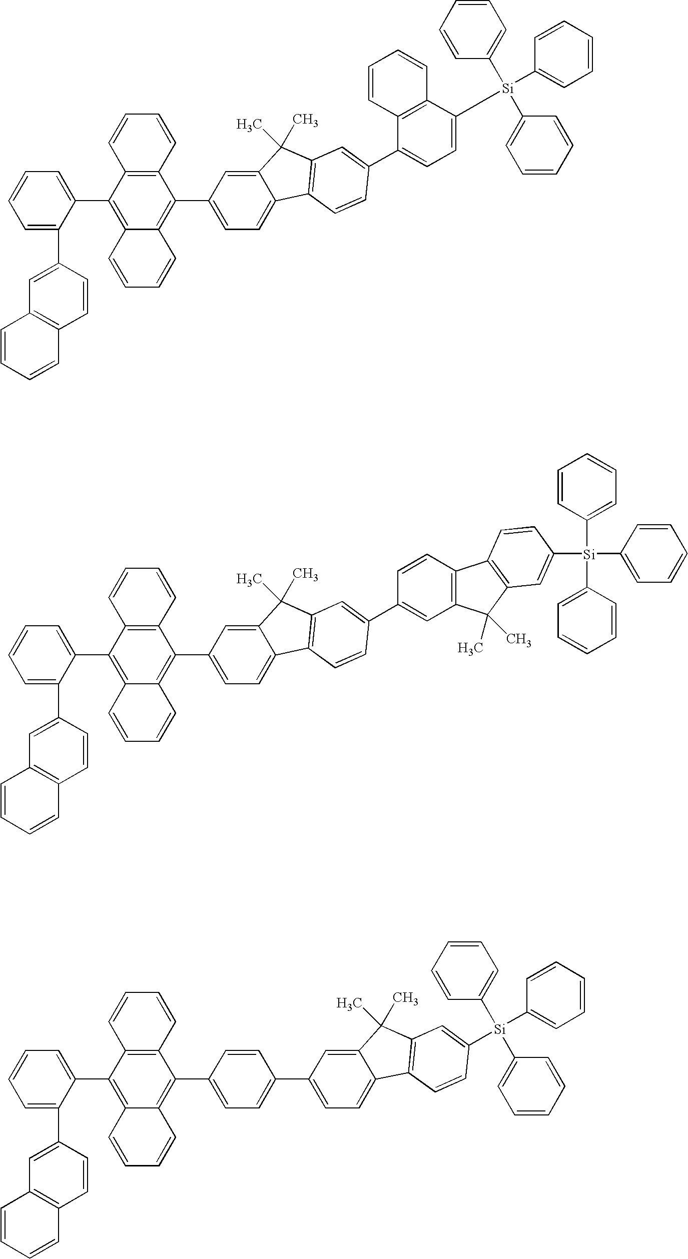

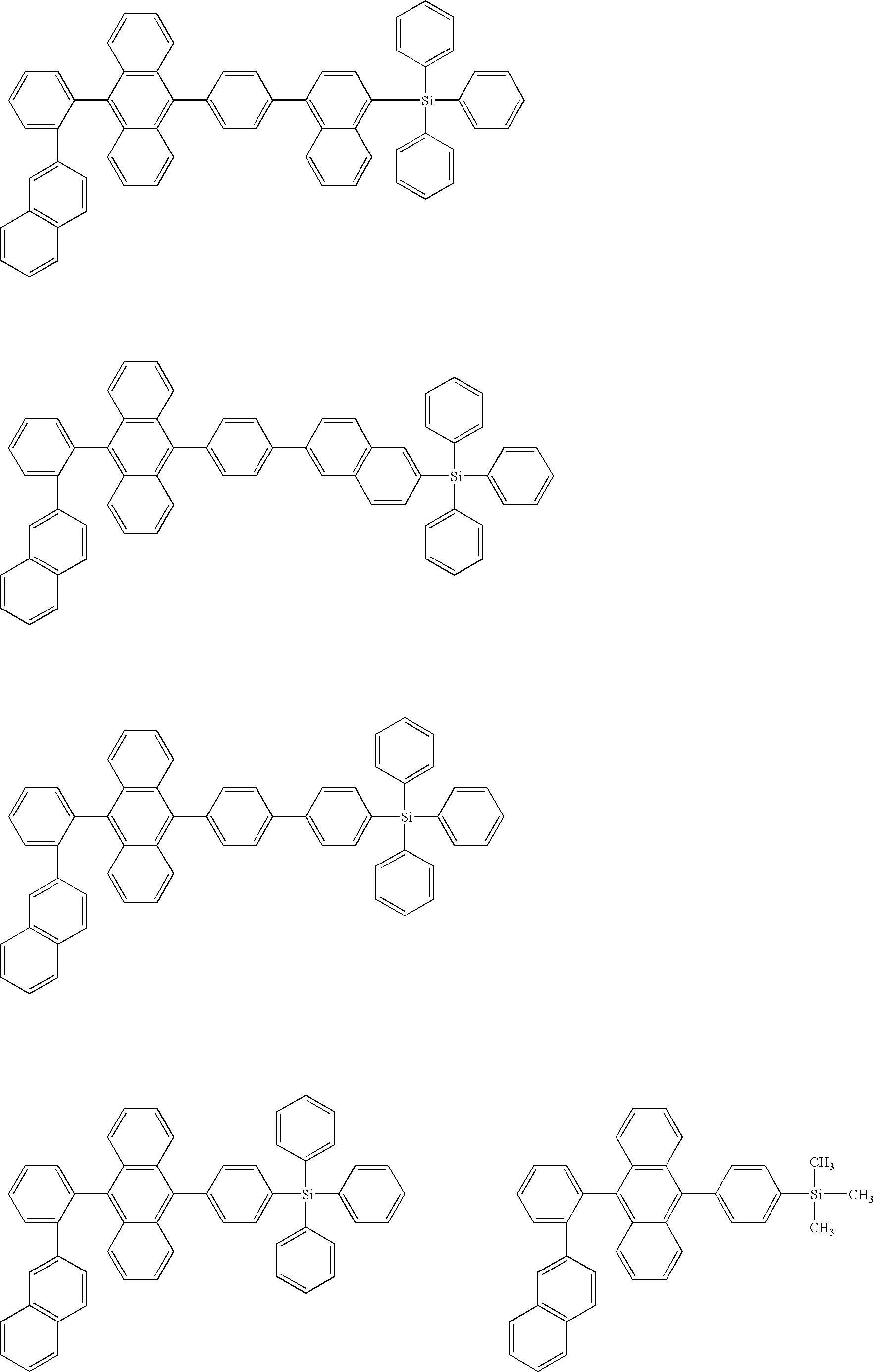

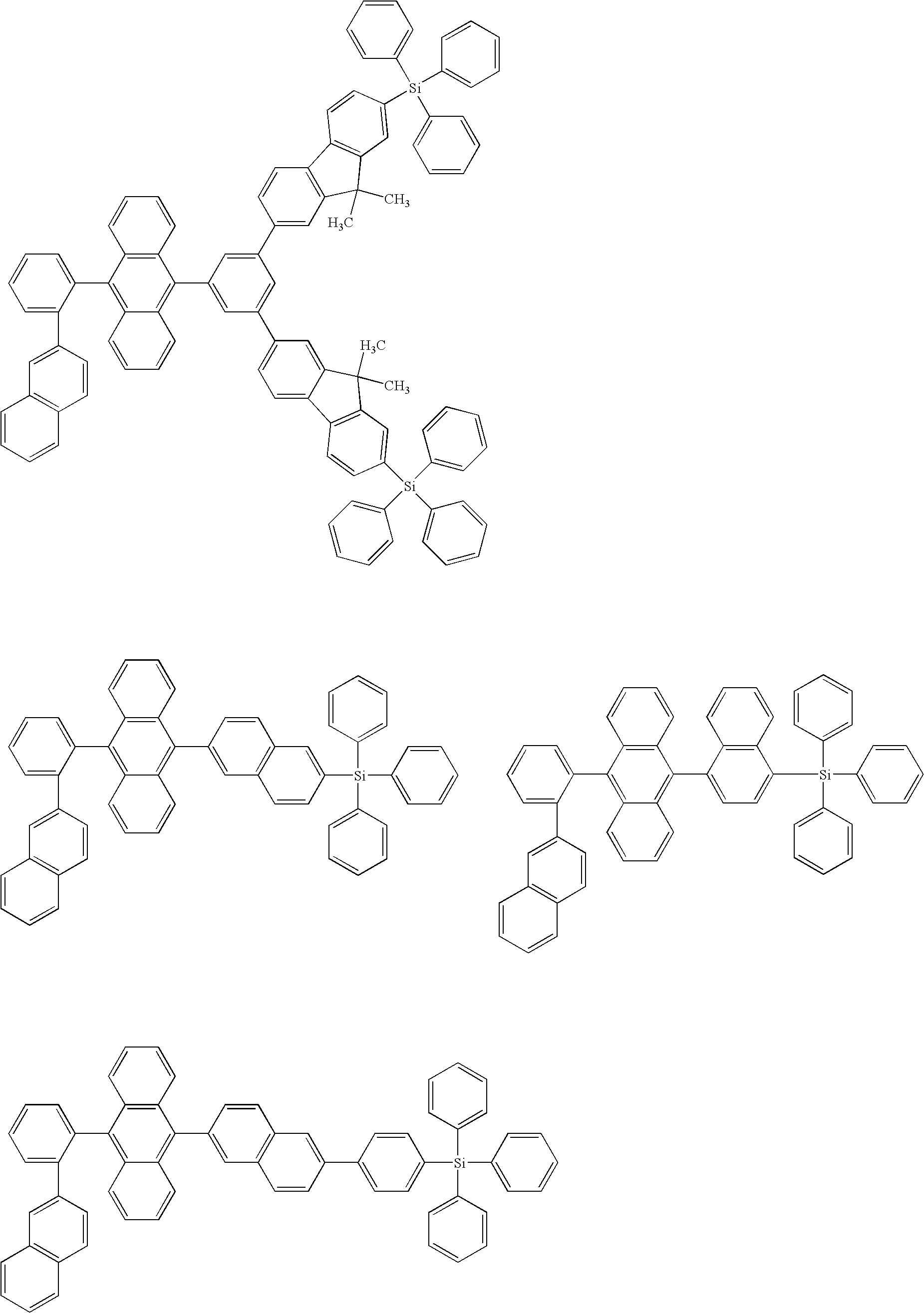

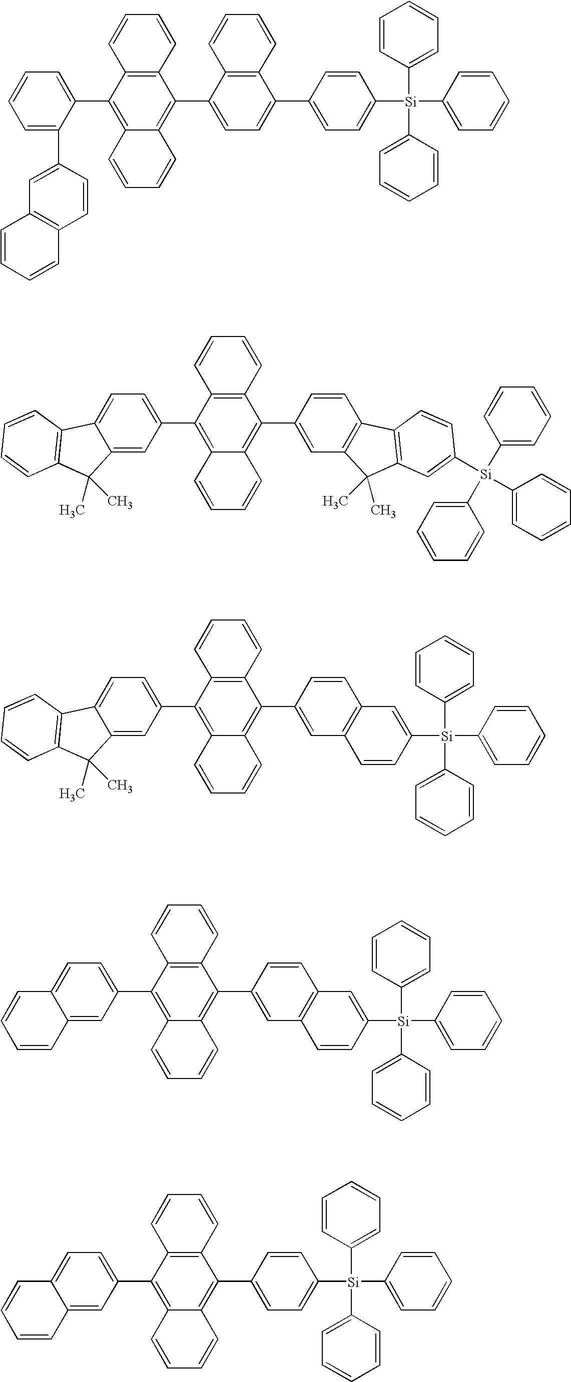

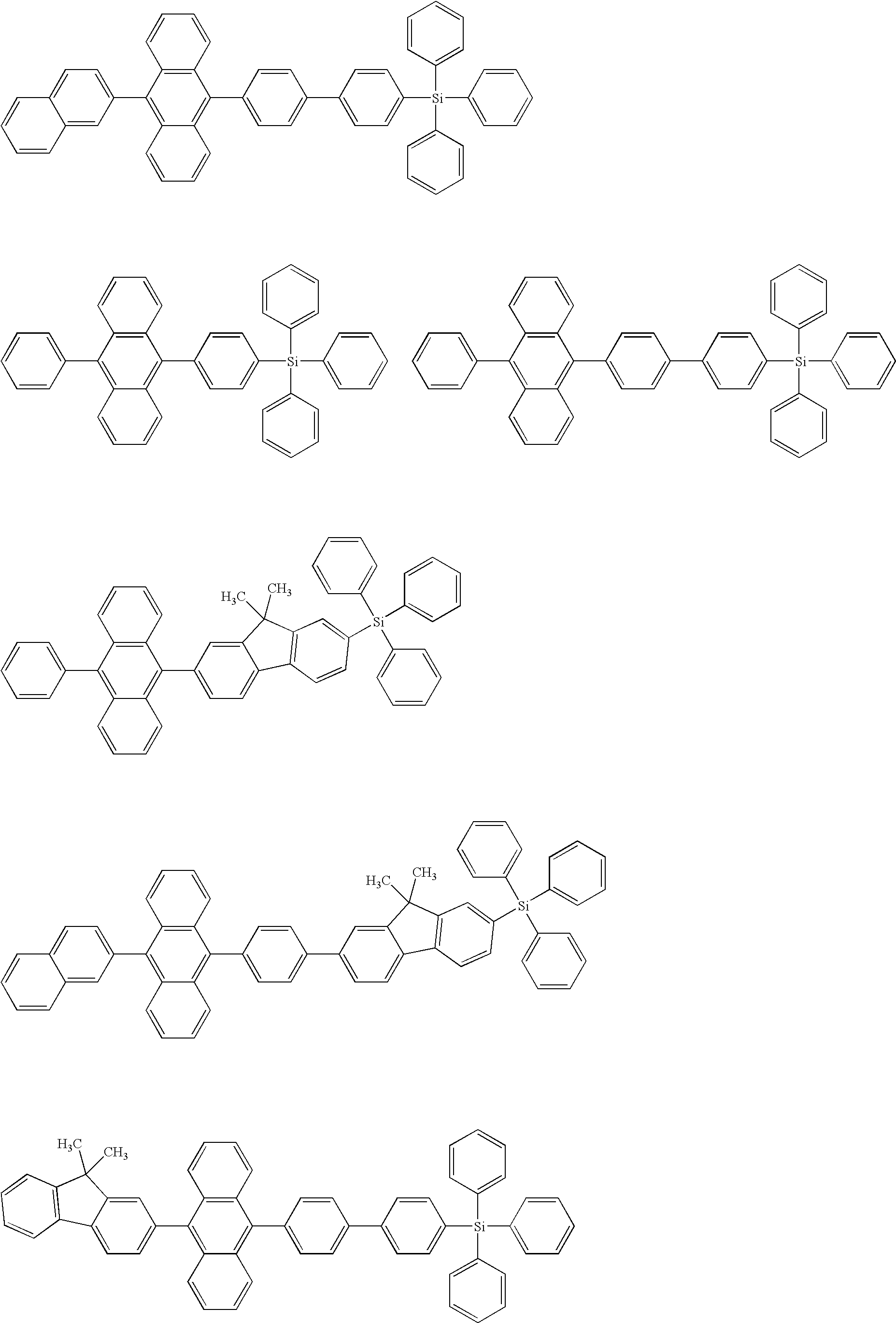

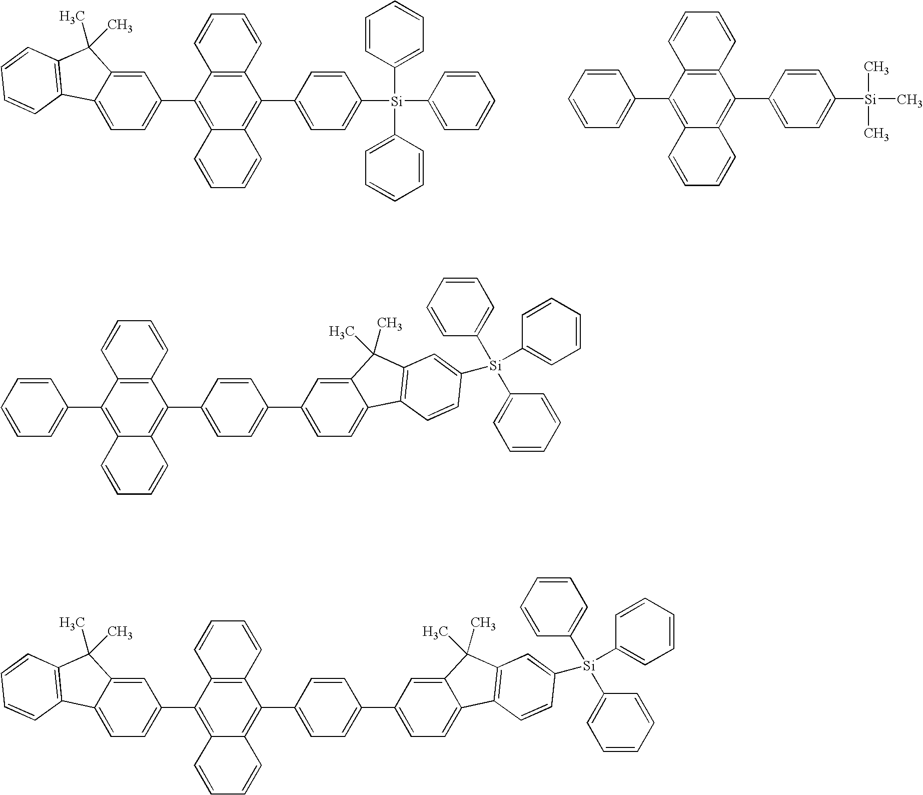

6. An organic electroluminescent compound according to claim 1, which is selected from the following compounds.

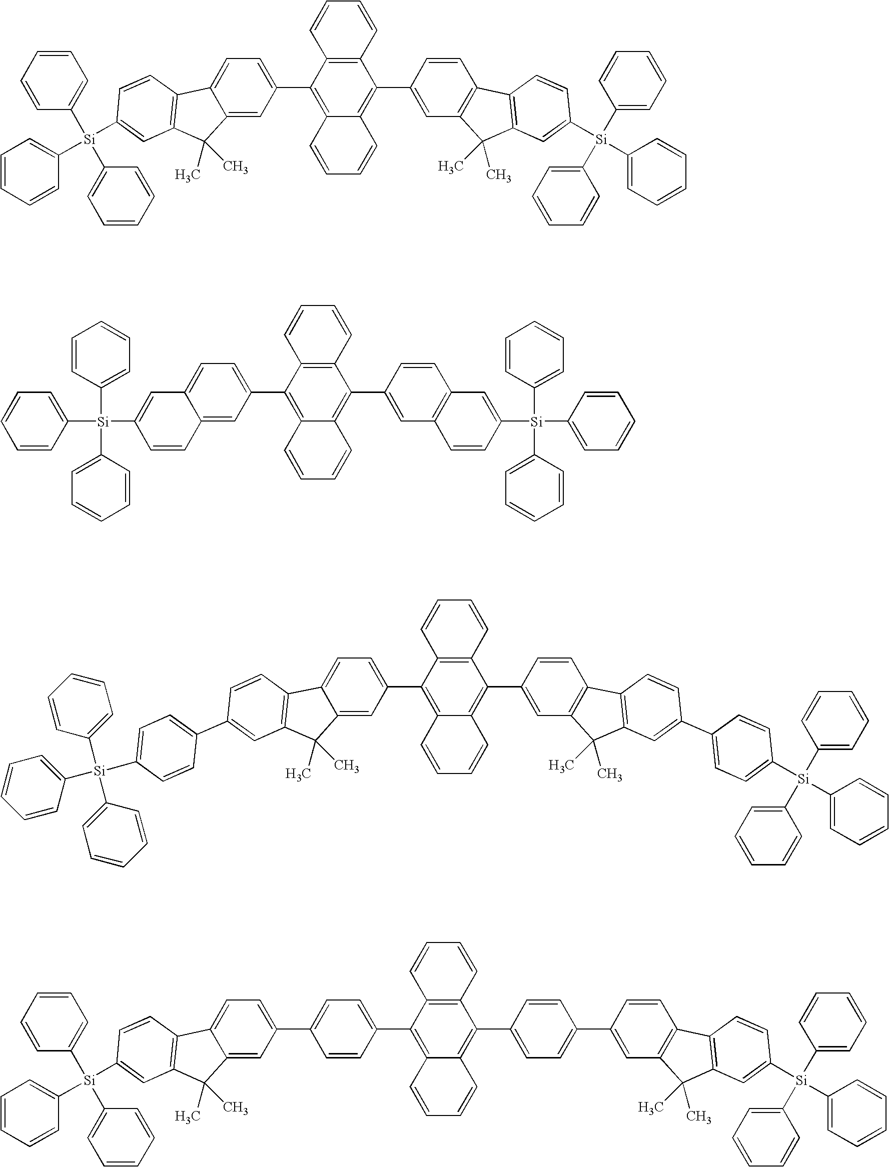

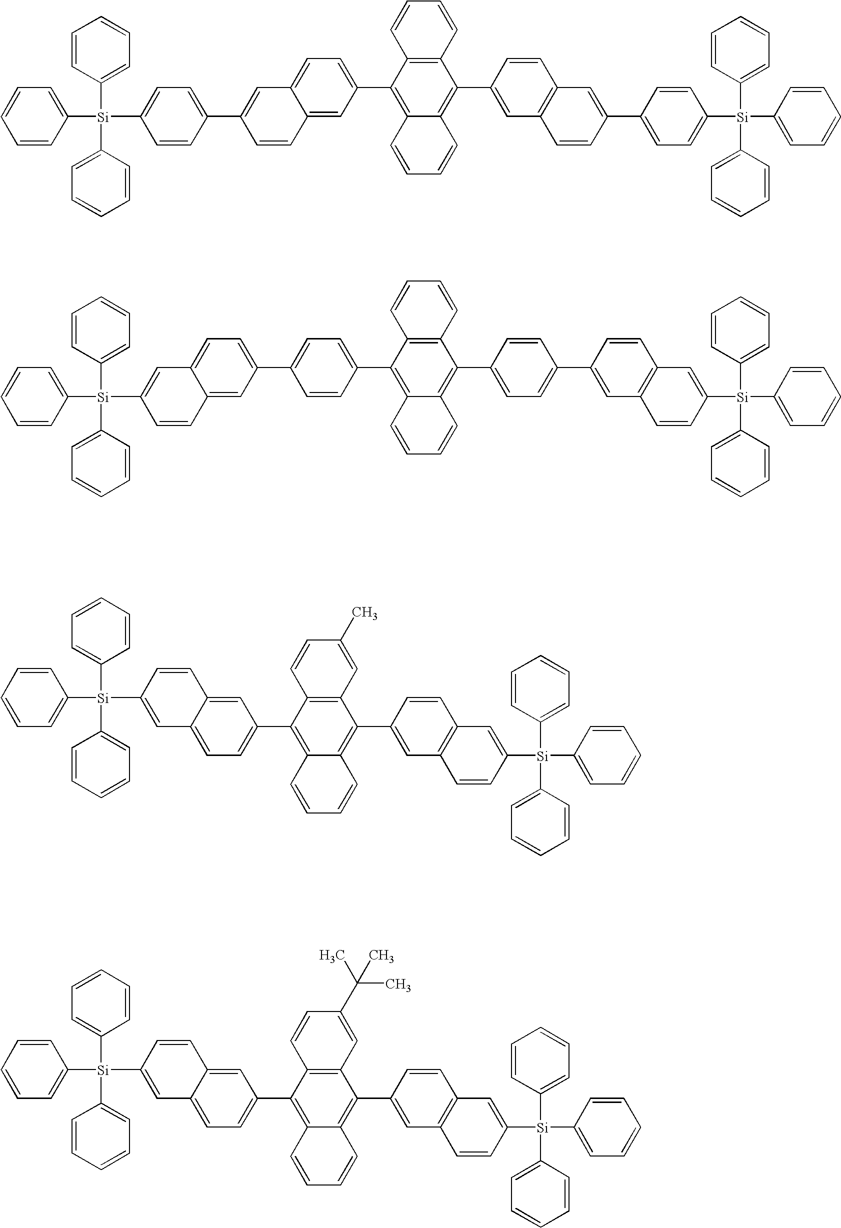

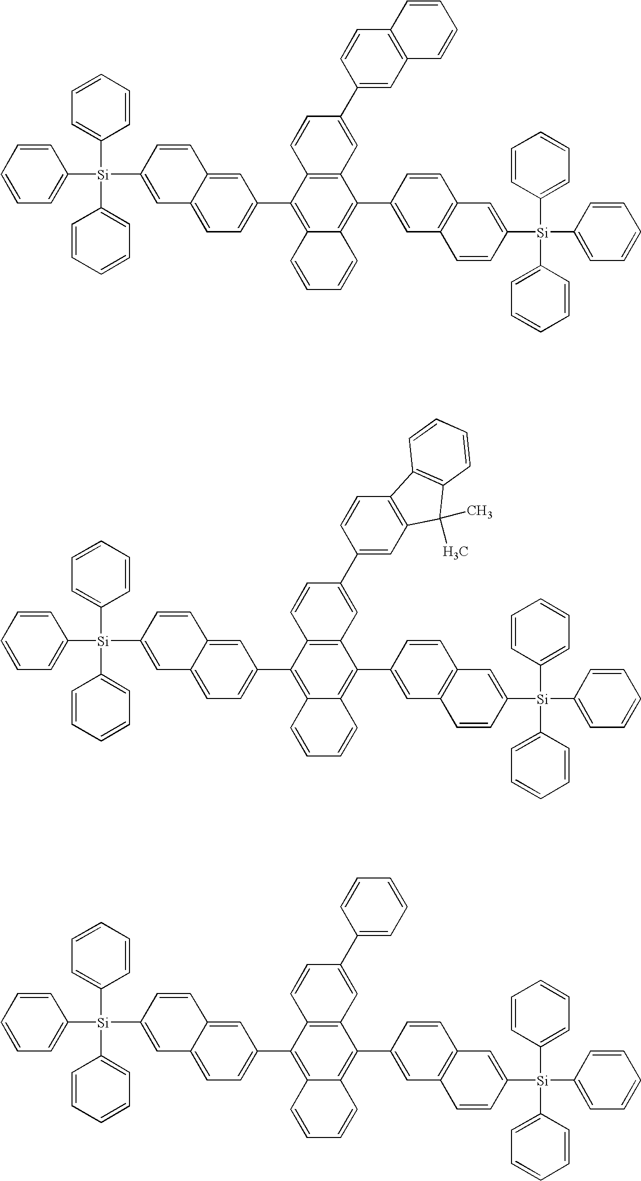

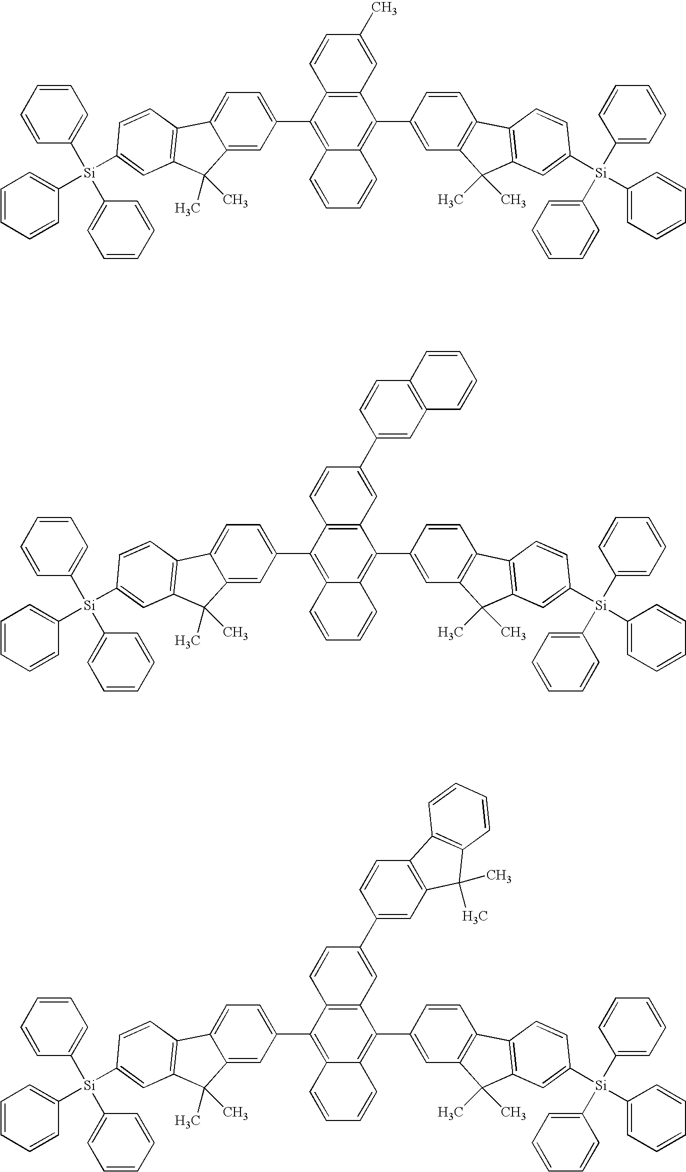

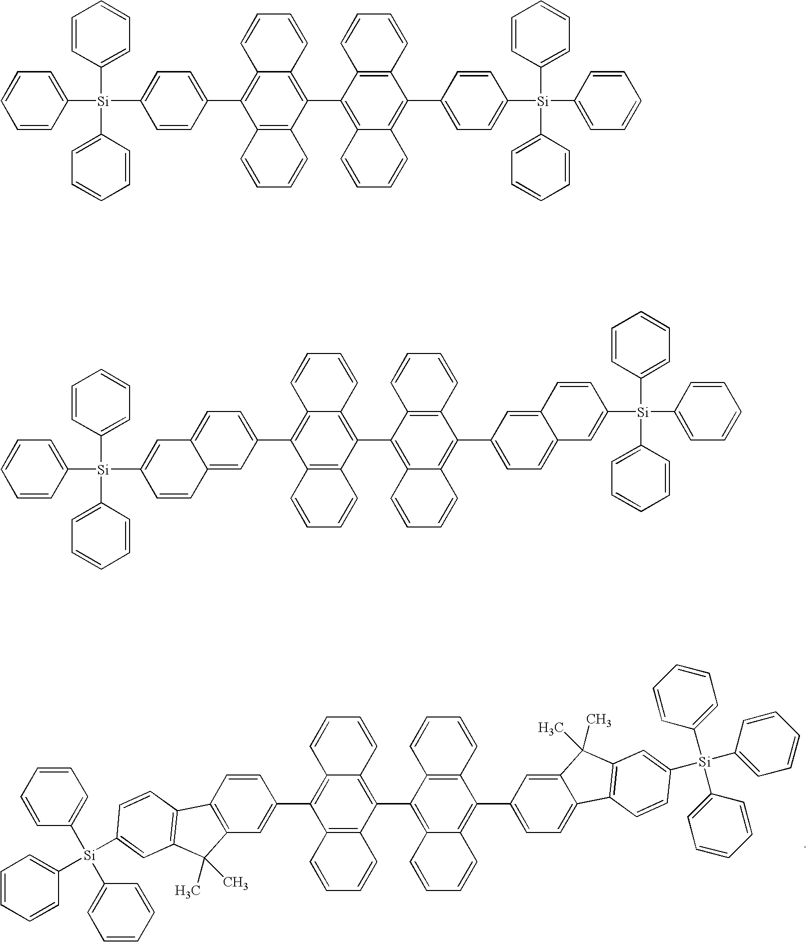

7. An organic electroluminescent compound represented by Chemical Formula (2): 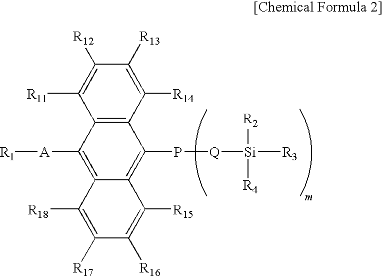
wherein, A represents phenylene, naphthylene or fluorenylene with or without a linear or branched and saturated or unsaturated (C₁-C₃₀)alkyl substituent(s);
P and Q independently represent a chemical bond, or (C₆-C₃₀)arylene with or without one or more substituent(s) selected from a linear or branched and saturated or unsaturated (C₁-C₃₀)alkyl with or without halogen substituent(s), (C₆-C₃₀)aryl and halogen;
R₁ represents hydrogen, phenyl, naphthyl, anthryl, biphenyl, phenanthryl, naphthacenyl, fluorenyl or 9,9-dimethyl-fluoren-2-yl;
R₂, R₃ and R₄ independently represent a linear or branched and saturated or unsaturated (C₁-C₃₀)alkyl or (C₆-C₃₀)aryl;
R₁₁ through R₁₈ independently represent hydrogen, or a linear or branched and saturated or unsaturated (C₁-C₃₀)alkyl or (C₆-C₃₀)aryl;
m is an integer of 1 or 2; and
the arylene or aryl may be further substituted by a linear or branched and saturated or unsaturated (C₁-C₃₀)alkyl, (C₁-C₃₀)alkoxy, halogen, (C₃-C₁₂)cycloalkyl, phenyl, naphthyl or anthryl.

8. An organic electroluminescent compound according to claim 7, which is selected from the following compounds.

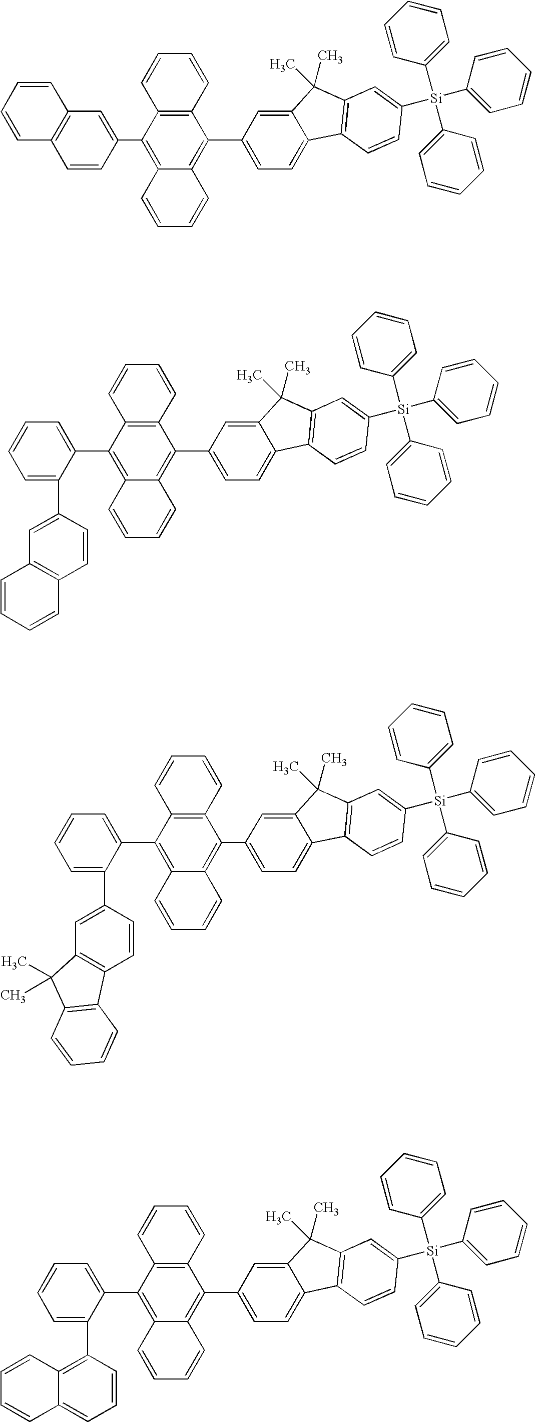

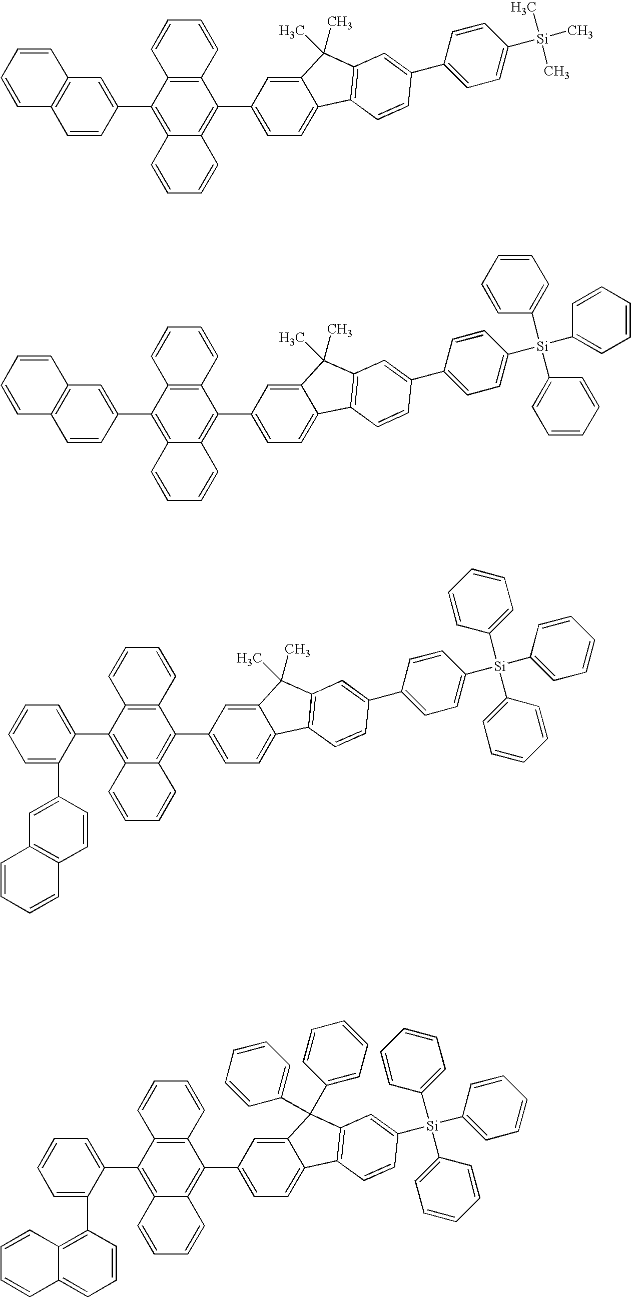

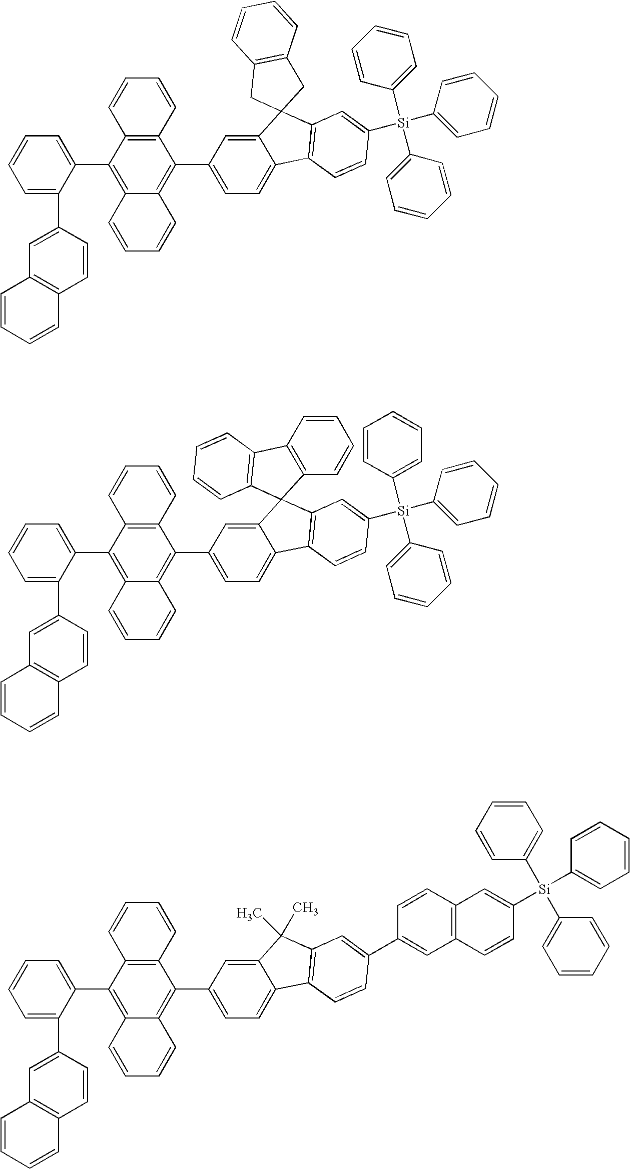

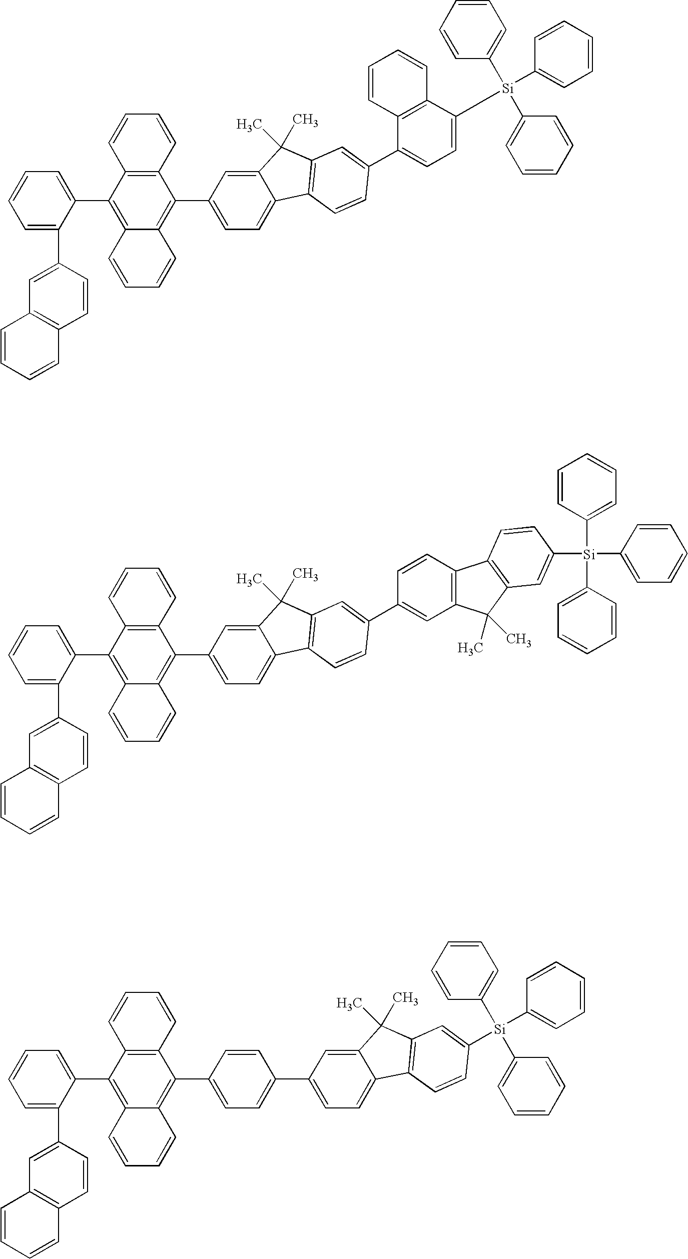

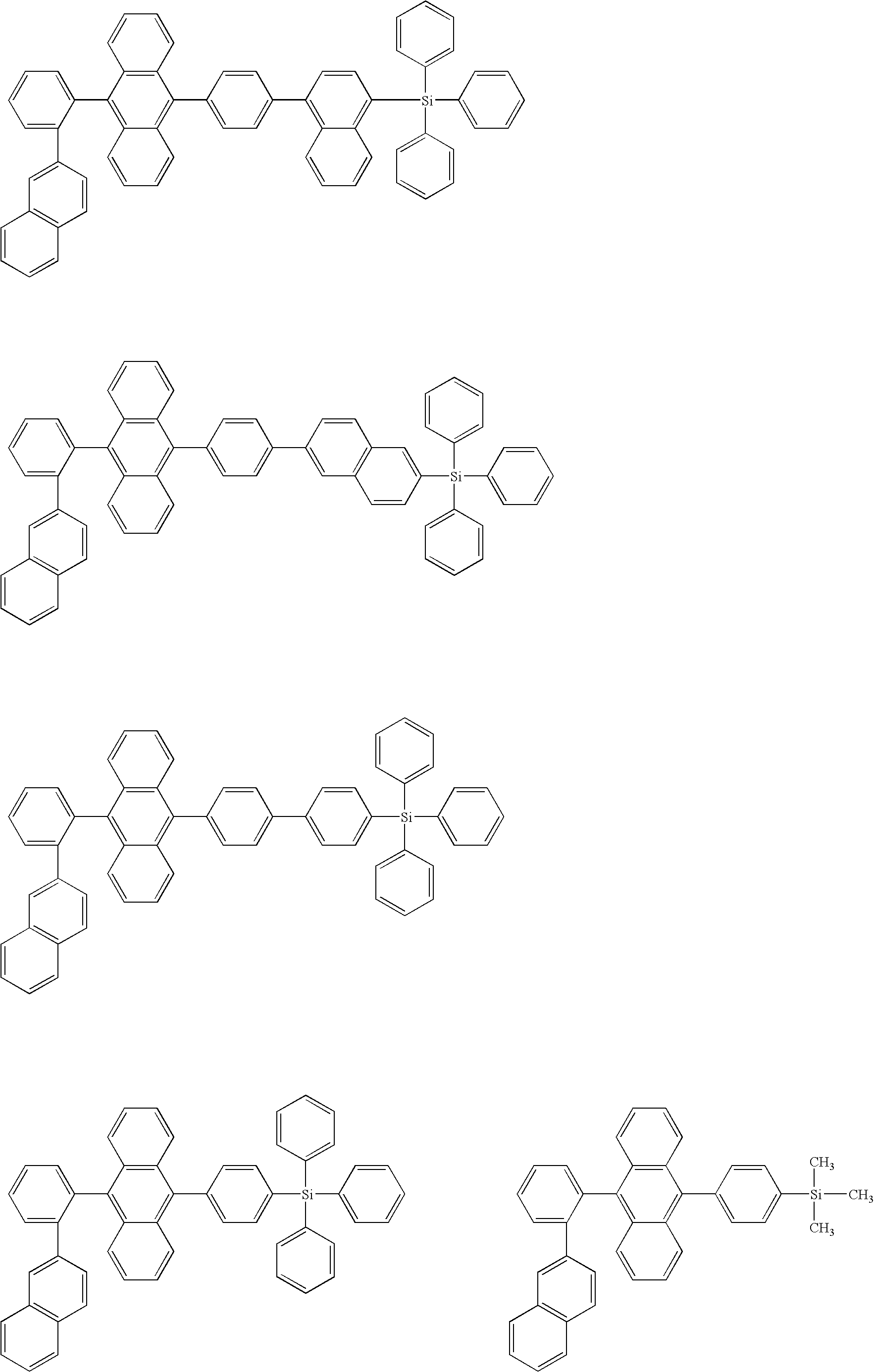

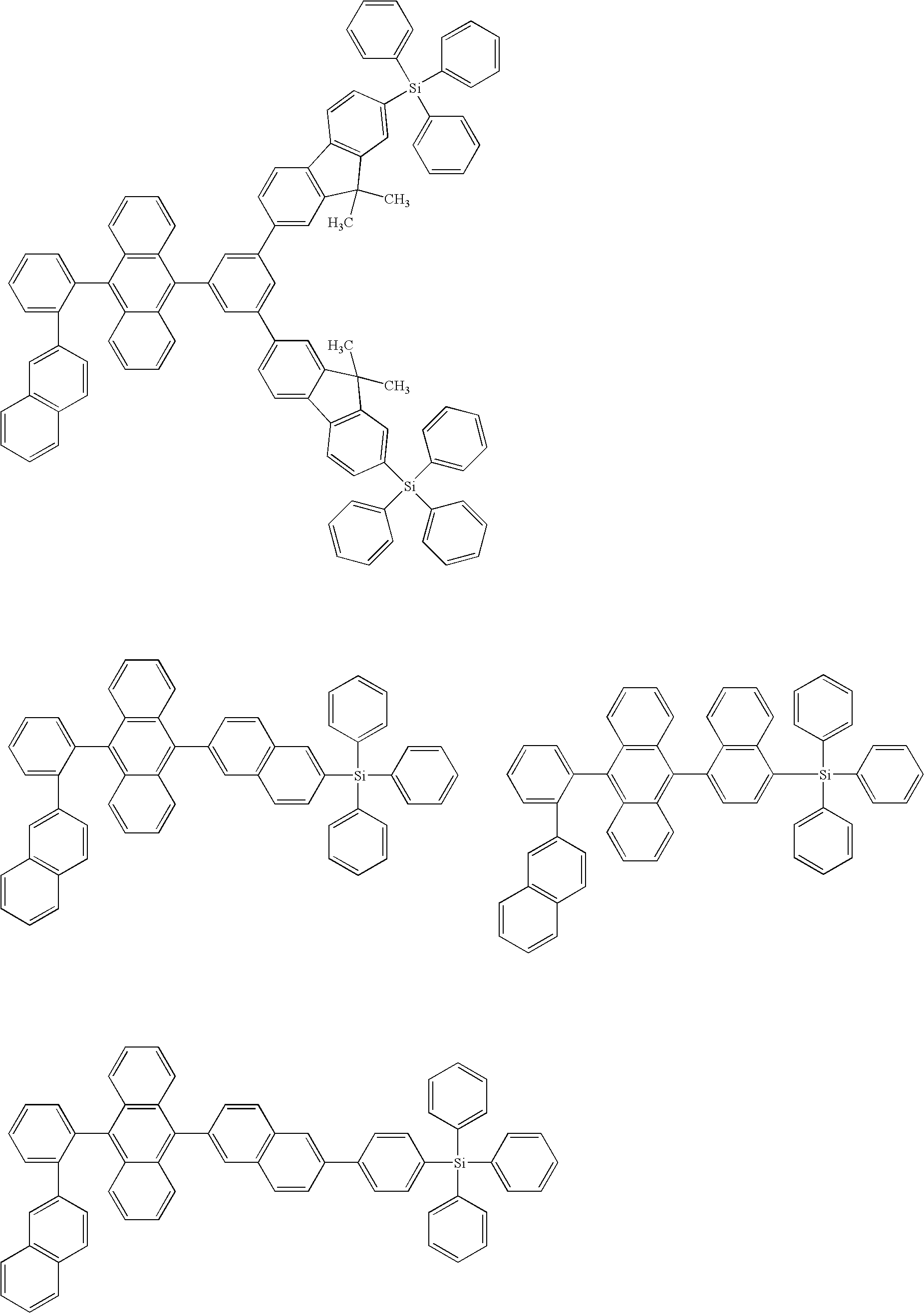

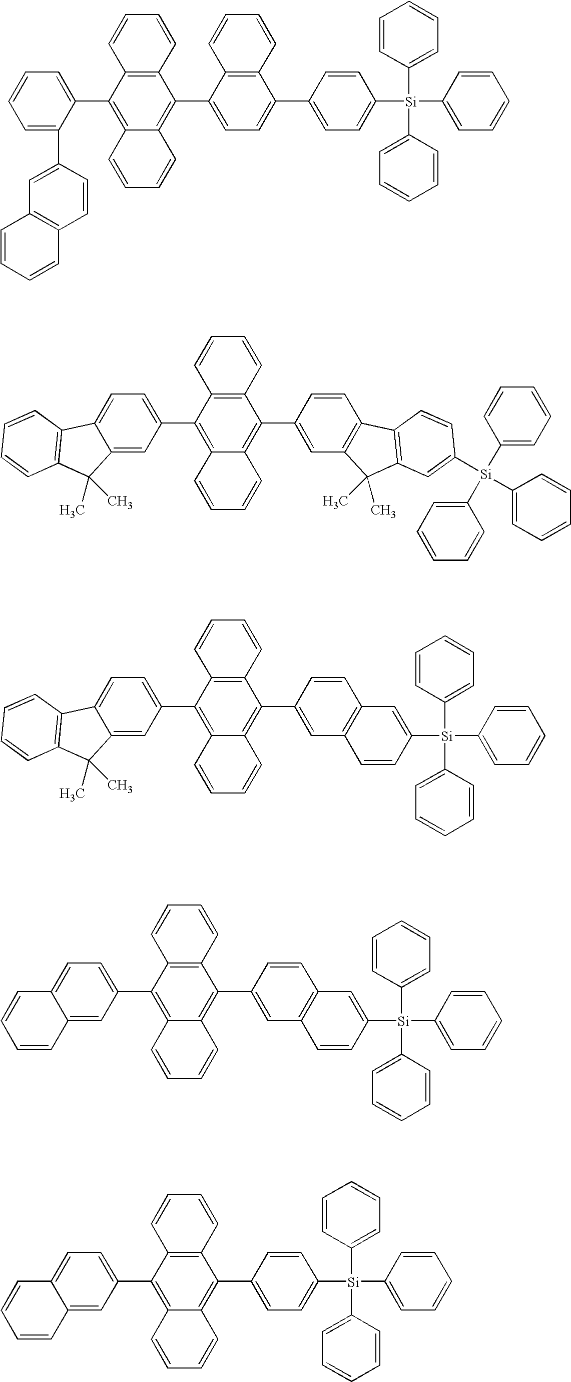

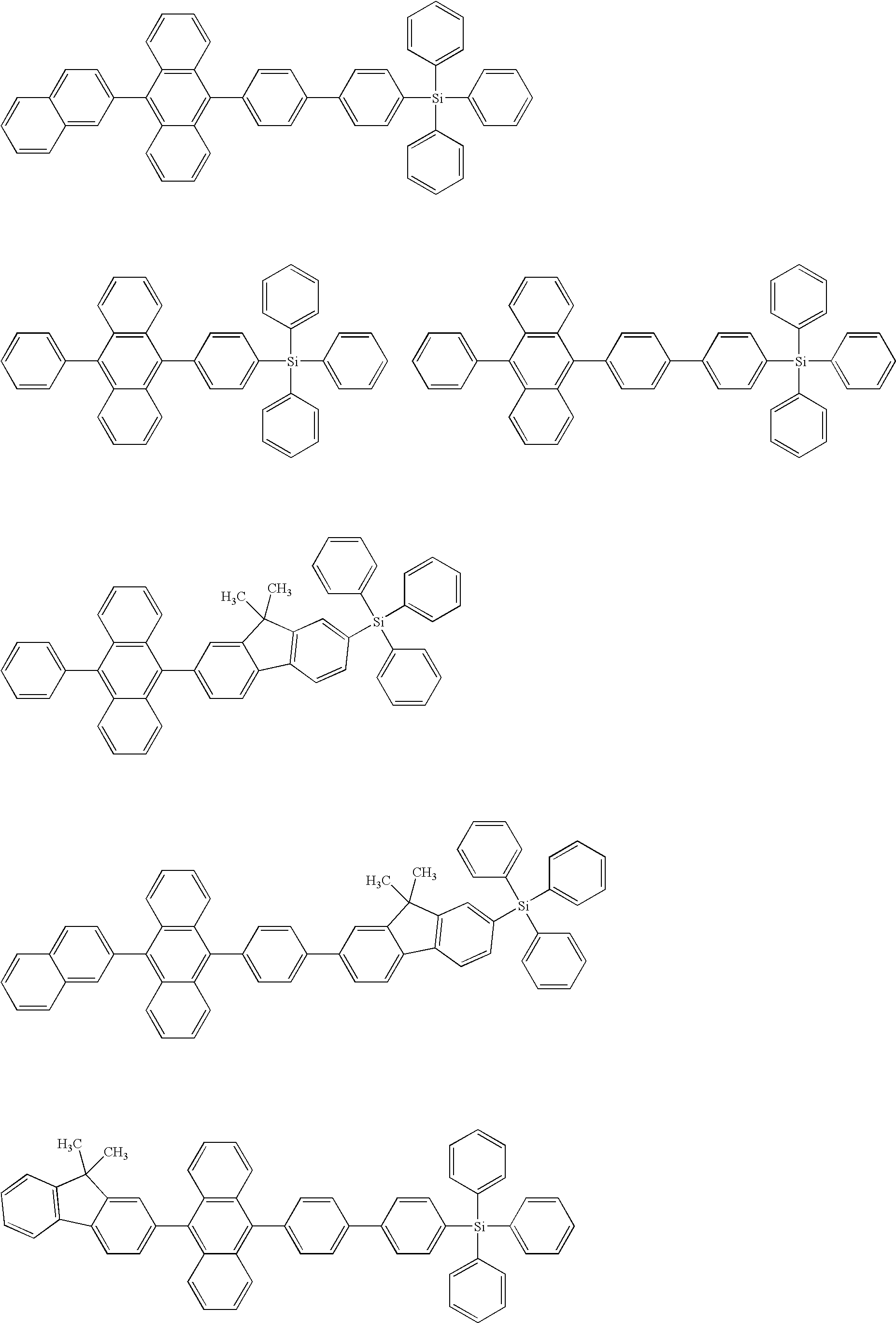

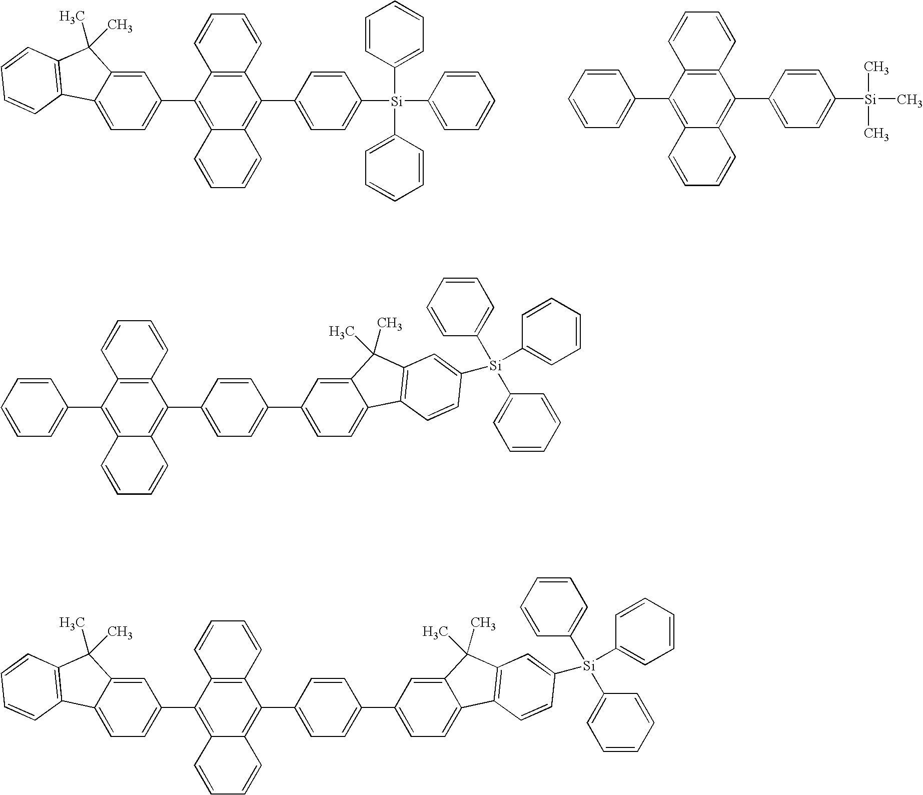

9. An organic electroluminescent compound represented by Chemical Formula (3): 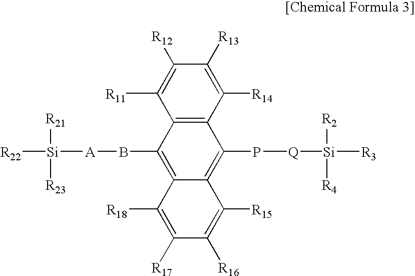
wherein,
A, B, P and Q independently represent a chemical bond, or phenylene, naphthylene, anthrylene or fluorenylene with or without one or more substituent(s) selected from a linear or branched and saturated or unsaturated (C₁-C₃₀)alkyl, (C₆-C₃₀)aryl and halogen, provided that A, B, P and Q are not chemical bonds all at the same time;
R₂, R₃ and R₄ independently represent a linear or branched and saturated or unsaturated (C₁-C₃₀)alkyl or (C₆-C₃₀)aryl;
R₁₁ through R₁₈ independently represent hydrogen, a linear or branched and saturated or unsaturated (C₁-C₃₀)alkyl or (C₆-C₃₀)aryl; and
R₂₁, R₂₂ and R₂₃ independently represent a linear or branched and saturated or unsaturated (C₁-C₃₀)alkyl or (C₆-C₃₀)aryl;
the aryl may be further substituted by a linear or branched and saturated or unsaturated (C₁-C₃₀)alkyl, (C₁-C₃₀)alkoxy, halogen, (C₃-C₁₂)cycloalkyl, phenyl, naphthyl or anthryl.

10. An organic electroluminescent compound according to claim 9, which is selected from the following compounds.

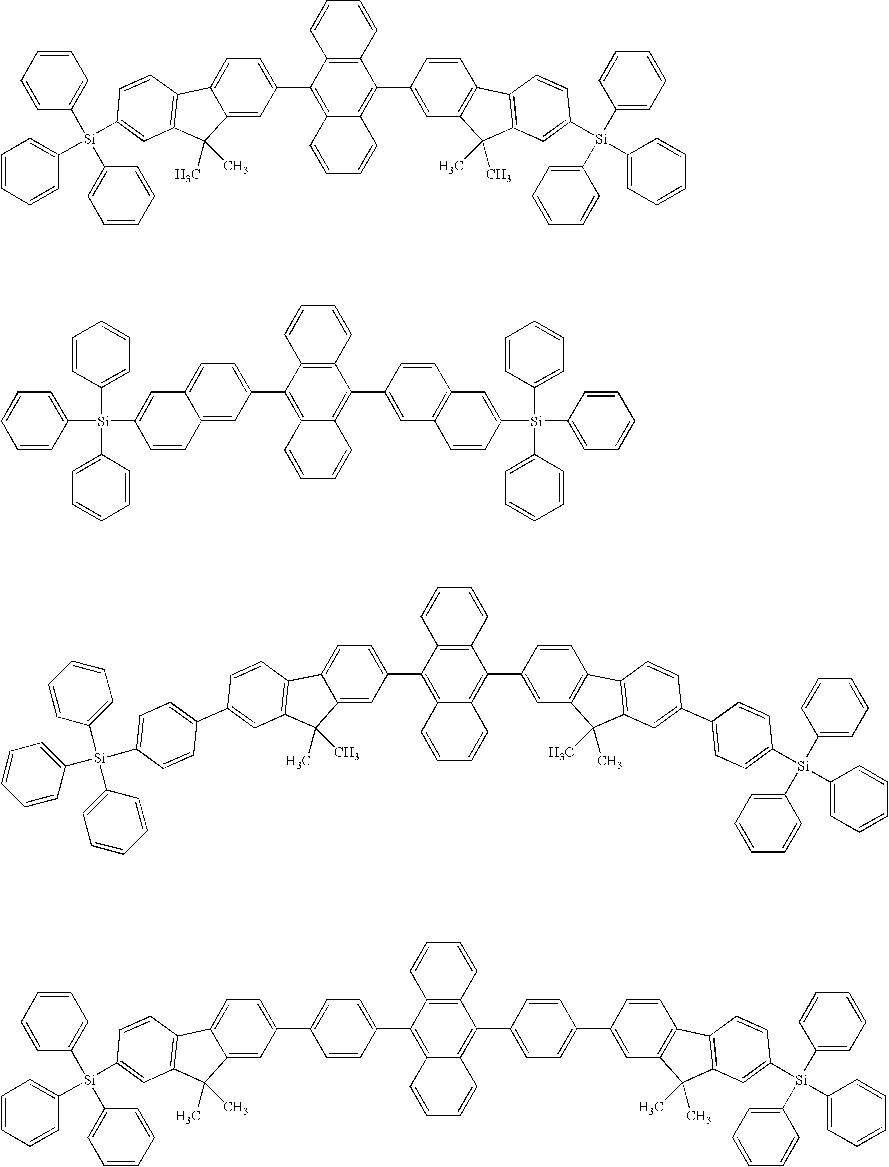

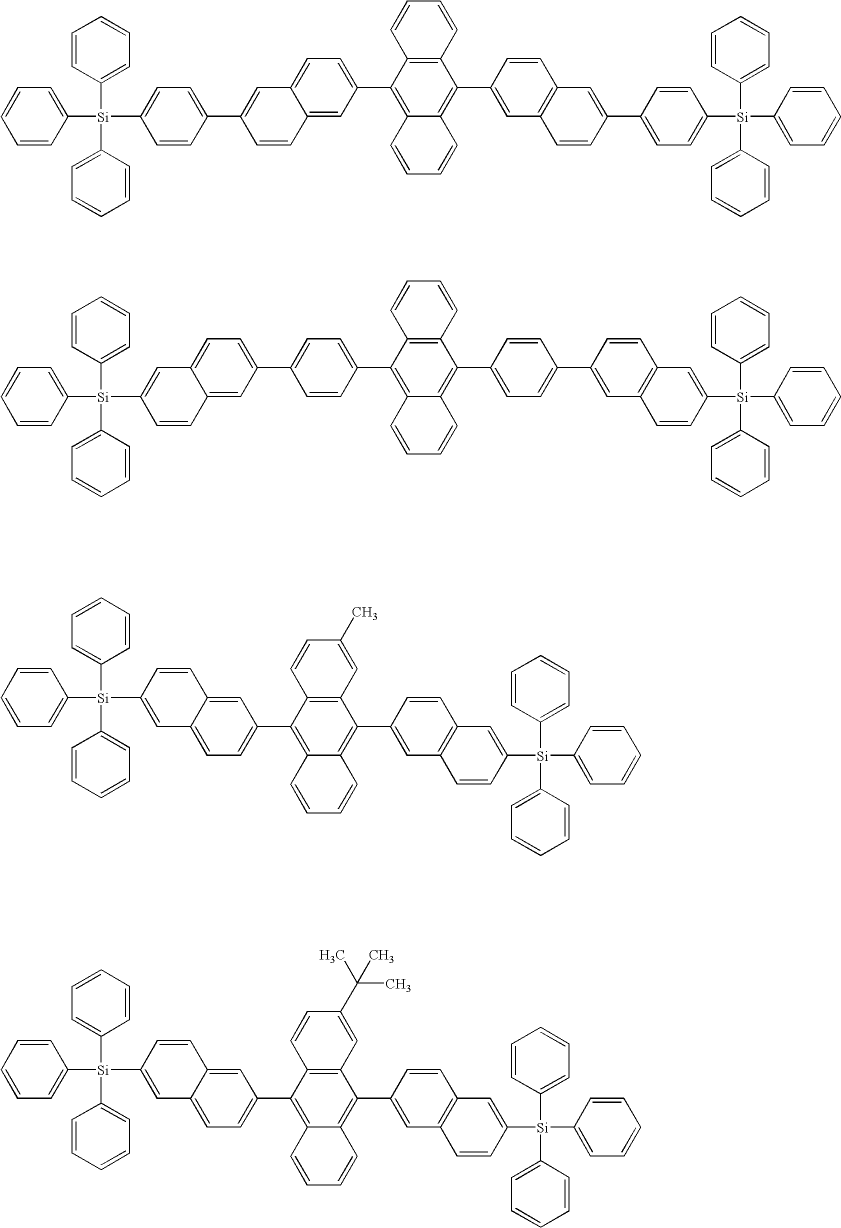

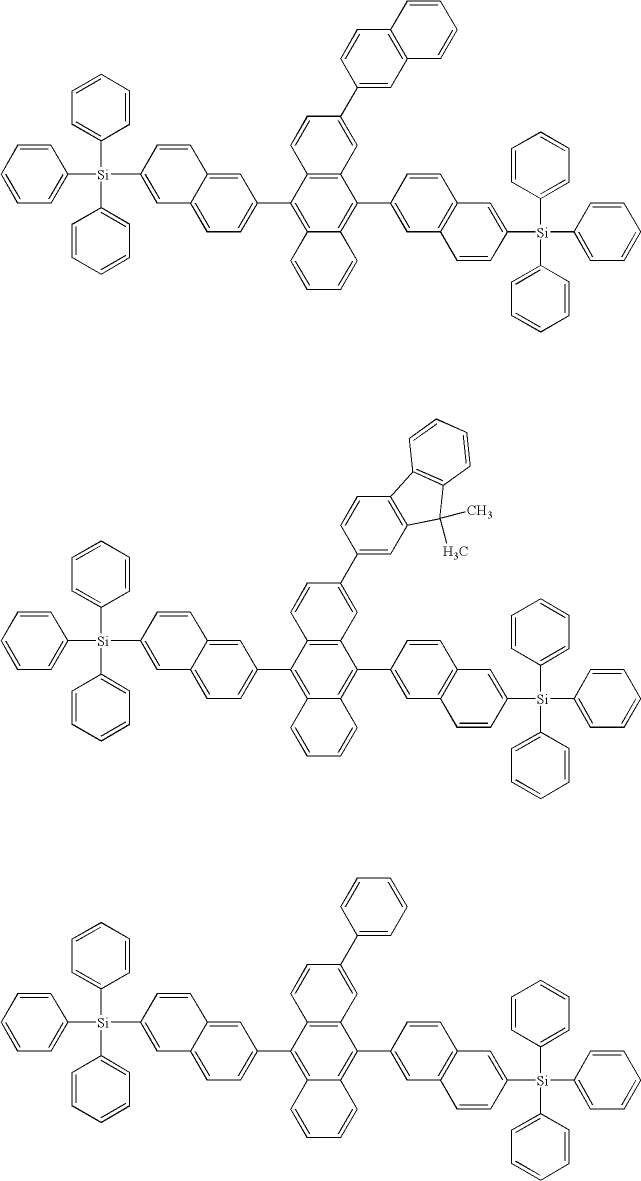

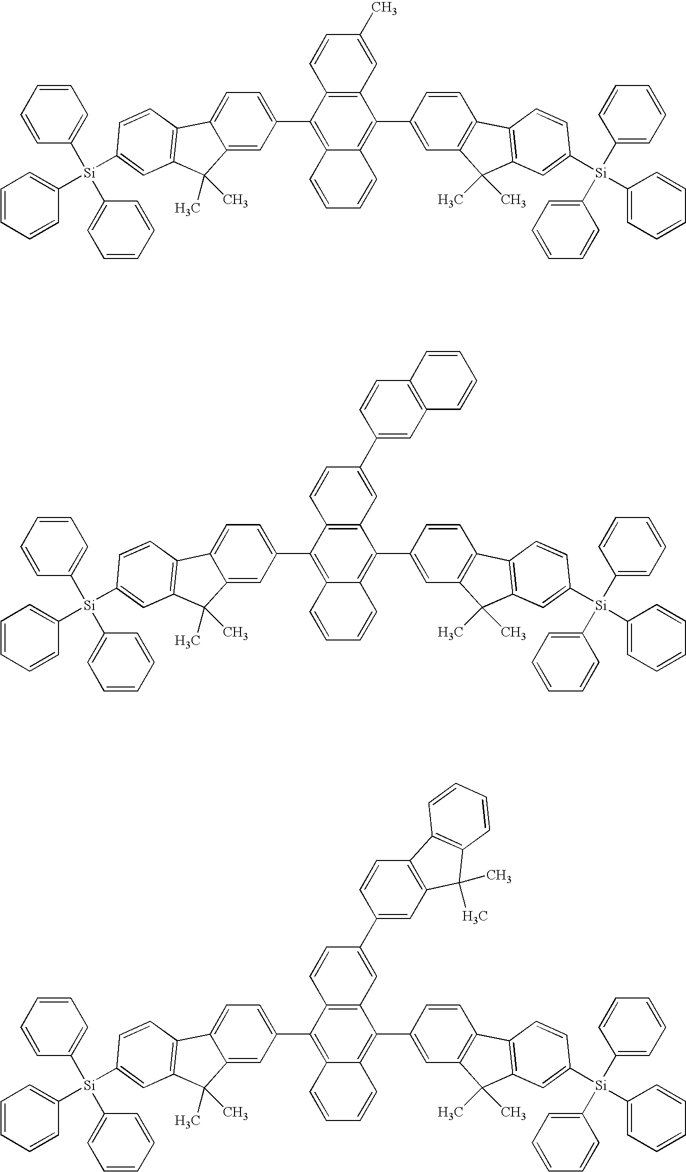

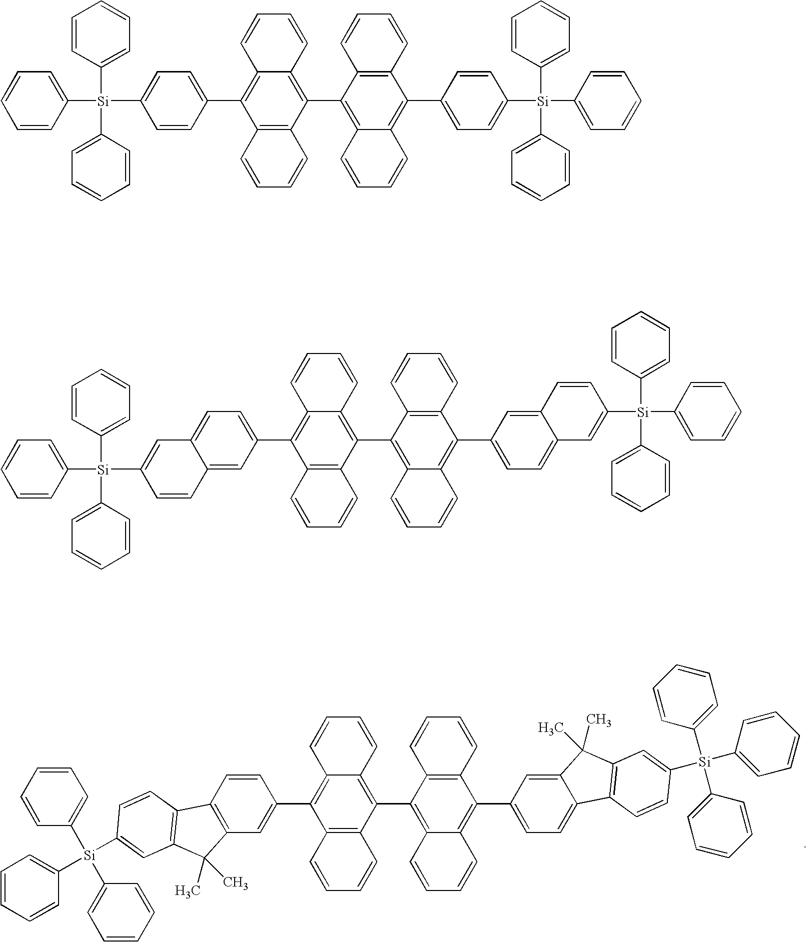

11. An organic light emitting diode comprising an organic electroluminescent compound according to any one of claims 1 to 10 between a cathode and an anode.
